(19) United States
(12) Patent Application Publication
(10) Pub. No.: US 2025/0151254 A1
(43) Pub. Date: May 8, 2025

(54) SEMICONDUCTOR DEVICE AND METHOD FOR MANUFACTURING THE SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Tatsuya ONUKI, Atsugi (JP); Kiyoshi KATO, Atsugi (JP); Hitoshi KUNITAKE, Machida (JP); Ryota HODO, Atsugi (JP)

(21) Appl. No.: 18/838,009

(22) PCT Filed: Feb. 8, 2023
(86) PCT No.: PCT/IB2023/051094

§ 371 Date: Aug. 13, 2024

(30) Foreign Application Priority Data
Feb. 18, 2022 (JP) 2022-023944

(51) Int. Cl. H10B 12/00

(52) U.S. Cl. CPC H10B 12/00

(57) ABSTRACT

A semiconductor device that can be miniaturized or highly integrated is provided. The semiconductor device includes a memory cell including first to third transistors and a capacitor. The second and third transistors share a metal oxide. The capacitor is provided between the first and second transistors. An insulator is provided over an electrode functioning as a source or a drain of the first transistor, and the insulator has an opening reaching the electrode. The capacitor is provided in the opening. One electrode of the capacitor includes, in the opening, a region in contact with the other of the source electrode and the drain electrode of the first transistor. The one electrode of the capacitor includes a region in contact with a gate electrode of the second transistor.

### TECHNICAL FIELD

One embodiment of the present invention relates to a semiconductor device, a memory device, and an electronic device. Another embodiment of the present invention relates to a method for manufacturing a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method of manufacturing any of them.

In this specification and the like, a semiconductor device generally means a device that can function by utilizing semiconductor characteristics. A semiconductor element such as a transistor, a semiconductor circuit, an arithmetic device, and a memory device are each one embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

### BACKGROUND ART

In recent years, semiconductor devices such as LSI (Large Scale Integration), CPUs (Central Processing Units), and memories (memory devices) have been developed. These semiconductor devices have been used in various electronic devices such as computers and portable information terminals. In addition, memories under development employ various storage systems for intended uses such as temporary storage at the time of executing arithmetic processing and long-term storage of data. Examples of memories with typical storage systems include a DRAM (Dynamic Random Access Memory), an SRAM (Static Random Access Memory), and a flash memory.

With an increase in the amount of data dealt with, semiconductor devices having larger memory capacity have been required. Patent Document 1 and Non-Patent Document 1 each disclose a memory cell including stacked transistors.

### REFERENCES

### Patent Document

[Patent Document 1] PCT International Publication No. 2021/053473

### Non-Patent Document

[Non-Patent Document 1] M. Oota, et al., “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be scaled down or highly integrated. Another object of one embodiment of the present invention is to provide a semiconductor device with a high operating speed. Another object of one embodiment of the present invention is to provide a semiconductor device having excellent electrical characteristics. Another object of one embodiment of the present invention is to provide a semiconductor device with a small variation in electrical characteristics of transistors. Another object of one embodiment of the present invention is to provide a highly reliable semiconductor device. Another object of one embodiment of the present invention is to provide a semiconductor device with a high on-state current. Another object of one embodiment of the present invention is to provide a semiconductor device with low power consumption. Another object of one embodiment of the present invention is to provide a novel semiconductor device.

Another object of one embodiment of the present invention is to provide a method for manufacturing a semiconductor device with a small number of processing steps.

Another object of one embodiment of the present invention is to provide a memory device having large memory capacity. Another object of one embodiment of the present invention is to provide a memory device occupying a small area. Another object of one embodiment of the present invention is to provide a highly reliable memory device. Another object of one embodiment of the present invention is to provide a memory device with low power consumption. Another object of one embodiment of the present invention is to provide a novel memory device.

Note that the description of these objects does not preclude the presence of other objects. One embodiment of the present invention does not need to achieve all of these objects. Other objects can be derived from the description of the specification, the drawings, and the claims.

### Means for Solving the Problems

One embodiment of the present invention is a semiconductor device including a first transistor, a second transistor, a third transistor, a capacitor, and a first insulator. The first transistor includes a first metal oxide, a second insulator, a first conductor, and a second conductor; the second transistor includes a second metal oxide, a third insulator, a third conductor, and a fourth conductor; the third transistor includes the second metal oxide, a fourth insulator, the fourth conductor, and a fifth conductor; the capacitor includes a sixth conductor, a fifth insulator, and a seventh conductor; the second insulator is over the first metal oxide; the second conductor is over the first metal oxide to be electrically connected to the first metal oxide; the third insulator and the fourth insulator are over the second metal oxide; the third conductor is over the third insulator; the fifth conductor is over the fourth insulator; the fourth conductor is between the third insulator and the fourth insulator to be electrically connected to the second metal oxide; the first insulator is over the second conductor; the sixth conductor includes a region in contact with a side surface of the first insulator and a top surface of the second conductor; the sixth conductor is electrically connected to the third conductor; the fifth insulator is over the sixth conductor; the seventh conductor is over the fifth insulator; and the seventh conductor includes a region below a top surface of the first insulator.

In the above embodiment, the semiconductor device may include an eighth conductor; the first insulator may include a ninth conductor; the ninth conductor may cover a part of a top surface and a part of a side surface of the first metal oxide; the second insulator may be between the second conductor and the ninth conductor; and the eighth conductor may include a region in contact with a side surface of the ninth conductor.

In the above embodiment, the first insulator may be over the ninth conductor; the eighth conductor may include a region in contact with the side surface of the first insulator; and in the eighth conductor, at least a part of the width of the region in contact with the side surface of the first insulator may be larger than at least a part of the width of the region in contact with the side surface of the ninth conductor in a cross-sectional view.

In the above embodiment, the semiconductor device may include a sixth insulator and a seventh insulator; the seventh insulator may cover at least a part of a top surface and a side surface of the sixth insulator; the first metal oxide, the second metal oxide, and the ninth conductor may be over the seventh insulator; and the eighth conductor may include a region in contact with a side surface of the seventh insulator.

In the above embodiment, the first transistor may include a tenth conductor and an eighth insulator; the second transistor may include an eleventh conductor and a ninth insulator; the third transistor may include a twelfth conductor and the ninth insulator; the tenth to twelfth conductors may be over the sixth insulator to include a region in contact with the side surface of the seventh insulator, the tenth conductor may include a region overlapping with the first conductor; the eleventh conductor may include a region overlapping with the third conductor; the twelfth conductor may include a region overlapping with the fifth conductor; the eighth insulator may be between the tenth conductor and the first metal oxide; and the ninth insulator may be between the eleventh and twelfth conductors and the second metal oxide.

In the above embodiment, the semiconductor device may include a tenth insulator; the first insulator may be over the fourth conductor; the tenth insulator may be over the first insulator and may include a region between the first insulator and the sixth conductor; the tenth insulator may include an opening reaching the fourth conductor; and the sixth conductor further may include a region in the opening.

In the above embodiment, the sixth conductor may include a region in contact with a top surface and a side surface of the tenth insulator.

In the above embodiment, the first metal oxide and the second metal oxide may each contain indium, zinc, and one or more selected from gallium, aluminum, and tin.

Another embodiment of the present invention is a method for manufacturing a semiconductor device, including: forming a first metal oxide and a second metal oxide; forming a first conductive layer over the first metal oxide and a second conductive layer over the second metal oxide; forming a first insulator over the first conductive layer and the second conductive layer; forming a first conductor and a second conductor by forming a first opening reaching the first metal oxide in the first insulator and the first conductive layer, and forming a third conductor, a fourth conductor, and a fifth conductor by forming a second opening and a third opening each reaching the second metal oxide in the first insulator and the second conductive layer; forming a second insulator and a sixth conductor over the second insulator in the first opening, a third insulator and a seventh conductor over the third insulator in the second opening, and a fourth insulator and an eighth conductor over the fourth insulator in the third opening; forming a fifth insulator over the first to fourth insulators and the sixth to eighth conductors; forming, in the first insulator and the fifth insulator, a fourth opening reaching the second conductor and forming, in the fifth insulator, a fifth opening reaching the seventh conductor; forming a ninth conductor in the fourth opening and the fifth opening; and forming, over the ninth conductor, a sixth insulator and a tenth conductor over the sixth insulator.

In the above embodiment, the first conductive layer may be formed to cover a top surface and a side surface of the first metal oxide and the second conductive layer may be formed to cover a top surface and a side surface of the second metal oxide; after the fifth insulator is formed, a sixth opening may be formed in the fifth insulator and the first insulator to expose a side surface of the first conductor; and an eleventh conductor may be formed in the sixth opening to include a region in contact with the side surface of the first conductor.

In the above embodiment, in a cross-sectional view, the side surface of the first conductor exposed by the formation of the sixth opening may be positioned in the sixth opening more inwardly than a side surface of the first insulator.

In the above embodiment, a seventh insulator may be formed, a seventh opening may be formed in the seventh insulator, an eighth insulator may be formed to cover the seventh opening, the first metal oxide and the second metal oxide may be formed over the eighth insulator, and the sixth opening may be formed in the eighth insulator to include a region overlapping with the first opening.

In the above embodiment, after the eighth insulator is formed, an eighth opening, a ninth opening, and a tenth opening each reaching the seventh insulator may be formed in the eighth insulator; a twelfth conductor may be formed in the eighth opening, a thirteenth conductor may be formed in the ninth opening, and a fourteenth conductor may be formed in the tenth opening; a ninth insulator and the first metal oxide over the ninth insulator may be formed over the twelfth conductor, and a tenth insulator and the second metal oxide over the tenth insulator may be formed over the thirteenth and fourteenth conductors; the first conductive layer may be formed to cover a side surface of the ninth insulator and the second conductive layer may be formed to cover a side surface of the tenth insulator; and the first opening may be formed to include a region overlapping with the twelfth conductor, the second opening may be formed to include a region overlapping with the thirteenth conductor, and the third opening may be formed to include a region overlapping with the fourteenth conductor.

### Effect of the Invention

According to one embodiment of the present invention, a semiconductor device that can be scaled down or highly integrated can be provided. According to one embodiment of the present invention, a semiconductor device with a high operating speed can be provided. According to one embodiment of the present invention, a semiconductor device with excellent electrical characteristics can be provided. According to one embodiment of the present invention, a semiconductor device with a small variation in electrical characteristics of transistors can be provided. According to one embodiment of the present invention, a highly reliable semiconductor device can be provided. According to one embodiment of the present invention, a semiconductor device with a high on-state current can be provided. According to one embodiment of the present invention, a semiconductor device with low power consumption can be provided. According to one embodiment of the present invention, a novel semiconductor device can be provided.

According to one embodiment of the present invention, a method for manufacturing a semiconductor device with a small number of processing steps can be provided.

According to one embodiment of the present invention, a memory device having large memory capacity can be provided. According to one embodiment of the present invention, a memory device occupying a small area can be provided. According to one embodiment of the present invention, a highly reliable memory device can be provided. According to one embodiment of the present invention, a memory device with low power consumption can be provided. According to one embodiment of the present invention, a novel memory device can be provided.

Note that the description of these effects does not preclude the presence of other effects. One embodiment of the present invention does not necessarily have all the effects. Other effects can be derived from the description of the specification, the drawings, and the claims.

### BRIEF DESCRIPTION OF THE DRAWINGS

FIG. 1 is a cross-sectional view illustrating a structure example of a semiconductor device.

FIG. 2A is a cross-sectional view illustrating a structure example of a semiconductor device. FIG. 2B is a cross-sectional view illustrating a structure example of a transistor.

FIG. 3 is a cross-sectional view illustrating a structure example of a semiconductor device.

FIG. 4 is a cross-sectional view illustrating a structure example of a semiconductor device.

FIG. 5 is a cross-sectional view illustrating a structure example of a semiconductor device.

FIG. 6 is a cross-sectional view illustrating a structure example of a semiconductor device.

FIG. 7 is a cross-sectional view illustrating a structure example of a semiconductor device.

FIG. 8 is a cross-sectional view illustrating a structure example of a semiconductor device.

FIG. 9A and FIG. 9B are plan views illustrating structure examples of a semiconductor device.

FIG. 10A and FIG. 10B are cross-sectional views illustrating an example of a method for manufacturing a semiconductor device.

FIG. 11A to FIG. 11G are cross-sectional views illustrating an example of a method for manufacturing a semiconductor device.

FIG. 12A to FIG. 12C are cross-sectional views illustrating an example of a method for manufacturing a semiconductor device.

FIG. 13A to FIG. 13C are cross-sectional views illustrating an example of a method for manufacturing a semiconductor device.

FIG. 14A and FIG. 14B are cross-sectional views illustrating an example of a method for manufacturing a semiconductor device.

FIGS. 15A and 15B are cross-sectional views illustrating an example of a method for manufacturing a semiconductor device.

FIG. 16A and FIG. 16B are cross-sectional views illustrating an example of a method for manufacturing a semiconductor device.

FIG. 17 is a cross-sectional view illustrating an example of a method for manufacturing a semiconductor device.

FIG. 18A to FIG. 18D are cross-sectional views illustrating an example of a method for manufacturing a semiconductor device.

FIGS. 19A and 19B are cross-sectional views illustrating an example of a method for manufacturing a semiconductor device.

FIG. 20A and FIG. 20B are diagrams illustrating an example of a memory device.

FIG. 21A and FIG. 21B are circuit diagrams illustrating examples of a memory layer.

FIG. 22 is a timing chart showing an operation example of a memory cell.

FIG. 23A and FIG. 23B are circuit diagrams illustrating an operation example of a memory cell.

FIG. 24A and FIG. 24B are circuit diagrams illustrating an operation example of a memory cell.

FIG. 25 is a circuit diagram illustrating a structure example of a semiconductor device.

FIG. 26A and FIG. 26B are diagrams illustrating an example of a semiconductor device.

FIG. 27A and FIG. 27B are diagrams illustrating examples of electronic components.

FIG. 28A to FIG. 28J are diagrams illustrating examples of electronic devices.

FIG. 29A to FIG. 29E are diagrams illustrating examples of electronic devices.

FIG. 30A to FIG. 30C are diagrams illustrating examples of electronic devices.

FIG. 31 is a diagram illustrating an example of a device for space.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

The same components, components having similar functions, components made of the same material, components formed at the same time, or the like in the structures of the invention described below are denoted by the same reference numerals and the description thereof is not repeated in some cases. Here, two components denoted by the same reference numeral are sometimes separated from each other. For example, even when two conductors are denoted by the same reference numeral, these two conductors are sometimes provided separately from each other. Moreover, the same components, components having similar functions, components made of the same material, components formed at the same time, or the like are shown with the same hatching pattern and their reference numerals are omitted as appropriate in some cases. For example, reference numerals are sometimes omitted so that a plurality of the same reference numerals are not shown in one drawing.

The position, size, range, and the like of each component illustrated in drawings do not represent the actual position, size, range, and the like in some cases for easy understanding. Therefore, the disclosed invention is not necessarily limited to the position, size, range, and the like disclosed in drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or claims in some cases.

Note that the term “film” and the term “layer” can be used interchangeably depending on the case or the situation. For example, the term “conductive layer” can be replaced with the term “conductive film”. For another example, the term “insulating film” can be replaced with the term “insulating layer”.

In this specification and the like, terms for describing positioning, such as “over”, “under”, “above”, and “below”, are sometimes used for convenience to describe the positional relationship between components with reference to drawings. The positional relationship between components is changed as appropriate in accordance with a direction in which each component is described. Thus, the positional relationship is not limited to the terms described in this specification and the like, and can be described with another term as appropriate depending on the situation. For example, the expression “an insulator positioned over a conductor” can be replaced with the expression “an insulator positioned under a conductor” when the direction of a drawing illustrating these components is rotated by 180°.

### Embodiment 1

In this embodiment, a semiconductor device of one embodiment of the present invention will be described with reference to drawings.

One embodiment of the present invention relates to a semiconductor device in which a memory layer is provided over a substrate. The memory layer includes a first transistor, a second transistor, a third transistor, and a capacitor, which can form a memory cell. The semiconductor device of one embodiment of the present invention includes the memory cell and thus has a function of storing data. Hence, the semiconductor device of one embodiment of the present invention can be referred to as a memory device.

The first transistor includes a first metal oxide, first and second conductors covering parts of the top surface and the side surfaces of the first metal oxide, a first insulator provided between the first conductor and the second conductor, and a third conductor over the first insulator. The second transistor includes a second metal oxide, a fourth conductor covering parts of the top surface and the side surface of the second metal oxide, a fifth conductor covering a part of the top surface of the second metal oxide, a second insulator provided between the fourth conductor and the fifth conductor, and a sixth conductor over the second insulator. The third transistor includes the second metal oxide, the fifth conductor, a seventh conductor covering a part of the top surface of the second metal oxide, a third insulator provided between the fifth conductor and the seventh conductor, and an eighth conductor over the second insulator. That is, the second transistor and the third transistor share the second metal oxide and the fifth conductor.

The first metal oxide includes a region functioning as a channel formation region of the first transistor. The first conductor includes a region functioning as one of a source electrode and a drain electrode of the first transistor. The second conductor includes a region functioning as the other of the source electrode and the drain electrode of the first transistor. The third conductor includes a region including a region functioning as a gate electrode of the first transistor. The first insulator includes a region functioning as a gate insulator of the first transistor.

The second metal oxide includes a region functioning as a channel formation region of the second transistor and a region functioning as a channel formation region of the third transistor. The fourth conductor includes a region functioning as one of a source electrode and a drain electrode of the second transistor. The fifth conductor includes a region functioning as the other of the source electrode and the drain electrode of the second transistor and also functioning as one of a source electrode and a drain electrode of the third transistor. The sixth conductor includes a region functioning as a gate electrode of the second transistor. The seventh conductor includes a region functioning as the other of the source electrode and the drain electrode of the third transistor. The eighth conductor includes a region functioning as a gate electrode of the third transistor. The second insulator includes a region functioning as a gate insulator of the second transistor. The third insulator includes a region functioning as a gate insulator of the third transistor.

When the second transistor and the third transistor are adjacent to each other to share the second metal oxide and the fifth conductor, the two transistors can be formed in an area smaller than the area of two transistors, for example, can be formed in the area of one and a half transistors. This enables the transistors to be arranged at high density, which leads to high integration in the semiconductor device.

The semiconductor device of one embodiment of the present invention includes a transistor including a metal oxide in a channel formation region (an OS transistor). When the OS transistor, which has a low off-state current, is used for a semiconductor device that can be a memory device, stored contents can be retained for a long time. That is, a refresh operation is not required or the frequency of the refresh operation is extremely low; thus, the power consumption of the semiconductor device can be adequately reduced. The OS transistor has high frequency characteristics and thus enables the semiconductor device to perform data reading and writing at high speed.

In the semiconductor device of one embodiment of the present invention, a plurality of memory layers each having the above structure are stacked. That is, the plurality of memory layers each having the above structure are provided in the direction perpendicular to the substrate surface, for example. Thus, without an increase in the area occupied by memory cells, the semiconductor device can have larger memory capacity than a semiconductor device including one memory layer. Accordingly, the occupation area per bit is reduced, so that the semiconductor device can have a small size and large memory capacity.

In the case where the plurality of memory layers are stacked, a bit line can be provided in the direction perpendicular to the substrate surface, for example. The bit line can be formed by, for example, providing an opening to penetrate the memory layers and forming a conductor in the opening. Here, the semiconductor device of one embodiment of the present invention includes a first bit line and a second bit line. A conductor including a region functioning as the first bit line is provided to include a region in contact with the top surface and the side surface of the first conductor. In addition, a conductor including a region functioning as the second bit line is provided to include a region in contact with the top surface and the side surface of the seventh conductor. Such a structure eliminates the need for additionally providing a connection electrode between the first conductor and the first bit line and the need for additionally providing a connection electrode between the seventh conductor and the second bit line. In this manner, the semiconductor device of one embodiment of the present invention can be a semiconductor device having a high integration degree of memory cells.

Note that in the semiconductor device of one embodiment of the present invention, data is written to a memory cell through the first bit line. Moreover, data retained in the memory cell is read through the second bit line. Accordingly, the first bit line can be referred to as a write bit line, and the second bit line can be referred to as a read bit line.

### <Structure Example of Semiconductor Device>

Structure examples of the semiconductor device of one embodiment of the present invention will be described below.

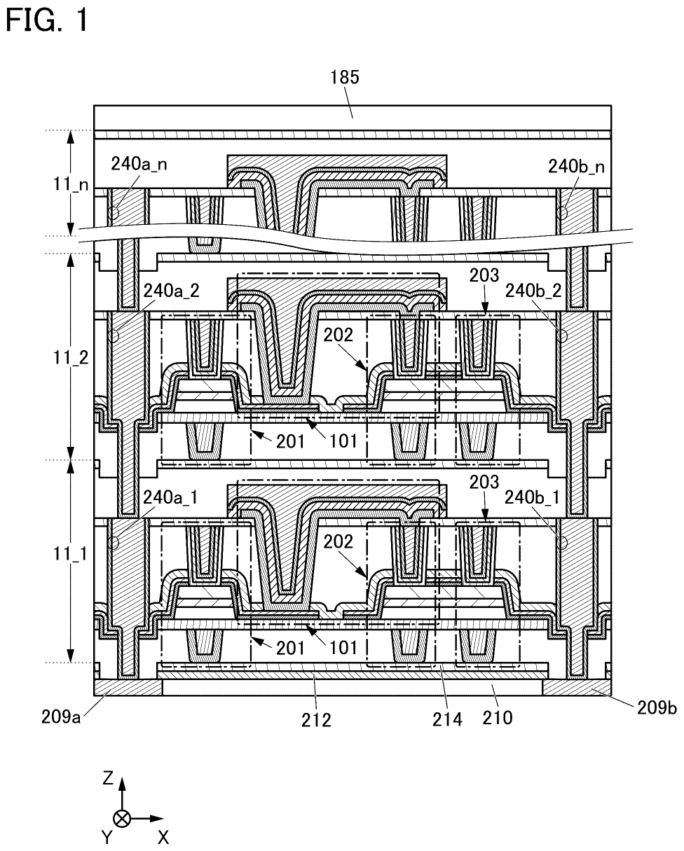

FIG. 1 is a cross-sectional view illustrating a structure example of the semiconductor device of one embodiment of the present invention. The semiconductor device illustrated in FIG. 1 includes an insulator 210 over a substrate (not illustrated), a conductor 209a and a conductor 209b embedded in the insulator 210, an insulator 212 over the insulator 210, an insulator 214 over the insulator 212, n memory layers 11 (a memory layer 11_1 to a memory layer 11_n) (n is an integer greater than or equal to 2) over the insulator 214, a conductor 240a (a conductor 240a_1 to a conductor 240a_n) and a conductor 240b (a conductor 240b_1 to a conductor 240b_n) which are provided in the memory layer 11, and an insulator 185 over the memory layer 11_n. The conductor 240a is electrically connected to the conductor 209a, and the conductor 240a_1 includes a region in contact with the conductor 209a, for example. The conductor 240b is electrically connected to the conductor 209b, and the conductor 240b_1 includes a region in contact with the conductor 209b, for example. The bottom surface of the conductor 240a_n can include a region in contact with the top surface of the conductor 240a_n−1, and the bottom surface of the conductor 240b_n can include a region in contact with the top surface of the conductor 240b_n−1, for example.

In this structure, the conductor 240a_1 to the conductor 240a_n and the conductor 240b_1 to the conductor 240b_n are provided to penetrate the memory layer 11_1 to the memory layer 11_n. The conductor 240a_1 and the conductor 240b_1 are provided in the memory layer 11_1, for example. The conductor 240a_2 and the conductor 240b_2 each include a region provided in the memory layer 11_1 and a region provided in the memory layer 11_2, for example. Note that components included in the semiconductor device of this embodiment may each have either a single-layer structure or a stacked-layer structure.

In this specification and the like, a direction parallel to a channel length direction of a transistor illustrated is referred to as an X direction, and a direction parallel to a channel width direction of a transistor illustrated is referred to as a Y direction. The X direction and the Y direction can be perpendicular to each other. Furthermore, a direction perpendicular to both the X direction and the Y direction, i.e., a direction perpendicular to the XY plane, is referred to as a Z direction. The X direction and the Y direction can each be a direction parallel to the substrate surface, and the Z direction can be a direction perpendicular to the substrate surface, for example.

In the following description of matters common to components distinguished from each other using letters of the alphabet, reference numerals without the letters of the alphabet are sometimes used. For example, in the case where matters common to the conductor 209a and the conductor 209b are described, the term “conductor 209” is used in some cases.

The memory layer 11_1 to the memory layer 11_n are each provided with a memory cell array including a plurality of memory cells. The memory cells each include a transistor 201, a transistor 202, a transistor 203, and a capacitor 101. Note that the circuit structure and driving method of the memory cells will be described in Embodiment 2.

The conductor 240a and the conductor 240b each include a region functioning as a bit line. Here, in the semiconductor device of one embodiment of the present invention, data is written to the memory cells through the conductor 240a. Moreover, data retained in the memory cells is read through the conductor 240b. Accordingly, the conductor 240a can be regarded as including a region functioning as a write bit line, and the conductor 240b can be regarded as including a region functioning as a read bit line.

The conductor 209a and the conductor 209b each function as a wiring, an electrode, a terminal, or a part of a circuit element such as a switch, a transistor, a capacitor, an inductor, a resistor, or a diode.

FIG. 1 illustrates, among the n memory layers 11, the memory layer 11_1 that is the lowest layer, the memory layer 11_2 over the memory layer 11_1, and the memory layer 11_n that is the uppermost layer.

The conductor 209a and the conductor 209b are electrically connected to driver circuits for driving the memory cells provided in the memory layers 11. The driver circuits are provided below the conductor 209a and the conductor 209b. Increasing the number of stacked memory layers 11 (the value of n) can increase the memory capacity of the memory device without an increase in the area occupied by the memory cells. Accordingly, the occupation area per bit is reduced, so that the semiconductor device can have a small size and large memory capacity.

The transistor 201, the transistor 202, the transistor 203, and the capacitor 101 are provided over the insulator 214. Here, the transistor 202 and the transistor 203 share some layers. The capacitor 101 includes a region positioned between the transistor 201 and the transistor 202. The capacitor 101 includes a region positioned over the transistor 202.

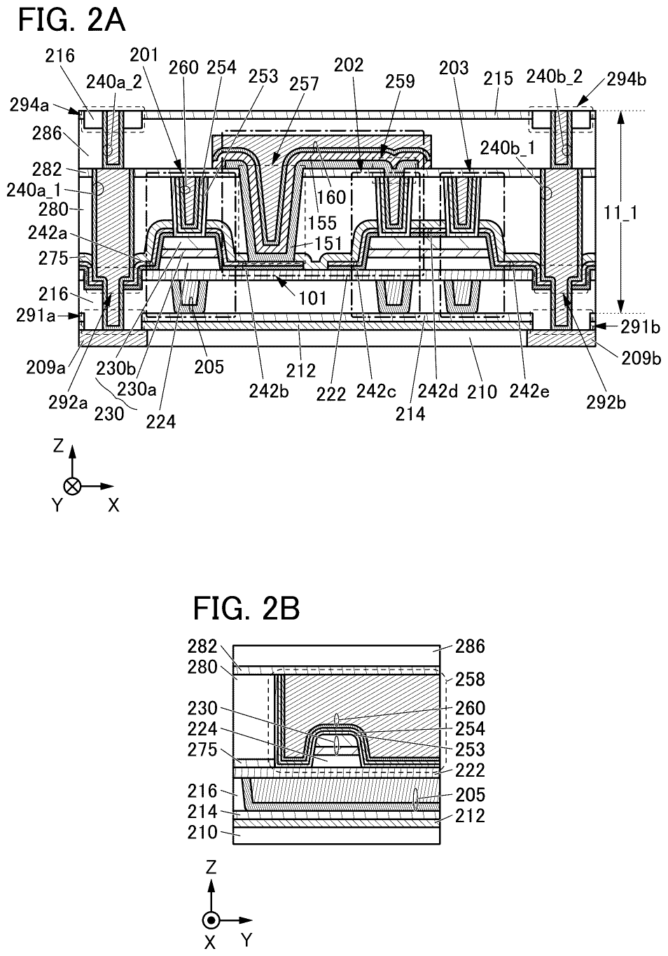

FIG. 2A is a cross-sectional view illustrating structure examples of the conductor 209a, the conductor 209b, the insulator 210, the insulator 212, the insulator 214, and the memory layer 11_1.

The transistor 201, the transistor 202, and the transistor 203 each include a conductor 205 over the insulator 214, an insulator 222 over the conductor 205, an insulator 224 over the insulator 222, a metal oxide 230 (a metal oxide 230a and a metal oxide 230b) over the insulator 224, a conductor 242 covering parts of the side surfaces of the insulator 224 and parts of the top surface and the side surfaces of the metal oxide 230, an insulator 253 over the metal oxide 230, an insulator 254 over the insulator 253, and a conductor 260 over the insulator 254. Here, the transistor 201 includes a conductor 242a and a conductor 242b as the conductor 242, the transistor 202 includes a conductor 242c and a conductor 242d as the conductor 242, and the transistor 203 includes the conductor 242d and a conductor 242e as the conductor 242. The transistor 202 and the transistor 203 share one insulator 224, one metal oxide 230, and one conductor 242d.

An insulator 216 provided with an opening is provided over the insulator 214, and the conductor 205 is embedded in the opening. The insulator 222 is provided over the conductor 205 and the insulator 216. An insulator 275 is provided over the conductor 242a to the conductor 242e, and an insulator 280 is provided over the insulator 275. The insulator 253, the insulator 254, and the conductor 260 are embedded in an opening provided in the insulator 280 and the insulator 275. An insulator 282 is provided over the insulator 280, the conductor 260, the insulator 253, and the insulator 254. The conductor 205 can be provided over the insulator 214 to include a region in contact with the side surface of the insulator 216. The insulator 253 can include a region in contact with at least parts of the side surface of the conductor 242, the side surface of the insulator 275, and the side surface of the insulator 280.

In this specification and the like, the term “opening” includes a groove, a slit, and the like. A region where an opening is formed is referred to as an opening portion in some cases.

The metal oxide 230 includes a region functioning as a channel formation region of the transistor 201, the transistor 202, or the transistor 203. Note that for the transistor 201, the transistor 202, and the transistor 203, a semiconductor such as single crystal silicon, polycrystalline silicon, or amorphous silicon may be used instead of the metal oxide 230; for example, low-temperature polysilicon (LTPS) may be used.

The conductor 242a includes a region functioning as one of a source electrode and a drain electrode of the transistor 201. The conductor 242b includes a region functioning as the other of the source electrode and the drain electrode of the transistor 201. The conductor 242c includes a region functioning as one of a source electrode and a drain electrode of the transistor 202. The conductor 242d includes a region functioning as the other of the source electrode and the drain electrode of the transistor 202 and a region functioning as one of a source electrode and a drain electrode of the transistor 203. The conductor 242e includes a region functioning as the other of the source electrode and the drain electrode of the transistor 203. The conductor 242 is electrically connected to the metal oxide 230.

The conductor 260 includes a region functioning as a first gate electrode of the transistor 201, the transistor 202, or the transistor 203. The insulator 253 and the insulator 254 each include a region functioning as a first gate insulator of the transistor 201, the transistor 202, or the transistor 203.

The conductor 205 includes a region functioning as a second gate electrode of the transistor 201, the transistor 202, or the transistor 203. The insulator 222 includes a region functioning as a second gate insulator of the transistor 201, a region functioning as a second gate insulator of the transistor 202, and a region functioning as a second gate insulator of the transistor 203. The insulator 224 includes a region functioning as the second gate insulator of the transistor 201, the transistor 202, or the transistor 203. Here, the conductor 205 includes a region overlapping with the conductor 260.

In this specification and the like, the first gate electrode can be referred to as a front gate electrode or simply as a gate electrode, and the second gate electrode can be referred to as a back gate electrode. Note that the first gate electrode may be referred to as a back gate electrode, and the second gate electrode may be referred to as a front gate electrode or simply as a gate electrode.

The transistor 202 and the transistor 203 are adjacent to each other and share one insulator 224, one metal oxide 230, and one conductor 242d as described above. Thus, the two transistors (the transistor 202 and the transistor 203) can be formed in an area smaller than the area of two transistors, for example, can be formed in the area of one and a half transistors. This enables the transistors to be arranged at high density as compared with the case where the transistor 202 and the transistor 203 do not share the insulator 224, the metal oxide 230, and the conductor 242d; hence, high integration in the semiconductor device can be achieved.

The conductor 242d is placed in a region between the conductor 260 included in the transistor 202 and the conductor 260 included in the transistor 203. Thus, in the case where the transistor 202 and the transistor 203 are n-channel transistors, an n-type region (a low-resistance region) can be formed in a region of the metal oxide 230 that overlaps with the conductor 242d. Specifically, the n-type region can be formed in a region of the metal oxide 230b that overlaps with the conductor 242d. Moreover, current can flow between the transistor 202 and the transistor 203 through the conductor 242d. Thus, the resistance component between the transistor 202 and the transistor 203 can be significantly reduced as compared with a structure in which two transistors using silicon in their semiconductor layers where channels are formed (also referred to as Si transistors) are connected in series.

Unless otherwise specified, description is given below assuming that the transistors are n-channel transistors; however, the description below can apply to the case where the transistors are p-channel transistors by reversing the high/low relationship between potentials as appropriate, for example.

An opening 257 reaching the conductor 242b is provided in the insulator 275, the insulator 280, and the insulator 282, and the capacitor 101 is provided in the opening 257. Specifically, the capacitor 101 includes a conductor 151, an insulator 155 over the conductor 151, and a conductor 160 over the insulator 155. The capacitor 101 forms a MIM (Metal-Insulator-Metal) capacitor.

At least parts of the conductor 151, the insulator 155, and the conductor 160 are provided in the opening 257. Thus, the conductor 151, the insulator 155, and the conductor 160 each include a region positioned below the top surface of the insulator 282.

Inside the opening 257, the conductor 151 includes a region in contact with the top surface of the conductor 242b. The conductor 151 includes a region in contact with at least parts of the side surface of the insulator 275, the side surface of the insulator 280, and the top surface and the side surface of the insulator 282. Here, the conductor 151 includes a region functioning as one electrode of the capacitor 101, the insulator 155 includes a region functioning as a dielectric of the capacitor 101, and the conductor 160 includes a region functioning as the other electrode of the capacitor 101. The deeper the opening 257 is, i.e., the thicker at least one of the insulator 275, the insulator 280, and the insulator 282 is, the larger the capacitance per unit area of the capacitor 101 can be. In that case, miniaturization or high integration of the semiconductor device can be achieved.

An opening 259 reaching the conductor 260 of the transistor 202 is provided in the insulator 282. The conductor 151 includes a region positioned in the opening 259. The conductor 151 includes a region in contact with the conductor 260 of the transistor 202 in the opening 259, for example.

Since the conductor 151 includes the region positioned in the opening 257 and the region positioned in the opening 259 as described above, an electrical connection between the conductor 242b and the conductor 260 included in the transistor 202 can be achieved through the conductor 151. Thus, the one electrode of the capacitor 101 can be electrically connected to the other of the source electrode and the drain electrode of the transistor 201 and the gate electrode of the transistor 202.

An insulator 286 is provided over the insulator 282 to cover the capacitor 101. The insulator 215 is provided over the insulator 286.

The conductor 242a, the conductor 242b, the conductor 242c, and the conductor 242e extend beyond the metal oxide 230 functioning as a semiconductor layer and cover parts of the top surface and the side surfaces of the metal oxide 230. Thus, the conductor 242a, the conductor 242b, the conductor 242c, and the conductor 242e also function as wirings. The conductor 240a including the region functioning as a write bit line is provided to include a region in contact with parts of the top surface and the side surface of the conductor 242a, for example. The conductor 240b including the region functioning as a read bit line is provided to include a region in contact with parts of the top surface and the side surface of the conductor 242e. Note that the conductor 242d can also function as a wiring. Another conductor can also function as a wiring in some cases.

Since the conductor 240a includes the region in contact with parts of the top surface and the side surface of the conductor 242a and the conductor 240b includes the region in contact with parts of the top surface and the side surface of the conductor 242e, a connection electrode does not need to be provided additionally; thus, the area occupied by the memory cell array can be reduced. In addition, the integration degree of the memory cells can be increased and the memory capacity can be increased. Note that when the conductor 240a is in contact with both the top surface and the side surface of the conductor 242a, the contact resistance between the conductor 240a and the conductor 242a can be lower than when the conductor 240a is in contact with only one of the top surface and the side surface of the conductor 242a, for example. When the conductor 240b is in contact with both the top surface and the side surface of the conductor 242e, the contact resistance between the conductor 240b and the conductor 242e can be lower than when the conductor 240b is in contact with only one of the top surface and the side surface of the conductor 242e, for example.

Here, an opening 291a including a region overlapping with the conductor 209a and an opening 291b including a region overlapping with the conductor 209b are provided in the insulator 212 and the insulator 214. An opening 292a including a region overlapping with the conductor 209a and the opening 291a and an opening 292b including a region overlapping with the conductor 209b and the opening 291b are provided in the insulator 222. Furthermore, in the insulator 215, an opening 294a including a region overlapping with the conductor 209a, the opening 291a, and the opening 292a and an opening 294b including a region overlapping with the conductor 209b, the opening 291b, and the opening 292b are provided. The conductor 240a is provided in the opening 291a, the opening 292a, and the opening 294a, and the conductor 240b is provided in the opening 291b, the opening 292b, and the opening 294b. Note that the opening 291a and the opening 291b are not necessarily provided in the insulator 212. In that case, a structure can be obtained in which the side surface of the insulator 212 is not aligned with the side surface of the insulator 214, for example. The side surface of the insulator 212 can include a region in contact with the side surface of the conductor 240a, and the side surface of the insulator 212 can include a region in contact with the side surface of the conductor 240b, for example.

In each of the opening 291a and the opening 291b, the insulator 216 covers the side surface of the insulator 212 and the side surface of the insulator 214. The conductor 242a covers the side surface of the insulator 222 in the opening 292a, and the conductor 242e covers the side surface of the insulator 222 in the opening 292b. Furthermore, in each of the opening 294a and the opening 294b, the side surface of the insulator 215 is covered with the insulator 216. Note that the insulator 216 covering the side surface of the insulator 215 in FIG. 2A includes a region provided in the memory layer 11_2.

Accordingly, the insulator 216 can be regarded as being provided to cover at least parts of the top surface and the side surfaces of the insulator 214. In addition, the conductor 242a and the conductor 242e can be regarded as being provided to cover at least parts of the top surface and the side surfaces of the insulator 222. Moreover, the insulator 216 can be regarded as being provided to cover at least parts of the top surface and the side surfaces of the insulator 215.

In the semiconductor device of one embodiment of the present invention having the above structure, the conductor 240a and the conductor 240b are each provided to include regions in contact with at least parts of the side surface of the insulator 216, the side surface of the insulator 275, the side surface of the insulator 280, the side surface of the insulator 282, and the side surface of the insulator 286. As described above, the conductor 240a is provided to include the region in contact with the side surface of the conductor 242a, and the conductor 240b is provided to include the region in contact with the side surface of the conductor 242e. Furthermore, the conductor 240a and the conductor 240b are provided so as not to be in contact with the insulator 212, the insulator 214, the insulator 222, or the insulator 215. Here, the top surfaces of the conductor 240a_1 to the conductor 240a_n and the top surfaces of the conductor 240b_1 to the conductor 240b_n can each be aligned or substantially aligned with the top surface of the insulator 282. The bottom surfaces of the conductor 240a_2 to the conductor 240a_n and the bottom surfaces of the conductor 240b_2 to the conductor 240b_n can be aligned or substantially aligned with the bottom surface of the insulator 286.

In the case of the semiconductor device of one embodiment of the present invention having the above-described structure, for example, the insulator 212, the insulator 214, the insulator 222, and the insulator 215 do not need to be processed when the openings are provided in the insulator 216, the insulator 275, the insulator 280, the insulator 282, and the insulator 286 to form the conductor 240a and the conductor 240b. In that case, the insulator 212, the insulator 214, the insulator 222, and the insulator 215 can be formed using materials that are easily processed under conditions different from those of the materials for the insulator 216, the insulator 275, the insulator 280, the insulator 282, and the insulator 286. This can widen the range of choices for materials that can be used for the insulators. Note that the conductor 240a and the conductor 240b can each be formed by embedding a conductive film in the opening.

FIG. 2B is a cross-sectional view illustrating a structure example of the transistor illustrated in FIG. 2A in the channel width direction, i.e., in the Y direction.

In the example illustrated in FIG. 2B, the insulator 212 is provided over the insulator 210, the insulator 214 is provided over the insulator 212, the insulator 216 is provided over the insulator 214, and the conductor 205 is provided in the opening provided in the insulator 216. The insulator 222 is provided over the conductor 205 and the insulator 216, the insulator 224 and the insulator 275 are provided over the insulator 222, and the metal oxide 230 is provided over the insulator 224. The side surfaces of the insulator 224 and the top surface and the side surfaces of the metal oxide 230 are covered with the insulator 253, the insulator 254, and the conductor 260. The insulator 253, the insulator 254, and the conductor 260 are provided in an opening 258 formed in the insulator 280 over the insulator 275. The insulator 282 is provided over the insulator 253, the insulator 254, the conductor 260, and the insulator 280, and the insulator 286 is provided over the insulator 282.

Here, the conductor 260 including the region functioning as the first gate electrode can be regarded as covering not only the top surface but also the side surfaces of the metal oxide 230.

In this specification and the like, a transistor structure in which a channel formation region is electrically surrounded by at least the electric field of the first gate electrode is referred to as a surrounded channel (s-channel) structure. The s-channel structure disclosed in this specification and the like has a structure that is different from a Fin-type structure and a planar structure. The s-channel structure disclosed in this specification and the like can be regarded as a kind of the Fin-type structure. Note that in this specification and the like, the Fin-type structure refers to a structure in which a gate electrode is placed to cover at least two or more surfaces (specifically, two surfaces, three surfaces, or four surfaces) of a channel. With the use of the Fin-type structure and the s-channel structure, a transistor with high resistance to a short-channel effect, i.e., a transistor in which a short-channel effect is unlikely to occur, can be obtained.

When the transistor included in the semiconductor device of this embodiment has the above-described s-channel structure, the channel formation region can be electrically surrounded. Since the s-channel structure is a structure with the electrically surrounded channel formation region, the s-channel structure is, in a sense, equivalent to a GAA (Gate All Around) structure or an LGAA (Lateral Gate All Around) structure. In the transistor having the s-channel structure, the GAA structure, or the LGAA structure, the channel formation region that is formed at the interface between a metal oxide and a gate insulator or in the vicinity of the interface can be the entire bulk of the metal oxide. Accordingly, the density of current flowing through the transistor can be improved, which can be expected to improve the on-state current of the transistor or increase the field-effect mobility of the transistor.

Although FIG. 2B illustrates a transistor with the s-channel structure as the transistor, the semiconductor device of one embodiment of the present invention is not limited thereto. For example, a transistor structure that can be used in one embodiment of the present invention may be one or more selected from the planar structure, the Fin-type structure, and the GAA structure.

Note that a cross-sectional shape of the metal oxide 230 may have a curved surface between its side surface and top surface as illustrated in FIG. 2B. Thus, coverage with a film formed over the metal oxide 230 can be improved.

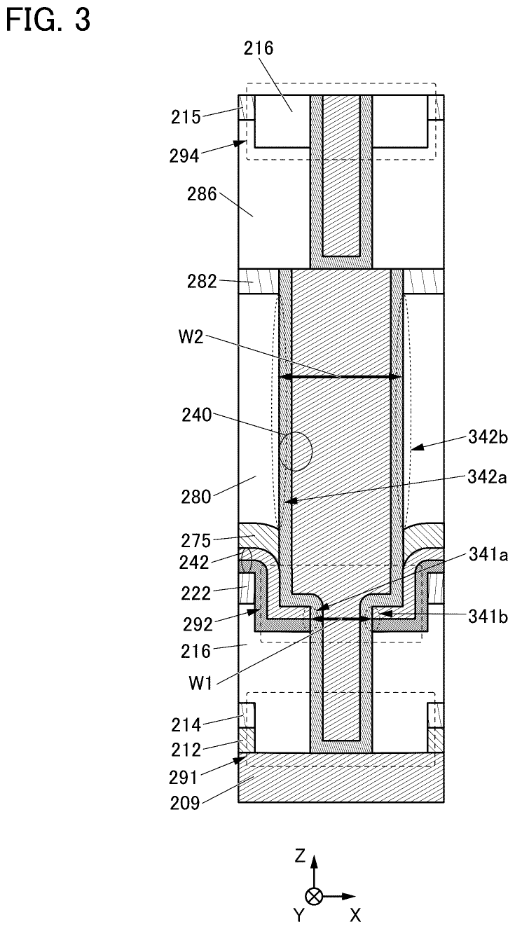

FIG. 3 is an enlarged view of a part of the conductor 240 and its peripheral region. In FIG. 3, the width of a region of the conductor 240 in contact with the side surface of the conductor 242 in a cross-sectional view (e.g., a length in the direction perpendicular to the region) is referred to as a width W1, and the width of a region of the conductor 240 in contact with the side surface of the insulator 280 in the cross-sectional view (e.g., a length in the direction perpendicular to the region) is referred to as a width W2. In other words, the distance between a region 341a in contact with the side surface of the conductor 242 and a region 341b that faces the region 341a and is in contact with the side surface of the conductor 242 in the conductor 240 in the cross-sectional view is referred to as the width W1. The distance between a region 342a in contact with the side surface of the insulator 280 and a region 342b that faces the region 342a and is in contact with the side surface of the insulator 280 in the conductor 240 in the cross-sectional view is referred to as the width W2.

As illustrated in FIG. 3, there is preferably a region where the width W2 is larger than the width W1. In this structure, the conductor 240 is in contact with both the top surface and the side surface of the conductor 242. Thus, the structure can have a larger area of a region where the conductor 240 is in contact with the conductor 242 than a structure in which the conductor 240 is in contact with, for example, only one of the top surface and the side surface of the conductor 242. In this specification and the like, the structure in which the conductor 240 is in contact with both the top surface and the side surface of the conductor 242 is sometimes referred to as a top side contact.

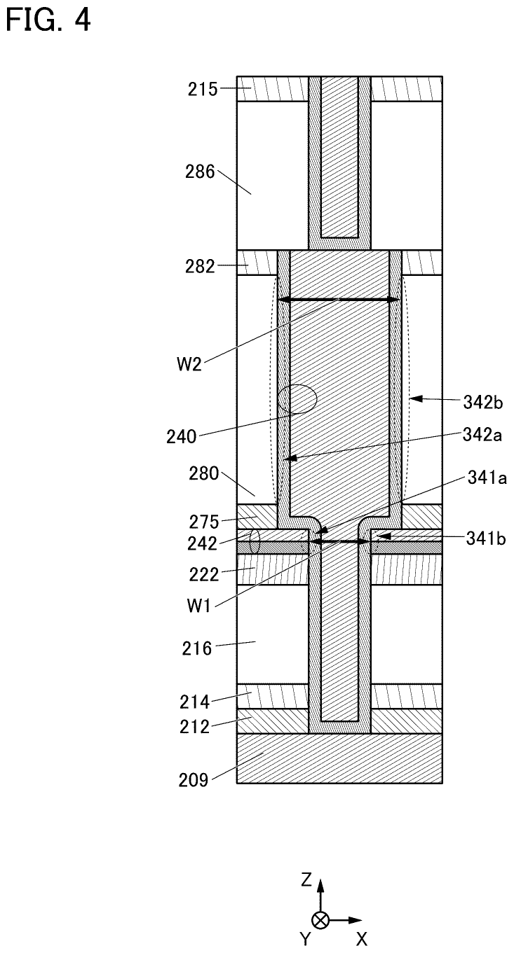

FIG. 4 illustrates a modification example of the structure illustrated in FIG. 3. In this example, at least a part of the side surface of the insulator 212, at least a part of the side surface of the insulator 214, at least a part of the side surface of the insulator 222, and at least a part of the side surface of the insulator 215 are in contact with the conductor 240.

In the example illustrated in FIG. 4, in a cross-sectional view, end portions of the insulator 212 and the insulator 214 are aligned or substantially aligned with an end portion of the insulator 216, and the end portion of the insulator 212 and the end portion of the insulator 214 are not covered with the insulator 216. In the cross-sectional view, an end portion of the insulator 222 is aligned or substantially aligned with an end portion of the conductor 242, and the end portion of the insulator 222 is not covered with the conductor 242. Although not illustrated in FIG. 4, in the cross-sectional view, an end portion of the insulator 215 is aligned or substantially aligned with an end portion of the insulator 216 over the insulator 215, and the end portion of the insulator 215 is not covered with the insulator 216. In the example illustrated in FIG. 4, the end portion of the insulator 212, the end portion of the insulator 214, the end portion of the insulator 216, the end portion of the insulator 222, the end portion of the conductor 242, an end portion of the insulator 286, and the end portion of the insulator 215 can be aligned or substantially aligned with each other in the cross-sectional view. In addition, an end portion of the insulator 275, an end portion of the insulator 280, and an end portion of the insulator 282 can be aligned or substantially aligned with each other in the cross-sectional view.

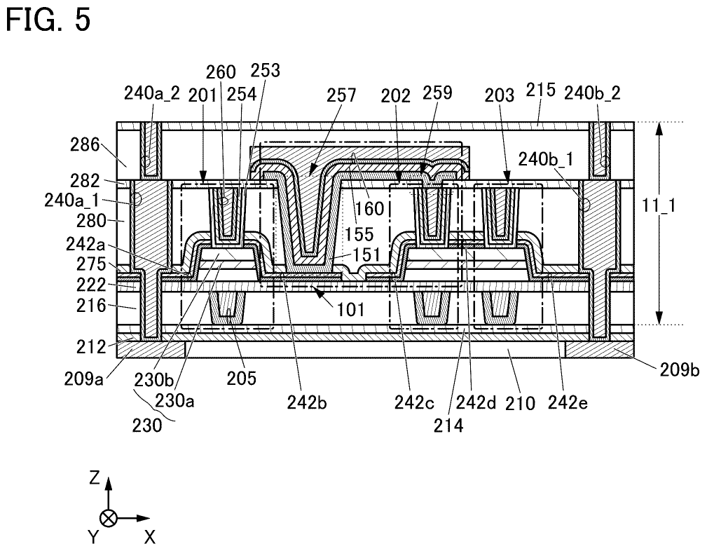

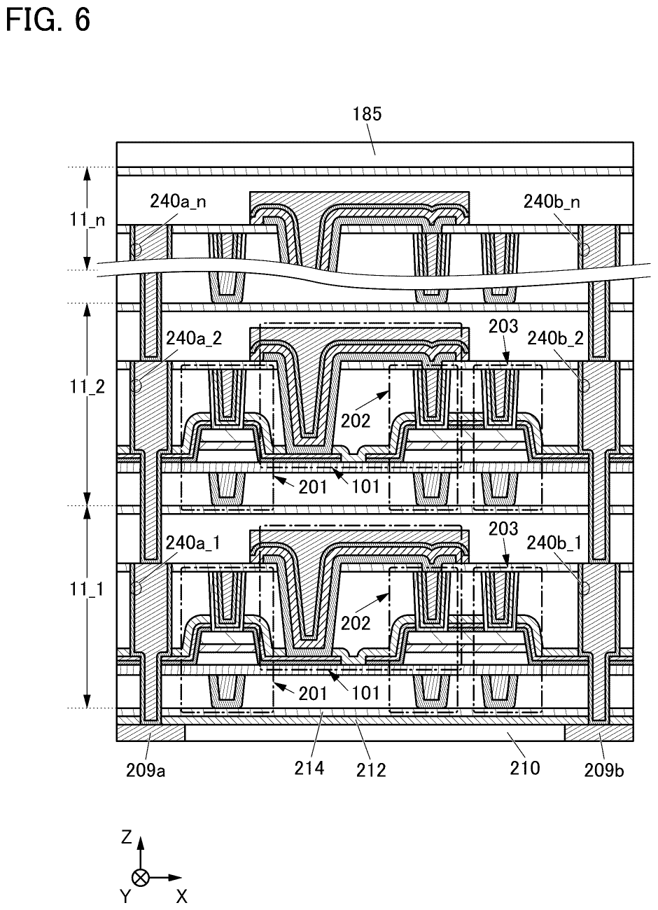

FIG. 5 is a modification example of the structure illustrated in FIG. 2A and employs the structure illustrated in FIG. 4 for the conductor 240a_1, the conductor 240b_1, and the peripheral components. FIG. 6 is a modification example of the structure illustrated in FIG. 1 and employs the structure illustrated in FIG. 4 for the conductor 240a_1 to the conductor 240a_n, the conductor 240b_1 to the conductor 240b_n, and the peripheral components.

Next, the transistors included in the semiconductor device of this embodiment will be described in detail.

The metal oxide 230 preferably includes the metal oxide 230a over the insulator 224 and the metal oxide 230b over the metal oxide 230a. Including the metal oxide 230a under the metal oxide 230b makes it possible to inhibit diffusion of impurities into the metal oxide 230b from components formed below the metal oxide 230a.

Although an example in which the metal oxide 230 has a two-layer structure of the metal oxide 230a and the metal oxide 230b is described in this embodiment, the present invention is not limited thereto. For example, the metal oxide 230 may have a single-layer structure of the metal oxide 230b or a stacked-layer structure of three or more layers.

The metal oxide 230b includes a channel formation region of each transistor and a source region and a drain region provided to sandwich the channel formation region. At least a part of the channel formation region overlaps with the conductor 260. The source region overlaps with one of a pair of conductors 242, and the drain region overlaps with the other of the pair of conductors 242.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (low-resistance region) having a higher carrier concentration than the channel formation region.

Note that the carrier concentration of the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1×10⁻⁹ cm⁻³.

In order to reduce the carrier concentration in the metal oxide 230b, the impurity concentration in the metal oxide 230b is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration may be referred to as a highly purified intrinsic or substantially highly purified intrinsic oxide semiconductor (or metal oxide).

In order to obtain stable electrical characteristics of the transistor, reducing the impurity concentration in the metal oxide 230b is effective. In order to reduce the impurity concentration in the metal oxide 230b, it is preferable that the impurity concentration in an adjacent film be also reduced. Examples of impurities include hydrogen, nitrogen, an alkali metal, an alkaline earth metal, iron, nickel, and silicon. Note that an impurity in the metal oxide 230b refers to, for example, an element other than the main components of the metal oxide 230b. For example, an element with a concentration lower than 0.1 atomic % can be regarded as an impurity.

Note that the channel formation region, the source region, and the drain region may each be formed not only in the metal oxide 230b but also in the metal oxide 230a.

In the metal oxide 230, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

A metal oxide functioning as a semiconductor (hereinafter, also referred to as an oxide semiconductor) is preferably used as the metal oxide 230.

The metal oxide functioning as a semiconductor preferably has a band gap of 2 eV or more, further preferably 2.5 eV or more. With the use of a metal oxide having a wide band gap, the off-state current of the transistor can be reduced.

As the metal oxide 230, a metal oxide such as indium oxide, gallium oxide, or zinc oxide is preferably used, for example. Alternatively, as the metal oxide 230, a metal oxide containing two or three selected from indium, an element M, and zinc is preferably used, for example. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin. Note that a metal oxide containing indium, the element M, and zinc is referred to as In-M-Zn oxide in some cases.

The metal oxide 230 preferably has a stacked-layer structure of a plurality of oxide layers with different chemical compositions. For example, the atomic ratio of the element M to a metal element that is a main component in the metal oxide used as the metal oxide 230a is preferably higher than the atomic ratio of the element M to a metal element that is a main component in the metal oxide used as the metal oxide 230b. Moreover, the atomic ratio of the element M to In in the metal oxide used as the metal oxide 230a is preferably higher than the atomic ratio of the element M to In in the metal oxide used as the metal oxide 230b. With this structure, impurities and oxygen can be inhibited from diffusing into the metal oxide 230b from the components formed below the metal oxide 230a.

Furthermore, the atomic ratio of In to the element M in the metal oxide used as the metal oxide 230b is preferably higher than the atomic ratio of In to the element M in the metal oxide used as the metal oxide 230a. With this structure, the transistor can have a high on-state current and high frequency characteristics.

When the metal oxide 230a and the metal oxide 230b contain a common element as the main component besides oxygen, the density of defect states at an interface between the metal oxide 230a and the metal oxide 230b can be decreased. The density of defect states at the interface between the metal oxide 230a and the metal oxide 230b can be decreased. Thus, the influence of interface scattering on carrier conduction is small, and the transistor can have a high on-state current and high frequency characteristics.

Specifically, as the metal oxide 230a, a metal oxide with a composition of In:M:Zn=1:3:4 [atomic ratio] or in the neighborhood thereof or a composition of In:M:Zn=1:1:0.5 [atomic ratio] or in the neighborhood thereof can be used. As the metal oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of +30% of an intended atomic ratio. Gallium is preferably used as the element M. In the case where a single layer of the metal oxide 230b is provided as the metal oxide 230, a metal oxide that can be used as the metal oxide 230a may be used as the metal oxide 230b. The compositions of the metal oxide 230a and the metal oxide 230b are not limited to the above. For example, the above composition of the metal oxide 230a may be employed for the metal oxide 230b. Similarly, the above composition of the metal oxide 230b may be employed for the metal oxide 230a.

When the metal oxide is deposited by a sputtering method, the above atomic ratio is not limited to the atomic ratio of the deposited metal oxide and may be the atomic ratio of a sputtering target used for depositing the metal oxide.

The metal oxide 230b preferably has crystallinity. It is particularly preferable to use a CAAC-OS (c-axis aligned crystalline oxide semiconductor) as the metal oxide 230b.

The CAAC-OS is a metal oxide having a dense structure with high crystallinity and small amounts of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as the CAAC-OS, is used as the metal oxide 230b, oxygen extraction from the metal oxide 230b by the source electrode or the drain electrode can be inhibited. This can reduce oxygen extraction from the metal oxide 230b even when heat treatment is performed; thus, the transistor is stable with respect to high temperatures in a manufacturing process (what is called thermal budget).

A transistor using an oxide semiconductor is likely to have its electrical characteristics changed by impurities and oxygen vacancies in a region where a channel is formed in the oxide semiconductor, which might reduce the reliability. In some cases, a defect that is an oxygen vacancy into which hydrogen in the vicinity of the oxygen vacancy has entered (hereinafter, also referred to as V_{O}H) is formed, which generates an electron serving as a carrier. Therefore, when the region where a channel is formed in the oxide semiconductor includes oxygen vacancies, the transistor is likely to have normally-on characteristics (characteristics with which, even when no voltage is applied to the gate electrode, the channel exists and current flows through the transistor). Therefore, impurities, oxygen vacancies, and V_{O}H are preferably reduced as much as possible in the region where a channel is formed in the oxide semiconductor. In other words, the region where a channel is formed in the oxide semiconductor is preferably an i-type (intrinsic) or substantially i-type region with a reduced carrier concentration.

As a countermeasure against the above, an insulator containing oxygen that is released by heating (hereinafter, also referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor. Furthermore, a variation in the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the channel formation region is preferably an i-type or substantially i-type region with a reduced carrier concentration, whereas the source region and the drain region are preferably n-type regions with high carrier concentrations. That is, the amounts of oxygen vacancies and V_{O}H in the channel formation region of the oxide semiconductor are preferably reduced. Supply of an excess amount of oxygen to the source region and the drain region and excessive reduction in the amount of V_{O}H in the source region and the drain region are preferably inhibited. Furthermore, a structure is preferable in which a reduction in the conductivity of the conductor 260, the conductor 242, and the like is inhibited. For example, a structure is preferable in which oxidation of the conductor 260, the conductor 242, and the like is inhibited. Note that hydrogen in the oxide semiconductor can form V_{O}H; thus, the hydrogen concentration needs to be reduced in order to reduce the amount of V_{O}H.

The semiconductor device of this embodiment thus has a structure in which the hydrogen concentration in the channel formation region is reduced, oxidation of the conductor 242 and the conductor 260 is inhibited, and a reduction in the hydrogen concentration in the source region and the drain region is inhibited.

The insulator 253 in contact with the channel formation region of the metal oxide 230b preferably has a function of capturing and fixing hydrogen. Thus, the hydrogen concentration in the channel formation region of the metal oxide 230b can be reduced. Accordingly, V_{O}H in the channel formation region can be reduced, so that the channel formation region can be an i-type or substantially i-type region.

Examples of an insulator having a function of capturing and fixing hydrogen include a metal oxide having an amorphous structure. As the insulator 253, for example, a metal oxide, such as magnesium oxide or an oxide containing one or both of aluminum and hafnium, is preferably used. In such a metal oxide having an amorphous structure, an oxygen atom has a dangling bond and sometimes has a property of capturing or fixing hydrogen with the dangling bond. That is, the metal oxide having an amorphous structure has high capability of capturing or fixing hydrogen.

A high dielectric constant (high-k) material is preferably used for the insulator 253. An example of the high-k material is an oxide containing one or both of aluminum and hafnium. With the use of the high-k material for the insulator 253, a gate potential applied during the operation of the transistor can be reduced while the physical thickness of the gate insulator is maintained. In addition, the equivalent oxide thickness (EOT) of the insulator functioning as the gate insulator can be reduced.

As described above, for the insulator 253, an oxide containing one or both of aluminum and hafnium is preferably used, an oxide containing one or both of aluminum and hafnium and having an amorphous structure is further preferably used, and hafnium oxide having an amorphous structure is still further preferably used. In this embodiment, hafnium oxide is used for the insulator 253. In that case, the insulator 253 is an insulator that contains at least oxygen and hafnium. The hafnium oxide has an amorphous structure. In that case, the insulator 253 has an amorphous structure.

Alternatively, as the insulator 253, an insulator having a thermally stable structure, such as silicon oxide or silicon oxynitride, may be used. For example, the insulator 253 may have a stacked-layer structure including aluminum oxide and silicon oxide or silicon oxynitride over the aluminum oxide. For another example, the insulator 253 may have a stacked-layer structure including aluminum oxide, silicon oxide or silicon oxynitride over the aluminum oxide, and hafnium oxide over the silicon oxide or silicon oxynitride.

In order to inhibit oxidation of the conductor 242 and the conductor 260, a barrier insulator against oxygen is preferably provided in the vicinity of each of the conductor 242 and the conductor 260. In the semiconductor device described in this embodiment, the insulator corresponds to the insulator 253, the insulator 254, and the insulator 275, for example.

Note that in this specification and the like, a barrier insulator refers to an insulator having a barrier property. A barrier property in this specification and the like means a function of inhibiting diffusion of a targeted substance (also referred to as having low permeability). Alternatively, the barrier property means a function of capturing and fixing (also referred to as gettering) a targeted substance.

Examples of the barrier insulator against oxygen include an oxide containing one or both of aluminum and hafnium, magnesium oxide, gallium oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate). For example, each of the insulator 253, the insulator 254, and the insulator 275 preferably has a single-layer structure or a stacked-layer structure of the barrier insulator against oxygen.

The insulator 253 preferably has a barrier property against oxygen. It is preferable that oxygen be less likely to pass through the insulator 253 than at least the insulator 280. The insulator 253 includes a region in contact with the side surface of the conductor 242. When the insulator 253 has a barrier property against oxygen, oxidation of the side surface of the conductor 242 and formation of an oxide film on the side surface can be inhibited. Accordingly, a decrease in the on-state current or field-effect mobility of the transistor can be inhibited.

The insulator 253 is provided in contact with the top surface and the side surface of the metal oxide 230b, the side surface of the metal oxide 230a, the side surface of the insulator 224, and the top surface of the insulator 222. When the insulator 253 has a barrier property against oxygen, release of oxygen from the channel formation region of the metal oxide 230b caused by heat treatment can be inhibited, for example. This can reduce formation of oxygen vacancies in the metal oxide 230a and the metal oxide 230b.

Even when an excess amount of oxygen is contained in the insulator 280, oxygen can be inhibited from being excessively supplied to the metal oxide 230a and the metal oxide 230b. Thus, it is possible to inhibit excessive oxidation of the source region and the drain region and a decrease in the on-state current or field-effect mobility of the transistor.

The oxide containing one or both of aluminum and hafnium has a barrier property against oxygen and thus can be suitably used for the insulator 253.

The insulator 254 preferably has a barrier property against oxygen. The insulator 254 is provided between the conductor 260 and the channel formation region of the metal oxide 230 and between the insulator 280 and the conductor 260. Such a structure can inhibit diffusion of oxygen contained in the channel formation region of the metal oxide 230 into the conductor 260 and formation of oxygen vacancies in the channel formation region of the metal oxide 230. Oxygen contained in the metal oxide 230 and oxygen contained in the insulator 280 can be inhibited from diffusing into the conductor 260 and oxidizing the conductor 260. It is preferable that oxygen be less likely to pass through the insulator 254 than at least the insulator 280. For example, silicon nitride is preferably used for the insulator 254. In that case, the insulator 254 is an insulator that contains at least nitrogen and silicon.

The insulator 254 preferably has a barrier property against hydrogen. Accordingly, diffusion of impurities contained in the conductor 260, such as hydrogen, into the metal oxide 230b can be prevented.

The insulator 275 preferably has a barrier property against oxygen. The insulator 275 is provided between the insulator 280 and the conductor 242. With this structure, oxygen contained in the insulator 280 can be inhibited from diffusing into the conductor 242. Thus, the conductor 242 can be inhibited from being oxidized by oxygen contained in the insulator 280, so that an increase in resistivity and a reduction in on-state current can be inhibited. It is preferable that oxygen be less likely to pass through the insulator 275 than at least the insulator 280. For example, silicon nitride is preferably used for the insulator 275. In that case, the insulator 275 is an insulator that contains at least nitrogen and silicon.

In order to inhibit a reduction in hydrogen concentration in the source region and the drain region in the metal oxide 230, a barrier insulator against hydrogen is preferably provided in the vicinity of each of the source region and the drain region. In the semiconductor device described in this embodiment, the barrier insulator against hydrogen is, for example, the insulator 275.

Examples of the barrier insulator against hydrogen include oxides such as aluminum oxide, hafnium oxide, and tantalum oxide and nitrides such as silicon nitride. For example, the insulator 275 preferably has a single-layer structure or a stacked-layer structure of the above barrier insulator against hydrogen.

The insulator 275 preferably has a barrier property against hydrogen. When the insulator 275 has a barrier property against hydrogen, capturing and fixing of hydrogen in the source region and the drain region by the insulator 253 can be inhibited. Thus, the source region and the drain region can be n-type regions.

With the above structure, the channel formation region can be an i-type or substantially i-type region, and the source region and the drain region can be n-type regions; thus, a semiconductor device with excellent electrical characteristics can be provided. The semiconductor device with the above structure can have excellent electrical characteristics even when scaled down or highly integrated. Scaling down of the transistor can improve the high-frequency characteristics. Specifically, the cutoff frequency can be improved.

The insulator 253 and the insulator 254 each function as a part of a gate insulator. The insulator 253 and the insulator 254 are provided together with the conductor 260 in an opening formed in the insulator 280 and the like. The thickness of the insulator 253 and the thickness of the insulator 254 are preferably small for scaling down of the transistor. The thickness of the insulator 253 is preferably greater than or equal to 0.1 nm and less than or equal to 5.0 nm, further preferably greater than or equal to 0.5 nm and less than or equal to 5.0 nm, still further preferably greater than or equal to 1.0 nm and less than 5.0 nm, yet still further preferably greater than or equal to 1.0 nm and less than or equal to 3.0 nm. The thickness of the insulator 254 is preferably greater than or equal to 0.1 nm and less than or equal to 5.0 nm, further preferably greater than or equal to 0.5 nm and less than or equal to 3.0 nm, still further preferably greater than or equal to 1.0 nm and less than or equal to 3.0 nm. Note that at least a part of each of the insulator 253 and the insulator 254 includes a region having the above-described thickness.

To form the insulator 253 having a small thickness as described above, an atomic layer deposition (ALD) method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because deposition at a lower temperature is possible.

An ALD method, which enables atomic layers to be deposited one by one, has advantages such as formation of an extremely thin film, film formation on a component with a high aspect ratio, formation of a film with a small number of defects such as pinholes, film formation with excellent coverage, and low-temperature film formation. Therefore, the insulator 253 can be formed on the side surface of the opening portion formed in the insulator 280 and the like, the side end portion of the conductor 242, and the like, with a small thickness like the above-described thickness and good coverage.

Note that some of precursors usable in an ALD method contain carbon, for example. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

For example, silicon nitride deposited by a PEALD method can be used for the insulator 254.

Note that when an insulator having a function of inhibiting passage of oxygen and impurities such as hydrogen, e.g., hafnium oxide, is used as the insulator 253, the insulator 253 can also have the function of the insulator 254. In such a case, the structure without the insulator 254 enables simplification of the manufacturing process and the improvement in productivity of the semiconductor device.

In addition to the above structure, the semiconductor device of this embodiment preferably has a structure in which hydrogen is inhibited from entering the transistor. For example, an insulator having a function of inhibiting diffusion of hydrogen is preferably provided to cover one or both of the upper portion and the lower portion of the transistor. In the semiconductor device described in this embodiment, the insulator is, for example, the insulator 212.

As the insulator 212, an insulator having a function of inhibiting diffusion of hydrogen is preferably used. This can inhibit diffusion of hydrogen into the transistor from below the insulator 212. As the insulator 212, the above-described insulator that can be used as the insulator 275 can be used.

One or more of the insulator 212, the insulator 214, the insulator 282, and the insulator 215 preferably function as a barrier insulating film, which inhibits diffusion of impurities such as water and hydrogen into the transistor from the substrate side or from above the transistor. Thus, one or more of the insulator 212, the insulator 214, and the insulator 282 preferably contain an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), or a copper atom (an insulating material through which the impurities are less likely to pass). Alternatively, it is preferable to contain an insulating material having a function of inhibiting diffusion of oxygen (e.g., at least one of an oxygen atom, an oxygen molecule, and the like) (an insulating material through which the oxygen is less likely to pass).

The insulator 212, the insulator 214, the insulator 282, and the insulator 215 each preferably include an insulator having a function of inhibiting diffusion of oxygen and impurities such as water and hydrogen; for example, aluminum oxide, magnesium oxide, hafnium oxide, gallium oxide, indium gallium zinc oxide, silicon nitride, silicon nitride oxide, or the like can be used. For example, silicon nitride, which has a higher hydrogen barrier property, is preferably used for the insulator 212. For example, the insulator 212, the insulator 214, and the insulator 282 each preferably contain aluminum oxide, magnesium oxide, or the like, which has an excellent function of capturing and fixing hydrogen. Accordingly, impurities such as water and hydrogen can be inhibited from diffusing from the substrate side to the transistor side through the insulator 212 and the insulator 214. Furthermore, impurities such as water and hydrogen can be inhibited from diffusing to the transistor side from an interlayer insulating film and the like placed outside the insulator 282. Moreover, oxygen contained in the insulator 224 and the like can be inhibited from diffusing to the substrate side. In addition, oxygen contained in the insulator 280 and the like can be inhibited from diffusing to the components over the transistor through the insulator 282 and the like. In this manner, it is preferable that the transistor be surrounded by the insulators having a function of inhibiting diffusion of oxygen and impurities such as water and hydrogen.

The conductor 205 is placed to overlap with the metal oxide 230 and the conductor 260. Here, the conductor 205 is preferably provided to be embedded in an opening portion formed in the insulator 216. A part of the conductor 205 is embedded in the insulator 214 in some cases.

The conductor 205 may have either a single-layer structure or a stacked-layer structure. For example, FIG. 2A illustrates an example in which the conductor 205 has a two-layer stacked structure of a first conductor and a second conductor. The first conductor of the conductor 205 is provided in contact with the bottom surface and sidewall of the opening portion provided in the insulator 216. The second conductor of the conductor 205 is provided to be embedded in a depressed portion formed in the first conductor of the conductor 205. Here, the top surface of the second conductor of the conductor 205 is substantially level with the top surface of the first conductor of the conductor 205 and the top surface of the insulator 216.

Here, the first conductor of the conductor 205 preferably contains a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to contain a conductive material having a function of inhibiting diffusion of oxygen (e.g., at least one of an oxygen atom, an oxygen molecule, and the like).

When a conductive material having a function of inhibiting diffusion of hydrogen is used for the first conductor of the conductor 205, impurities such as hydrogen contained in the second conductor of the conductor 205 can be prevented from diffusing into the metal oxide 230 through the insulator 216, the insulator 224, and the like. When a conductive material having a function of inhibiting diffusion of oxygen is used for the first conductor of the conductor 205, the conductivity of the second conductor of the conductor 205 can be inhibited from being lowered because of oxidation. Examples of the conductive material having a function of inhibiting diffusion of oxygen include titanium, titanium nitride, tantalum, tantalum nitride, ruthenium, and ruthenium oxide. The first conductor of the conductor 205 can have a single-layer structure or a stacked-layer structure of the above conductive material. For example, the first conductor of the conductor 205 preferably contains titanium nitride.

A conductive material containing tungsten, copper, or aluminum as its main component is preferably used for the second conductor of the conductor 205. For example, the second conductor of the conductor 205 preferably contains tungsten.

The conductor 205 can function as the second gate electrode. In that case, by changing a potential applied to the conductor 205 not in conjunction with but independently of a potential applied to the conductor 260, the threshold voltage (Vth) of the transistor can be controlled. In particular, by applying a negative potential to the conductor 205, Vth of the transistor can be higher, and its off-state current can be reduced. Thus, a drain current at the time when a potential applied to the conductor 260 is 0 V can be lower in the case where a negative potential is applied to the conductor 205 than in the case where the negative potential is not applied to the conductor 205.

The electrical resistivity of the conductor 205 is designed in consideration of the potential applied to the conductor 205, and the thickness of the conductor 205 is set in accordance with the electrical resistivity. The thickness of the insulator 216 is substantially equal to the thickness of the conductor 205. Here, the conductor 205 and the insulator 216 are preferably as thin as possible in the allowable range of the design of the conductor 205. When the thickness of the insulator 216 is reduced, the absolute amount of impurities such as hydrogen contained in the insulator 216 can be reduced, so that diffusion of the impurities into the metal oxide 230 can be reduced.

The insulator 222 and the insulator 224 function as a gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

The insulator 222 preferably includes an insulator containing an oxide of one or both of aluminum and hafnium, which is an insulating material. For the insulator, aluminum oxide, hafnium oxide, an oxide containing aluminum and hafnium (hafnium aluminate), or the like is preferably used. Alternatively, an oxide containing hafnium and zirconium, e.g., a hafnium zirconium oxide, is preferably used. In the case where the insulator 222 is formed using such a material, the insulator 222 functions as a layer that inhibits release of oxygen from the metal oxide 230 to the substrate side and diffusion of impurities such as hydrogen from the periphery of the transistor into the metal oxide 230. Thus, providing the insulator 222 can inhibit diffusion of impurities such as hydrogen to the inside of the transistor and inhibit generation of oxygen vacancies in the metal oxide 230. Moreover, the first conductor of the conductor 205 can be inhibited from reacting with oxygen contained in the insulator 224 and the metal oxide 230.

Alternatively, aluminum oxide, bismuth oxide, germanium oxide, niobium oxide, silicon oxide, titanium oxide, tungsten oxide, yttrium oxide, or zirconium oxide may be added to the above insulators, for example. Alternatively, these insulators may be subjected to nitriding treatment. A stack of silicon oxide, silicon oxynitride, or silicon nitride over the above insulators may be used for the insulator 222.

For example, the insulator 222 may have a single-layer structure or a stacked-layer structure of an insulator(s) containing what is called a high-k material such as aluminum oxide, hafnium oxide, tantalum oxide, zirconium oxide, or hafnium zirconium oxide. As scaling down and high integration of transistors progress, a problem such as leakage current may arise because of a thinner gate insulator. When a high-k material is used for the insulator functioning as a gate insulator, a gate potential at the time of the operation of the transistor can be reduced while the physical thickness is maintained. Furthermore, a substance with a high dielectric constant such as lead zirconate titanate (PZT), strontium titanate (SrTiO₃), or (Ba,Sr)TiO₃ (BST) can be used for the insulator 222 in some cases.

The insulator 224 that is in contact with the metal oxide 230 preferably contains silicon oxide or silicon oxynitride, for example.

Note that the insulator 222 and the insulator 224 may each have a stacked-layer structure of two or more layers. In that case, without limitation to a stacked-layer structure formed of the same material, a stacked-layer structure formed of different materials may be employed.

A conductive material that is not easily oxidized or a conductive material having a function of inhibiting oxygen diffusion is preferably used for each of the conductor 242 and the conductor 260. Examples of the conductive material include a conductive material containing nitrogen and a conductive material containing oxygen. This can inhibit a reduction in the conductivity of the conductor 242 and the conductor 260. In the case where a conductive material containing metal and nitrogen is used for the conductor 242 and the conductor 260, the conductor 242 and the conductor 260 are conductors that contain at least metal and nitrogen.

The conductor 242 may have a single-layer structure or a stacked-layer structure. The conductor 260 may have a single-layer structure or a stacked-layer structure.

For example, the conductor 242 illustrated in FIG. 2A has a two-layer structure of a first conductor and a second conductor over the first conductor. In that case, for the first conductor of the conductor 242 in contact with the metal oxide 230b, it is preferable to use a conductive material that is not easily oxidized or a conductive material having a function of inhibiting oxygen diffusion. Thus, the conductivity of the conductor 242 can be inhibited from being reduced. For the first conductor of the conductor 242, a material that is likely to absorb (extract) hydrogen is preferably used, in which case the hydrogen concentration in the metal oxide 230 can be reduced.

The second conductor of the conductor 242 preferably has higher conductivity than the first conductor of the conductor 242. For example, the thickness of the second conductor of the conductor 242 is preferably larger than the thickness of the first conductor of the conductor 242.

For example, tantalum nitride or titanium nitride can be used for the first conductor of the conductor 242, and tungsten can be used for the second conductor of the conductor 242.

To inhibit a reduction in the conductivity of the conductor 242, an oxide having crystallinity, such as a CAAC-OS, is preferably used as the metal oxide 230b. Specifically, a metal oxide containing indium, zinc, and one or more selected from gallium, aluminum, and tin is preferably used. When a CAAC-OS is used, oxygen extraction from the metal oxide 230b by the conductor 242 can be inhibited. Furthermore, it is possible to inhibit a reduction in the conductivity of the conductor 242.

As the conductor 242, for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. For another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

Note that, for example, hydrogen contained in the metal oxide 230b diffuses into the conductor 242 in some cases. In particular, when a nitride containing tantalum is used for the conductor 242, for example, hydrogen contained in the metal oxide 230b is likely to diffuse into the conductor 242, and the diffused hydrogen is bonded to nitrogen contained in the conductor 242 in some cases. That is, hydrogen contained in the metal oxide 230b or the like is sometimes absorbed by the conductor 242, for example.

The conductor 260 is placed such that its top surface is substantially level with the uppermost portion of the insulator 254, the uppermost portion of the insulator 253, and the top surface of the insulator 280.

The conductor 260 functions as the first gate electrode of the transistor. The conductor 260 preferably includes a first conductor and a second conductor over the first conductor. For example, the first conductor of the conductor 260 is preferably placed to cover the bottom surface and the side surface of the second conductor of the conductor 260.

For example, the conductor 260 illustrated in FIG. 2A has a two-layer structure. In that case, for the first conductor of the conductor 260, it is preferable to use a conductive material that is not easily oxidized or a conductive material having a function of inhibiting oxygen diffusion.

For the first conductor of the conductor 260, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

In addition, when the first conductor of the conductor 260 has a function of inhibiting oxygen diffusion, for example, the conductivity of the second conductor of the conductor 260 can be inhibited from being lowered because of oxidation due to oxygen contained in the insulator 280. As the conductive material having a function of inhibiting oxygen diffusion, for example, titanium, titanium nitride, tantalum, tantalum nitride, ruthenium, or ruthenium oxide is preferably used.

As the conductor 260, a conductor having high conductivity is preferably used. For example, a conductive material containing tungsten, copper, or aluminum as its main component can be used for the second conductor of the conductor 260. The second conductor of the conductor 260 may have a stacked-layer structure; for example, a stacked-layer structure of the conductive material and titanium or titanium nitride may be employed.

In the transistor, the conductor 260 is formed in a self-aligned manner to fill the opening formed in the insulator 280, for example. The formation of the conductor 260 in this manner allows the conductor 260 to be placed properly in a region between the pair of conductors 242 without alignment.

The dielectric constant of each of the insulator 216, the insulator 280, the insulator 286, and the insulator 185 is preferably lower than that of the insulator 214. When a material with a low dielectric constant is used for an interlayer film, parasitic capacitance generated between wirings can be reduced.

For example, the insulator 216, the insulator 280, the insulator 286, and the insulator 185 each preferably contain one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride, which are thermally stable, are preferable. A material such as silicon oxide, silicon oxynitride, or porous silicon oxide is particularly preferably used, in which case a region containing oxygen released by heating can be easily formed.

The top surfaces of the insulator 216, the insulator 280, the insulator 286, and the insulator 185 may be planarized.

The concentration of impurities such as water and hydrogen in the insulator 280 is preferably reduced. For example, the insulator 280 preferably contains an oxide containing silicon, such as silicon oxide or silicon oxynitride.

Note that in the opening portion of the insulator 280, the sidewall of the insulator 280 may be substantially perpendicular to the top surface of the insulator 222 or may have a tapered shape. The tapered sidewall can improve the coverage with the insulator 253 provided in the opening portion of the insulator 280, for example; as a result, the number of defects such as voids can be reduced.

Note that in this specification and the like, a tapered shape refers to a shape such that at least a part of the side surface of a component is inclined with respect to a substrate surface or a formation surface. For example, a tapered shape preferably includes a region where the angle between the inclined side surface and the substrate surface or the formation surface (hereinafter, also referred to as a taper angle) is less than 90°. Note that the side surface of the component and the substrate surface are not necessarily completely flat and may be substantially flat with a slight curvature or substantially flat with slight unevenness.

For each of the conductor 151 and the conductor 160 included in the capacitor 101, any of the materials that can be used for the conductor 205, the conductor 242, and the conductor 260 can be used. The conductor 151 and the conductor 160 are each preferably formed by a deposition method that offers good coverage, such as an ALD method or a chemical vapor deposition (CVD) method.

The conductor 160 includes a first conductor and a second conductor over the first conductor. For example, titanium nitride deposited by an ALD method can be used for the first conductor of the conductor 160, and tungsten deposited by a CVD method can be used for the second conductor of the conductor 160. Note that in the case where the adhesion of tungsten to the insulator 155 is sufficiently high, a single-layer structure of tungsten deposited by a CVD method may be used for the conductor 160.

For the insulator 155 included in the capacitor 101, a high dielectric constant (high-k) material (a material with a high relative permittivity) is preferably used. The insulator 155 is preferably formed by a deposition method that offers good coverage, such as an ALD method or a CVD method.

Examples of insulators of the high dielectric constant (high-k) material include an oxide, an oxynitride, a nitride oxide, and a nitride containing one or more kinds of metal elements selected from aluminum, hafnium, zirconium, gallium, and the like. The above-described oxide, oxynitride, nitride oxide, and nitride may contain silicon. Stacked insulators formed of any of the above-described materials can also be used.

Examples of the insulators of the high dielectric constant (high-k) material include aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, and an oxynitride containing hafnium and zirconium. Using such a high-k material allows the insulator 155 to be thick enough to inhibit leakage current and the capacitor 101 to have a sufficiently high capacitance.

It is preferable to use stacked insulators formed of any of the above-described materials, and it is preferable to use a stacked-layer structure of a high dielectric constant (high-k) material and a material having a higher dielectric strength than the high dielectric constant (high-k) material. As the insulator 155, an insulator in which zirconium oxide, aluminum oxide, and zirconium oxide are stacked in this order can be used, for example. For another example, an insulator in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. Using such stacked insulators with relatively high dielectric strength, such as aluminum oxide, can increase the dielectric strength and inhibit electrostatic breakdown of the capacitor 101.

The conductor 240 preferably has a stacked-layer structure of a first conductor and a second conductor. For example, as illustrated in FIG. 2A, a structure can be employed in which the first conductor of the conductor 240 is provided in contact with an inner wall of the opening and the second conductor is provided on the inner side. The first conductor of the conductor 240 includes a region in contact with at least parts of the top surface of the conductor 209, the side surface of the insulator 216, the top surface and the side surface of the conductor 242, the side surface of the insulator 275, the side surface of the insulator 280, and the side surface of the side surface of the insulator 282.

A conductive material having a function of inhibiting passage of impurities such as water and hydrogen is preferably used for the first conductor of the conductor 240. The first conductor of the conductor 240 can have a single-layer structure or a stacked-layer structure including one or more of tantalum, tantalum nitride, titanium, titanium nitride, ruthenium, and ruthenium oxide, for example. Thus, impurities such as water and hydrogen can be inhibited from entering the metal oxide 230 through the conductor 240.

The conductor 240 also functions as a wiring and thus is preferably formed using a conductor having high conductivity. For example, a conductive material containing tungsten, copper, or aluminum as its main component can be used for the second conductor of the conductor 240.

For example, it is preferable to use titanium nitride for the first conductor of the conductor 240 and tungsten for the second conductor of the conductor 240. In that case, the first conductor of the conductor 240 is a conductor that contains titanium and nitrogen, and the second conductor of the conductor 240 is a conductor that contains tungsten. Note that the conductor 240 may have a single-layer structure or a stacked-layer structure of three or more layers.

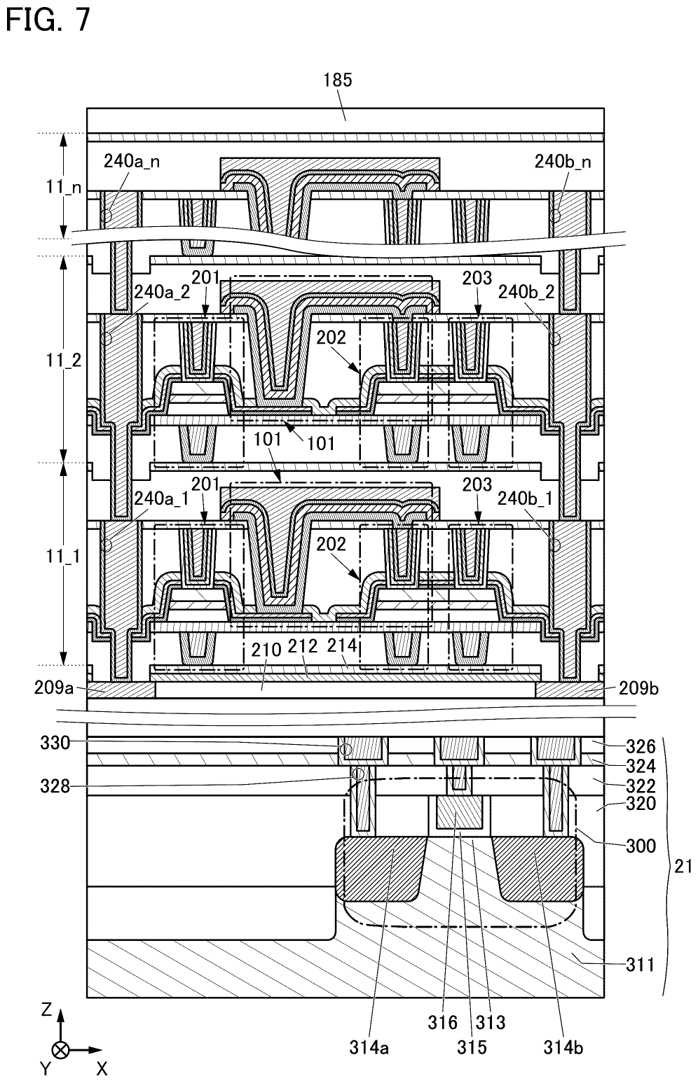

FIG. 7 is a cross-sectional view illustrating a structure example of the semiconductor device of one embodiment of the present invention. The semiconductor device illustrated in FIG. 7 is an example in which a layer 21 including a transistor 300 is provided under the structure illustrated in FIG. 1, for example. The transistor 300 can be provided in a driver circuit of a memory cell formed above the insulator 210, for example. Note that the structure above the insulator 210 in FIG. 7 is similar to that in FIG. 1; thus, the detailed description thereof is omitted.

FIG. 7 illustrates an example of the transistor 300. The transistor 300 is provided on a substrate 311 and includes a conductor 316 functioning as a gate, an insulator 315 functioning as a gate insulator, a semiconductor region 313 including a part of the substrate 311, and a low-resistance region 314a and a low-resistance region 314b functioning as a source region and a drain region. The transistor 300 may be either a p-channel transistor or an n-channel transistor. As the substrate 311, a single crystal silicon substrate can be used, for example.

Here, in the transistor 300 illustrated in FIG. 7, the semiconductor region 313 (a part of the substrate 311) in which a channel is formed has a protruding shape. The conductor 316 is provided to cover the side surface and the top surface of the semiconductor region 313 with the insulator 315 therebetween. Note that a material adjusting the work function may be used for the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing a part of the semiconductor substrate is described here, a semiconductor film having a protruding shape may be formed by processing an SOI (Silicon on Insulator) substrate.

Note that the transistor 300 illustrated in FIG. 7 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with design. Furthermore, in this specification and the like, a wiring and a plug electrically connected to the wiring may be a single component. That is, a part of a conductor functions as a wiring in some cases and a part of the conductor functions as a plug in other cases.

For example, an insulator 320, an insulator 322, an insulator 324, and an insulator 326 are stacked in this order over the transistor 300 as an interlayer film. A conductor 328 or the like is embedded in the insulator 320 and the insulator 322. A conductor 330 or the like is embedded in the insulator 324 and the insulator 326. Note that the conductor 328 and the conductor 330 function as a contact plug or a wiring.

The insulators functioning as the interlayer film may also function as a planarization film that covers an uneven shape thereunder. For example, the top surface of the insulator 322 may be planarized by planarization treatment using a chemical mechanical polishing (CMP) method or the like to have improved planarity.

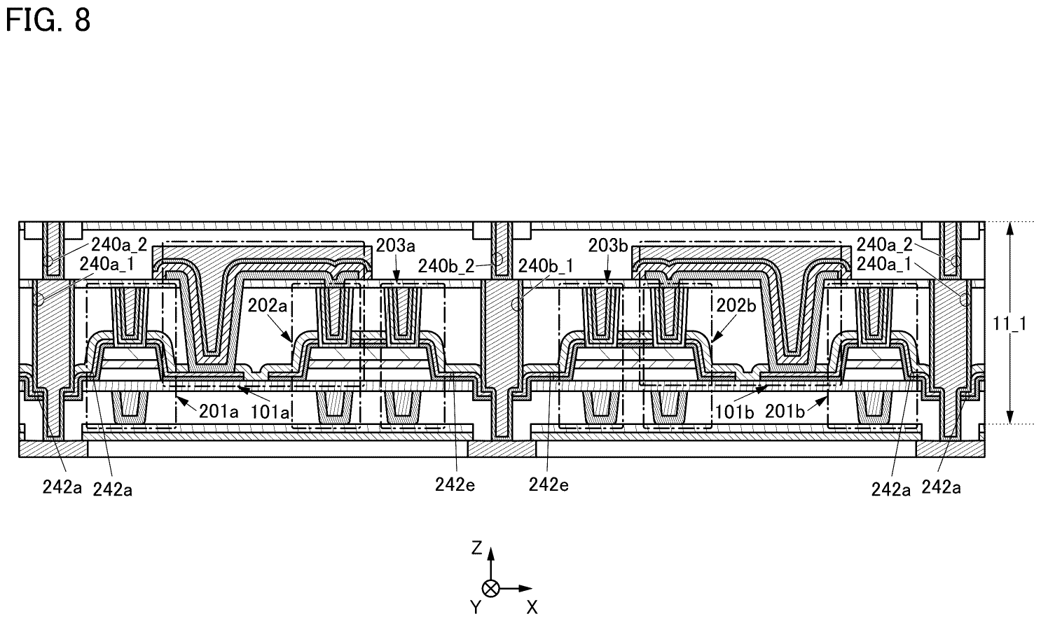

FIG. 8 is a cross-sectional view illustrating an example in which two memory cells included in the memory layer 11_1 are arranged in the X direction. FIG. 8 illustrates a memory cell including a transistor 201a, a transistor 202a, a transistor 203a, and a capacitor 101a respectively as the transistor 201, the transistor 202, the transistor 203, and the capacitor 101, and a memory cell including a transistor 201b, a transistor 202b, a transistor 203b, and a capacitor 101b respectively as the transistor 201, the transistor 202, the transistor 203, and the capacitor 101.

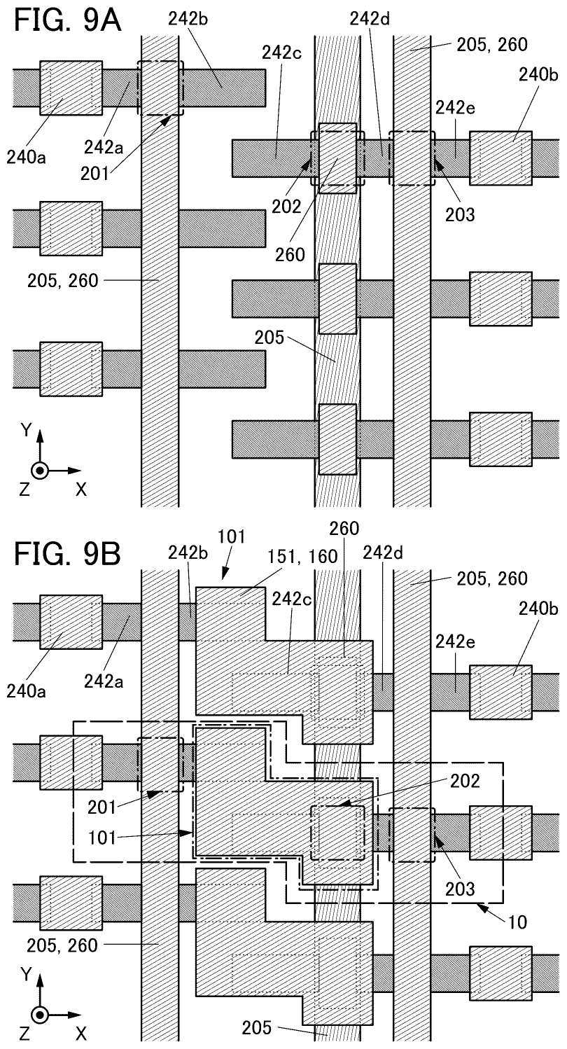

As illustrated in FIG. 8, the conductor 240b can be electrically connected to the conductor 242e included in the transistor 203a and the conductor 242e included in the transistor 203b. Thus, the conductor 240b can be shared by two memory cells adjacent to each other in the X direction, for example. The conductor 240a can be electrically connected to two conductors 242a adjacent to each other in the X direction, for example. Thus, the conductor 240a can also be shared by two memory cells adjacent to each other in the X direction, for example. FIG. 9A and FIG. 9B are plan views illustrating examples of the semiconductor device having the structure illustrated in FIG. 2A, for example, and illustrate structure examples of the XY plane.

FIG. 9A illustrates the transistor 201, the transistor 202, the transistor 203, the conductor 240a, and the conductor 240b. FIG. 9B illustrates a structure in which the capacitor 101 is added to FIG. 9A. In FIG. 9B, a memory cell 10, which is a memory cell of one embodiment of the present invention, includes the transistor 201, the transistor 202, the transistor 203, and the capacitor 101. Note that the components other than the conductors are omitted in FIG. 9A and FIG. 9B.

As illustrated in FIG. 9B, the conductor 151 including a region functioning as one electrode of the capacitor 101 and the conductor 160 including a region functioning as the other electrode of the capacitor 101 each have a shape more complex than a rectangle, specifically, a shape with a larger number of vertices than a rectangle. Thus, the area occupied by the memory cell 10 can be reduced as compared with the case where the conductor 151 and the conductor 160 are rectangular while the area where the conductor 151 and the conductor 160 overlap with each other is being maintained. Accordingly, the memory cells 10 can be arranged at high density, thereby improving the integration degree of the memory cells 10 and increasing the memory capacity of the semiconductor device. For example, in the case where the conductors illustrated in FIG. 9B are formed with a line-and-space pattern, the area of the memory cell 10 is 80 nm×245 nm=0.0196 μm² when the conductors other than the conductor 240 are designed with 20 nm/20 nm line/space and a margin of 10 nm for a portion where two patterns overlap with each other and the conductor 240 is designed with 25 nm×25 nm including a margin of 5 nm for preventing failure in overlap of one of the two conductors 242 and the conductor 240. The cell density of each of the memory layer 11_1 to the memory layer 11_n illustrated in FIG. 1 is 51.0 cell/μm², for example.

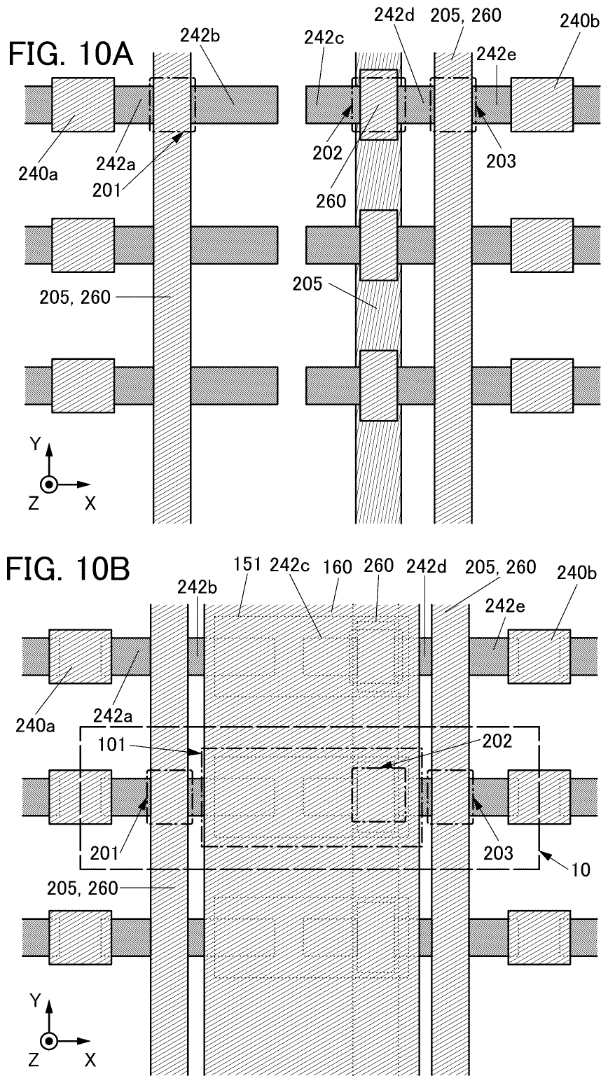

FIG. 10A and FIG. 10B are plan views illustrating examples of the semiconductor device having the structure illustrated in FIG. 2A, for example, that are different from the examples in FIG. 9A and FIG. 9B, and illustrate structure examples of the XY plane. FIG. 10B illustrates a structure in which the capacitor 101 is added to FIG. 10A, and the memory cell 10 includes the transistor 201, the transistor 202, the transistor 203, and the capacitor 101.

In the structure illustrated in FIG. 10B, the conductor 151 including the region functioning as one electrode of the capacitor 101 and the conductor 160 including the region functioning as the other electrode of the capacitor 101 are rectangular. Thus, the semiconductor device illustrated in FIG. 10B can be manufactured more easily than the semiconductor device illustrated in FIG. 9B.

### Example 1 of Method for Manufacturing Semiconductor Device

An example of a method for manufacturing the semiconductor device of one embodiment of the present invention will be described below. Here, the case of manufacturing the semiconductor device illustrated in FIG. 1 will be described as an example.

Hereinafter, an insulating material for forming an insulator, a conductive material for forming a conductor, or a semiconductor material for forming a semiconductor can be deposited by a sputtering method, a CVD method, an MBE method, a PLD method, an ALD method, or the like as appropriate.

Examples of the sputtering method include an RF (Radio Frequency) sputtering method in which a high-frequency power source is used as a sputtering power source, a DC sputtering method in which a DC power source is used, and a pulsed DC sputtering method in which voltage applied to an electrode is changed in a pulsed manner. The RF sputtering method is mainly used in the case where an insulating film is formed, and the DC sputtering method is mainly used in the case where a metal conductive film is formed. The pulsed DC sputtering method is mainly used in the case where a compound such as an oxide, a nitride, or a carbide is deposited by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method is a deposition method that does not use plasma and thus enables less plasma damage to an object to be processed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, such plasma damage is not caused in the case of the thermal CVD method, which does not use plasma, and thus the yield of the semiconductor device can be increased. In addition, the thermal CVD method does not cause plasma damage during deposition, so that a film with few defects can be obtained.

As the ALD method, a thermal ALD method, in which a precursor and a reactant react with each other only by a thermal energy, a PEALD method, in which a reactant excited by plasma is used, and the like can be used.

The CVD method and the ALD method are different from the sputtering method in which particles ejected from a target or the like are deposited. Thus, the CVD method and the ALD method are deposition methods that enable good step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as the CVD method, in some cases.

By the CVD method, a film with a certain composition can be formed depending on the flow rate ratio of the source gases. For example, by the CVD method, a film whose composition is continuously changed can be formed by changing the flow rate ratio of the source gases during film formation. In the case where the film is formed while the flow rate ratio of the source gases is changed, as compared with the case where the film is formed using a plurality of deposition chambers, the time taken for the film formation can be shortened because the time taken for transfer or pressure adjustment is not required. Thus, the productivity of the semiconductor device can be increased in some cases.

By the ALD method, a film with a certain composition can be formed by concurrently introducing different kinds of precursors. In the case where different kinds of precursors are introduced, a film with a certain composition can be formed by controlling the number of cycles for each of the precursors.

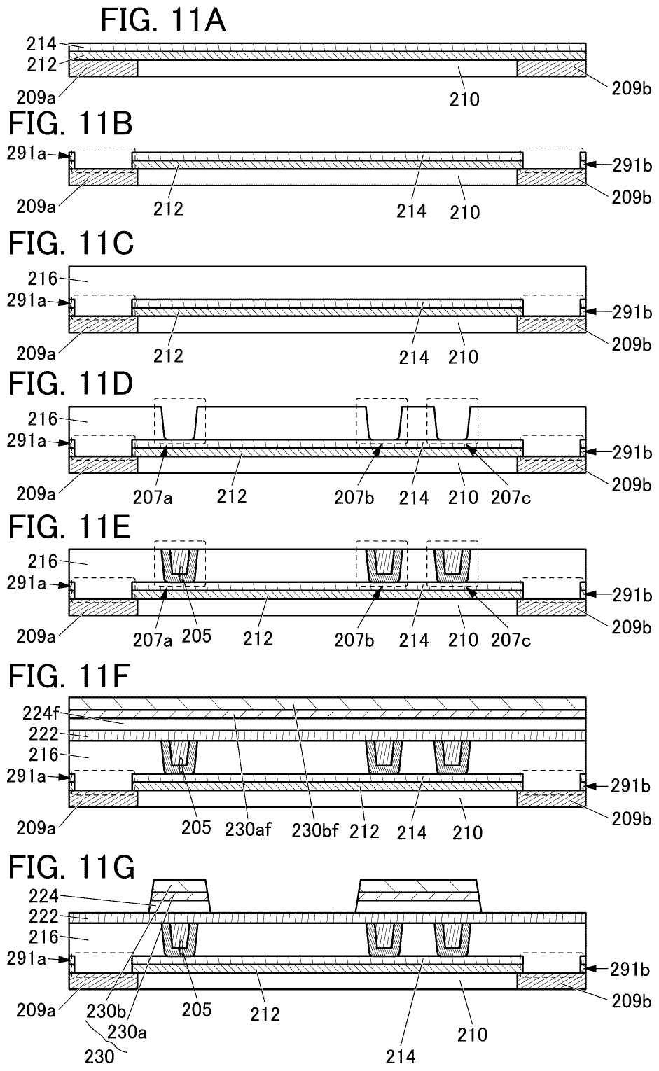

First, a substrate (not illustrated) is prepared, and the conductor 209a, the conductor 209b, and the insulator 210 are formed over the substrate. Next, the insulator 212 is formed over the conductor 209a, the conductor 209b, and the insulator 210, and the insulator 214 is formed over the insulator 212 (FIG. 11A).

The insulator 212 and the insulator 214 are preferably formed by an ALD method. Note that the insulator 212 and the insulator 214 may be formed by a sputtering method, a CVD method, an MBE method, or a PLD method.

In this embodiment, as the insulator 212, silicon nitride is deposited by a PEALD method. As the insulator 214, hafnium oxide is deposited by an ALD method.

The use of an insulator through which impurities such as water and hydrogen are unlikely to pass, such as silicon nitride or hafnium oxide, as the insulator 212 and the insulator 214 can inhibit diffusion of impurities such as water and hydrogen contained in a layer below the insulator 212. Even when a metal that is likely to diffuse, such as copper, is used for the conductor 209a, the conductor 209b, and the like, which are conductors in a layer below the insulator 212, the use of an insulator through which copper is unlikely to pass, such as silicon nitride or hafnium oxide, as the insulator 212 and the insulator 214 can inhibit upward diffusion of the metal through the insulator 212.

Next, the opening 291a reaching the conductor 209a is formed in the insulator 212 and the insulator 214 to overlap with the conductor 209a. The opening 291b reaching the conductor 209b is formed in the insulator 212 and the insulator 214 to overlap with the conductor 209b (FIG. 11B). Wet etching may be used for forming the opening 291a and the opening 291b; however, dry etching is preferably used for fine processing. Here, the opening 291a and the opening 291b are not necessarily formed in the insulator 212.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

Next, the insulator 216 is formed over the insulator 214, the conductor 209a, and the conductor 209b to cover the opening 291a and the opening 291b (FIG. 11C).

In this embodiment, as the insulator 216, silicon oxide is deposited by a pulsed DC sputtering method using a silicon target in an atmosphere containing an oxygen gas. The use of the pulsed DC sputtering method can achieve more uniform film thickness and improve the sputtering rate and film quality.

Next, an opening 207a, an opening 207b, and an opening 207c each reaching the insulator 214 are formed in the insulator 216 (FIG. 11D). The opening 207a, the opening 207b, and the opening 207c can be formed in parallel in the same step. Wet etching may be used for forming the opening 207a, the opening 207b, and the opening 207c; however, dry etching is preferably used for fine processing. Note that a part of the insulator 214 is sometimes removed by the formation of the opening 207a, the opening 207b, and the opening 207c. This sometimes leads to formation of a depressed portion in a region of the insulator 214 that overlaps with the opening 207a, the opening 207b, and the opening 207c.

Next, a conductive film to be the conductor 205 is formed. The conductive film preferably has a stacked-layer structure of a conductive film having a function of inhibiting passage of oxygen and a conductive film having lower electrical resistivity than the conductive film. As the conductive film having a function of inhibiting passage of oxygen, one or more of tantalum nitride, tungsten nitride, and titanium nitride are preferably included, for example. Alternatively, the conductive film can have a stacked-layer structure of the conductive film having a function of inhibiting passage of oxygen and tantalum, tungsten, titanium, molybdenum, aluminum, copper, or a molybdenum-tungsten alloy. As the conductive film having low electrical resistivity, one or more of tantalum, tungsten, titanium, molybdenum, aluminum, copper, and a molybdenum-tungsten alloy are preferably included. These conductive films can be formed by, for example, a sputtering method, a plating method, a CVD method, an MBE method, a PLD method, or an ALD method.

In this embodiment, titanium nitride is deposited as the lower layer of the conductive film to be the conductor 205 and tungsten is deposited as the upper layer thereof. The use of a metal nitride as the lower layer of the conductor 205 can inhibit the insulator 216 from oxidizing the conductor 205, for example. Furthermore, even when a metal that is likely to diffuse is used as the upper layer of the conductor 205, the metal can be prevented from diffusing to the outside from the conductor 205.

Next, CMP treatment is performed to remove a part of the conductive film to be the conductor 205, so that the insulator 216 is exposed. As a result, the conductor 205 is formed in the opening 207a, the opening 207b, and the opening 207c (FIG. 11E). Here, the conductor 205 formed in the opening 207a is included in the transistor 201 formed in a later step. The conductor 205 formed in the opening 207b is included in the transistor 202 formed in a later step. The conductor 205 formed in the opening 207c is included in the transistor 203 formed in a later step. Note that the insulator 216 is partly removed by the CMP treatment in some cases. This enables the insulator 216 to be planarized.

Next, the insulator 222 is formed over the insulator 216 and the conductor 205 (FIG. 11F).

An insulator containing an oxide of one or both of aluminum and hafnium is preferably formed as the insulator 222. Aluminum oxide, hafnium oxide, or an oxide containing aluminum and hafnium (hafnium aluminate) is preferably used for the insulator, for example. Alternatively, hafnium zirconium oxide is preferably used. Alternatively, the insulator 222 can have a stacked-layer structure of an insulating film containing an oxide of one or both of aluminum and hafnium and an insulating film containing silicon oxide, silicon oxynitride, silicon nitride, or silicon nitride oxide.

The insulator 222 can be formed by, for example, a sputtering method, a CVD method, an MBE method, a PLD method, or an ALD method. In this embodiment, as the insulator 222, hafnium oxide is deposited by an ALD method. Alternatively, the insulator 222 may have a stacked-layer structure of silicon nitride deposited by a PEALD method and hafnium oxide deposited by an ALD method.

Subsequently, heat treatment is preferably performed. The temperature of the heat treatment is preferably higher than or equal to 250° C. and lower than or equal to 650° C., further preferably higher than or equal to 300° C. and lower than or equal to 500° C., still further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is preferably 1 ppb or less, further preferably 0.1 ppb or less, still further preferably 0.05 ppb or less. The heat treatment using a highly purified gas can prevent entry of moisture into the insulator 222 as much as possible, for example.

In this embodiment, as the heat treatment, treatment is performed at 400° C. for one hour with a flow rate ratio of a nitrogen gas to an oxygen gas of 4:1 after the formation of the insulator 222. Through the heat treatment, impurities such as water and hydrogen contained in the insulator 222 can be removed, for example. In the case where an oxide containing hafnium is used for the insulator 222, the insulator 222 is partly crystallized by the heat treatment in some cases. The heat treatment can also be performed after formation of an insulating film 224f, for example.

Next, the insulating film 224f is formed over the insulator 222 (FIG. 11F).

The insulating film 224f can be formed by a sputtering method, a CVD method, an MBE method, a PLD method, or an ALD method, for example. In this embodiment, for the insulating film 224f, silicon oxide is deposited by a sputtering method. By using a sputtering method that does not need to use a molecule containing hydrogen for a deposition gas, the hydrogen concentration in the insulating film 224f can be reduced. The hydrogen concentration in the insulating film 224f is preferably reduced in this manner because the insulating film 224f is in contact with the metal oxide in a later step.

Next, a metal oxide film 230af is formed over the insulating film 224f and a metal oxide film 230bf is formed over the metal oxide film 230af (FIG. 11F). Note that it is preferable to form the metal oxide film 230af and the metal oxide film 230bf successively without exposure to the atmospheric environment. The film formation without exposure to the air can prevent attachment of impurities or moisture from the atmospheric environment to the vicinity of an interface between the metal oxide film 230af and the metal oxide film 230bf, so that the vicinity of the interface can be kept clean.

The metal oxide film 230af and the metal oxide film 230bf can each be formed by a sputtering method, a CVD method, an MBE method, a PLD method, or an ALD method, for example. In this embodiment, the metal oxide film 230af and the metal oxide film 230bf are formed by a sputtering method.

For example, in the case where the metal oxide film 230af and the metal oxide film 230bf are formed by a sputtering method, oxygen or a mixed gas of oxygen and a noble gas is used as a sputtering gas. Increasing the proportion of oxygen contained in the sputtering gas can increase the amount of excess oxygen in the formed metal oxide film 230af and metal oxide film 230bf. In the case where the metal oxide film 230af and the metal oxide film 230bf are formed by a sputtering method, an In-M-Zn oxide target can be used, for example.

In particular, when the metal oxide film 230af is formed, part of oxygen contained in the sputtering gas is supplied to the insulating film 224f in some cases. Thus, the proportion of oxygen contained in the sputtering gas is preferably higher than or equal to 70%, further preferably higher than or equal to 80%, still further preferably 100%.

In the case where the metal oxide film 230bf is formed by a sputtering method and the proportion of oxygen contained in the sputtering gas for film formation is higher than 30% and lower than or equal to 100%, preferably higher than or equal to 70% and lower than or equal to 100%, an oxygen-excess oxide semiconductor is formed. In a transistor using an oxygen-excess oxide semiconductor for its channel formation region, relatively high reliability can be obtained. Note that one embodiment of the present invention is not limited thereto. In the case where the metal oxide film 230bf is formed by a sputtering method and the proportion of oxygen contained in the sputtering gas for film formation is higher than or equal to 1% and lower than or equal to 30%, preferably higher than or equal to 5% and lower than or equal to 20%, an oxygen-deficient oxide semiconductor is formed. In a transistor using an oxygen-deficient oxide semiconductor for its channel formation region, relatively high field-effect mobility can be obtained. Furthermore, when the film formation is performed while the substrate is being heated, the crystallinity of the oxide film can be improved.

In this embodiment, the metal oxide film 230af is formed by a sputtering method using an oxide target with In:Ga:Zn=1:3:4 [atomic ratio]. In addition, the metal oxide film 230bf is formed by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the oxide films is preferably formed to have characteristics required for the metal oxide 230a and the metal oxide 230b by selecting the film formation conditions and the atomic ratios as appropriate.

Note that the insulating film 224f, the metal oxide film 230af, and the metal oxide film 230bf are preferably formed by a sputtering method without exposure to the air. For example, a multi-chamber deposition apparatus is preferably used. As a result, entry of hydrogen into the insulating film 224f, the metal oxide film 230af, and the metal oxide film 230bf in intervals between film formation steps can be inhibited.

Note that the metal oxide film 230af and the metal oxide film 230bf may be formed by an ALD method. When the metal oxide film 230af and the metal oxide film 230bf are formed by an ALD method, films with a uniform thickness can be formed even in a groove or an opening portion having a high aspect ratio. The metal oxide film 230af and the metal oxide film 230bf can be formed at a lower temperature by a PEALD method than by a thermal ALD method.

Next, heat treatment is preferably performed. The heat treatment is performed in a temperature range where the metal oxide film 230af and the metal oxide film 230bf do not become polycrystals. The temperature of the heat treatment is preferably higher than or equal to 250° C. and lower than or equal to 650° C., further preferably higher than or equal to 400° C. and lower than or equal to 600° C.

Note that an example of an atmosphere of the heat treatment is an atmosphere similar to the atmosphere applicable to the heat treatment performed after the formation of the insulator 222.

As in the heat treatment performed after the formation of the insulator 222, a gas used in the heat treatment is preferably highly purified. The heat treatment performed using a highly purified gas can prevent entry of moisture or the like into the metal oxide film 230af, the metal oxide film 230bf, and the like as much as possible.

In this embodiment, the heat treatment is performed at 400° C. for one hour with a flow rate ratio of a nitrogen gas to an oxygen gas being 4:1. Through such heat treatment using the oxygen gas, impurities such as carbon, water, and hydrogen in the metal oxide film 230af and the metal oxide film 230bf can be reduced. The reduction of impurities in the films in this manner improves the crystallinity of the metal oxide film 230af and the metal oxide film 230bf, thereby offering a dense structure with a higher density. Thus, crystalline regions in the metal oxide film 230af and the metal oxide film 230bf are expanded, so that in-plane variations of the crystalline regions in the metal oxide film 230af and the metal oxide film 230bf can be reduced. Accordingly, an in-plane variation of electrical characteristics of transistors can be reduced.

By performing the heat treatment, hydrogen in the insulator 216, the insulating film 224f, the metal oxide film 230af, and the metal oxide film 230bf moves into the insulator 222 and is absorbed by the insulator 222. In other words, hydrogen in the insulator 216, the insulating film 224f, the metal oxide film 230af, and the metal oxide film 230bf diffuses into the insulator 222. Accordingly, the hydrogen concentration in the insulator 222 increases, while the hydrogen concentrations in the insulator 216, the insulating film 224f, the metal oxide film 230af, and the metal oxide film 230bf decrease.

Specifically, the insulating film 224f (to be the insulator 224 later) functions as the gate insulator of each of the transistor 201, the transistor 202, and the transistor 203, and the metal oxide film 230af and the metal oxide film 230bf (to be the metal oxide 230a and the metal oxide 230b later) function as the channel formation region of each of the transistor 201, the transistor 202, and the transistor 203. The transistor 201, the transistor 202, and the transistor 203 formed using the insulating film 224f, the metal oxide film 230af, and the metal oxide film 230bf with reduced hydrogen concentrations are preferable because of their high reliability.

Next, the insulating film 224f, the metal oxide film 230af, and the metal oxide film 230bf are processed into island shapes by, for example, a lithography method and an etching method, so that the insulator 224, the metal oxide 230a, and the metal oxide 230b are formed (FIG. 11G). Here, the insulator 224, the metal oxide 230a, and the metal oxide 230b are formed to include a region overlapping with the conductor 205. As described above, the insulator 224, the metal oxide 230a, and the metal oxide 230b are common layers shared by the transistor 202 and the transistor 203.

As illustrated in FIG. 11G, the side surfaces of the insulator 224, the metal oxide 230a, and the metal oxide 230b may have tapered shapes. The taper angles of the side surfaces of the insulator 224, the metal oxide 230a, and the metal oxide 230b may be greater than or equal to 60° and less than 90°, for example. Such tapered side surfaces can improve the coverage with the insulator 275 in a later step, for example; as a result, the number of defects such as voids can be reduced.

Not being limited to the above, the insulator 224, the metal oxide 230a, and the metal oxide 230b may have side surfaces that are substantially perpendicular to the top surface of the insulator 222. With such a structure, a plurality of transistors can be provided at high density in a small area.

A dry etching method or a wet etching method can be employed for the processing. A dry etching method is suitable for fine processing. The insulating film 224f, the metal oxide film 230af, and the metal oxide film 230bf may be processed under different conditions.

In the lithography method, first, a resist is exposed to light through a mask. Next, a region exposed to light is removed or left using a developing solution, so that a resist mask is formed. The resist mask can be formed through, for example, exposure of the resist to KrF excimer laser light, ArF excimer laser light, EUV (Extreme Ultraviolet) light, or the like. Alternatively, a liquid immersion technique may be employed in which a gap between a substrate and a projection lens is filled with a liquid (e.g., water) in light exposure. Note that the resist mask can be removed by dry etching treatment such as ashing, wet etching treatment, wet etching treatment after dry etching treatment, or dry etching treatment after wet etching treatment. After the resist mask is formed by a lithography method, etching treatment through the resist mask is conducted, whereby a conductive film, a semiconductor film, an insulating film, or the like can be processed into a desired shape. In this manner, a conductor, a semiconductor, an insulator, or the like can be formed by a lithography method and an etching method. Note that an electron beam or an ion beam may be used instead of the light. A mask is unnecessary in the case of using an electron beam or an ion beam.

In addition, a hard mask formed of an insulator or a conductor may be used under the resist mask. In the case of using a hard mask, a hard mask with a desired shape can be formed in the following manner: an insulating film or a conductive film that is the material of the hard mask is formed over the metal oxide film 230bf, a resist mask is formed thereover, and then the hard mask material is etched. For example, the etching of the metal oxide film 230bf may be performed after removal of the resist mask or with the resist mask remaining. In the latter case, the resist mask sometimes disappears during the etching. The hard mask may be removed by etching after the etching of the metal oxide film 230bf, for example. Meanwhile, the hard mask is not necessarily removed when the hard mask material does not affect later steps or can be utilized in later steps.

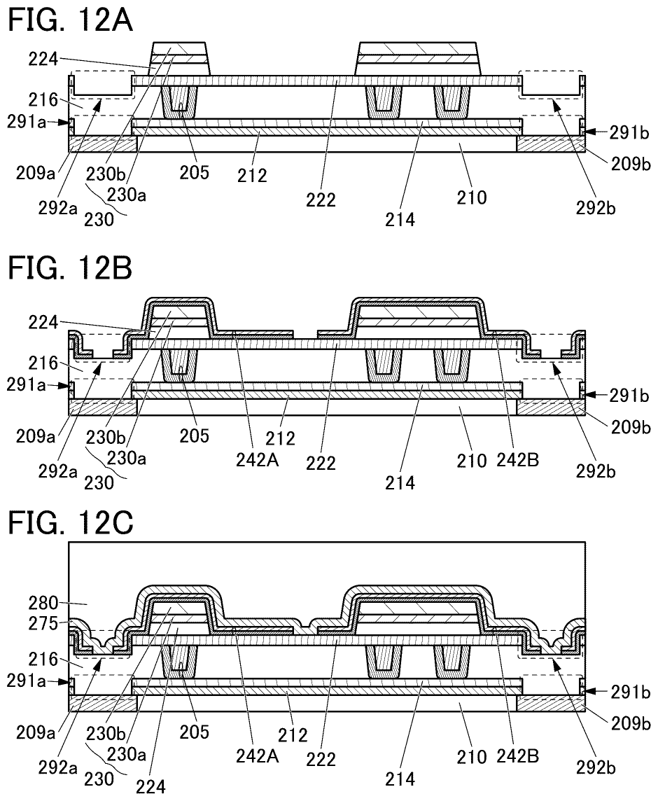

Next, the opening 292a reaching the insulator 216 is formed in the insulator 222 to overlap with the conductor 209a. The opening 292b reaching the insulator 216 is formed in the insulator 222 to overlap with the conductor 209b (FIG. 12A). The opening 292a is formed to include a region overlapping with the opening 291a, and the opening 292b is formed to include a region overlapping with the opening 291b. The opening 292a and the opening 292b can be formed by a formation method similar to that for the opening 291a and the opening 291b. Note that the insulator 216 is sometimes partly removed by the formation of the openings in the insulator 222. This sometimes leads to formation of a depressed portion in each of a region of the insulator 216 that overlaps with the opening 292a and a region of the insulator 216 that overlaps with the opening 292b. In the case where the insulator 222 has a stacked-layer structure of two or more layers, the opening 292a and the opening 292b are sometimes formed in only some of the layers included in the insulator 222. For example, in the case where the insulator 222 has a stacked-layer structure of a film containing silicon nitride and a film containing hafnium oxide, the opening 292a and the opening 292b are not formed in the film containing silicon nitride in some cases.

Next, a conductive film is formed over the metal oxide 230b, the insulator 222, and the insulator 216. The conductive film can be formed by, for example, a sputtering method, a CVD method, an MBE method, a PLD method, or an ALD method. Note that heat treatment may be performed before the formation of the conductive film. The heat treatment may be performed under reduced pressure, and the conductive film may be successively formed without exposure to the air. Such treatment can remove moisture and hydrogen adsorbed on the surface of the metal oxide 230b and can reduce the moisture concentration and the hydrogen concentration in each of the metal oxide 230a and the metal oxide 230b. The heat treatment temperature is preferably higher than or equal to 100° C. and lower than or equal to 400° C. In this embodiment, the heat treatment temperature is 200° C.

Next, the conductive film is processed by a lithography method and an etching method, whereby a conductive layer 242A and a conductive layer 242B that cover the top surface and the side surfaces of the metal oxide 230b, the side surfaces of the metal oxide 230a, the side surfaces of the insulator 224, and the top surface and the side surfaces of the insulator 222 are formed (FIG. 12B). Here, the conductive layer 242A is formed to cover the top surface and the side surfaces of the metal oxide 230b, the side surfaces of the metal oxide 230a, and the side surfaces of the insulator 224 of the transistor 201. The conductive layer 242B is formed to cover the top surface and the side surfaces of the metal oxide 230b, the side surfaces of the metal oxide 230a, and the side surfaces of the insulator 224 of the transistor 202 and the transistor 203.

Furthermore, part of the conductive layer 242A is formed in the opening 292a, and part of the conductive layer 242B is formed in the opening 292b. That is, part of the end portion of the conductive layer 242A is formed in the opening 292a, and part of the end portion of the conductive layer 242B is formed in the opening 292b. Note that the opening 292a and the opening 292b include regions not overlapping with the conductive layer 242A and the conductive layer 242B, respectively.

In this embodiment, the conductive film to be the conductive layer 242A and the conductive layer 242B has a stacked-layer structure of tantalum nitride and tungsten each deposited by a sputtering method. Here, a film containing tungsten and a film containing tantalum nitride may be processed under the same conditions or different conditions.

Next, the insulator 275 is formed over the conductive layer 242A, the conductive layer 242B, the insulator 222, and the insulator 216, and the insulator 280 is formed over the insulator 275 (FIG. 12C). As the insulator 280, an insulator having a flat top surface is preferably formed in the following manner: an insulating film to be the insulator 280 is formed and then the insulating film is subjected to CMP treatment. Note that, for example, silicon nitride may be deposited over the insulator 280 by a sputtering method and CMP treatment may be performed on the silicon nitride film until the insulator 280 is reached.

The insulator 275 and the insulator 280 can each be formed by a sputtering method, a CVD method, an MBE method, a PLD method, or an ALD method, for example.

As the insulator 275, an insulator having a function of inhibiting passage of oxygen is preferably used. For example, silicon nitride is preferably deposited for the insulator 275 by an ALD method, specifically a PEALD method. Alternatively, for the insulator 275, it is preferable that aluminum oxide be deposited by a sputtering method and silicon nitride be deposited thereover by a PEALD method. When the insulator 275 has such a stacked-layer structure, the function of inhibiting diffusion of oxygen and impurities such as water and hydrogen can be improved.

In this manner, the insulator 224, the metal oxide 230a, the metal oxide 230b, the conductive layer 242A, and the conductive layer 242B can be covered with the insulator 275, which has a function of inhibiting diffusion of oxygen. This can inhibit direct diffusion of oxygen from the insulator 280 or the like into the insulator 224, the metal oxide 230a, the metal oxide 230b, the conductive layer 242A, and the conductive layer 242B in a later step.

The insulator 280 is preferably silicon oxide deposited by a sputtering method, for example. When the insulator 280 is formed by a sputtering method in an oxygen-containing atmosphere, the insulator 280 containing excess oxygen can be formed. By using a sputtering method that does not need to use a molecule containing hydrogen as a deposition gas, the hydrogen concentration in the insulator 280 can be reduced. Note that heat treatment may be performed before the formation of the insulating film. The heat treatment may be performed under reduced pressure, and the insulating film may be successively formed without exposure to the air. Such treatment can remove moisture and hydrogen adsorbed onto the surface of the insulator 275 and the like, and further can reduce the moisture concentration and the hydrogen concentration in each of the metal oxide 230a, the metal oxide 230b, and the insulator 224. For the heat treatment, the above heat treatment conditions can be used.

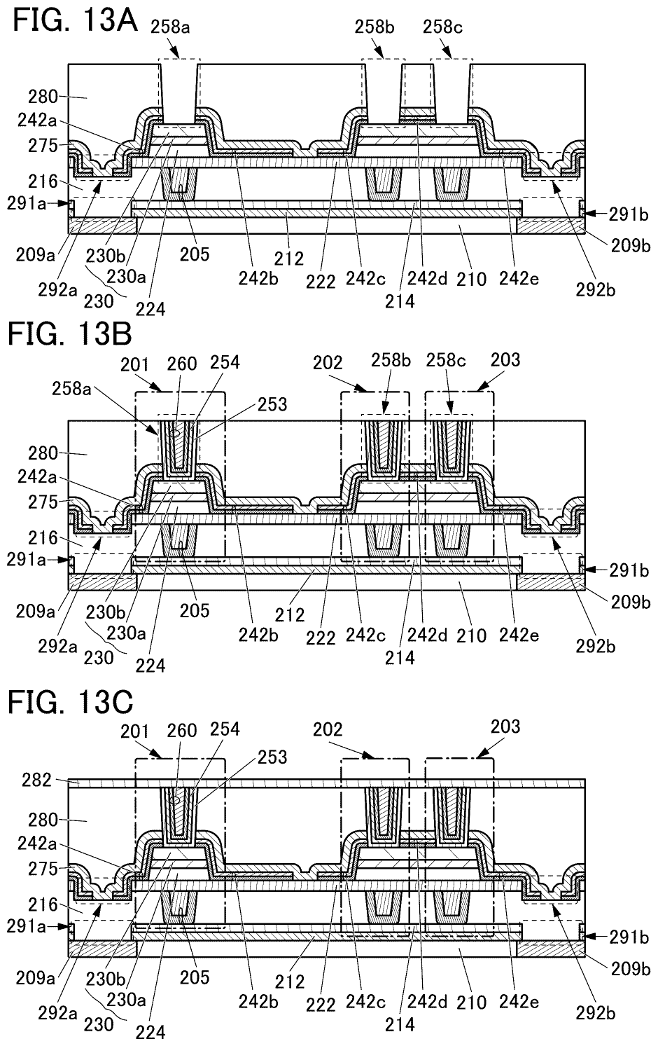

Then, the conductive layer 242A, the insulator 275, and the insulator 280 are processed by a lithography method and an etching method to form an opening 258a reaching the metal oxide 230b. In addition, the conductive layer 242B, the insulator 275, and the insulator 280 are processed to form an opening 258b and an opening 258c that reach the metal oxide 230b. The conductor 242a and the conductor 242b are formed by the formation of the opening 258a. The conductor 242c, the conductor 242d, and the conductor 242e are formed by the formation of the opening 258b and the opening 258c (FIG. 13A). The opening 258a, the opening 258b, and the opening 258c each include a region overlapping with the conductor 205. Note that the processing of the conductive layer 242A and the conductive layer 242B, the processing of the insulator 275, and the processing of the insulator 280 may be performed under different conditions. Alternatively, the processing of the insulator 275 and the processing of the insulator 280 may be performed under the same conditions, which may be different from the conditions for the processing of the conductive layer 242A and the conductive layer 242B.

Through the etching treatment, impurities might be attached to the top surface of the metal oxide 230b, the side surfaces of the conductor 242a to the conductor 242e, the side surface of the insulator 275, the side surface of the insulator 280, and the like. The impurities might diffuse into these components. A step of removing the impurities may be performed. Particularly in the case where the opening 258a, the opening 258b, and the opening 258c are formed by a dry etching method, a damaged region is sometimes formed on the surface of the metal oxide 230b. Such a damaged region may be removed. The impurities result from components contained in the insulator 280, the insulator 275, and the conductor 242a to the conductor 242e, components contained in a member of an apparatus used to form the opening 258a to the opening 258c, and components contained in a gas or a liquid used for etching, for example. Examples of the impurities include hafnium, aluminum, silicon, tantalum, fluorine, and chlorine.

In particular, impurities such as aluminum and silicon might reduce the crystallinity of the metal oxide 230b. Thus, it is preferable that impurities such as aluminum and silicon be removed from the surface of the metal oxide 230b and the vicinity thereof. The concentration of the impurities is preferably reduced. For example, the concentration of aluminum atoms at the surface of the metal oxide 230b and the vicinity thereof is preferably lower than or equal to 5.0 atomic %, further preferably lower than or equal to 2.0 atomic %, still further preferably lower than or equal to 1.5 atomic %, yet further preferably lower than or equal to 1.0 atomic %, yet still further preferably lower than 0.3 atomic %.

Note that since the density of a crystal structure is reduced in a low-crystallinity region of the metal oxide 230b because of impurities such as aluminum and silicon, a large amount of V_{O}H is formed; thus, the transistor is likely to be normally on. Hence, the low-crystallinity region of the metal oxide 230b is preferably reduced or removed.

By contrast, the metal oxide 230b preferably has a layered CAAC structure. In particular, the CAAC structure preferably reaches a lower edge portion of a drain in the metal oxide 230b. Here, in the transistor 201 to the transistor 203, at least parts of the conductor 242a to the conductor 242e and their vicinities function as drains. Thus, the metal oxides 230b in the vicinities of the lower edge portions of the conductor 242a to the conductor 242e preferably have a CAAC structure. In this manner, the low-crystallinity region of the metal oxide 230b is removed and the CAAC structure is formed also in the drain edge portion, which significantly affects the drain breakdown voltage, so that variations in the electrical characteristics of the transistor 201 to the transistor 203 can be further inhibited. In addition, the reliability of the transistor 201 to the transistor 203 can be improved.

In order to remove impurities attached to the surface of the metal oxide 230b in the above etching step, for example, cleaning treatment is performed. Examples of the cleaning method include wet cleaning using a cleaning solution (which can also be referred to as wet etching treatment), plasma treatment using plasma, and cleaning by heat treatment, and any of these cleanings may be performed in appropriate combination. Note that the cleaning treatment sometimes makes the groove portion deeper.

The wet cleaning may be performed using an aqueous solution in which one or more of ammonia water, oxalic acid, phosphoric acid, and hydrofluoric acid is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. For example, damage to the metal oxide 230b can be reduced with this frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the cleaning treatment in this embodiment, wet cleaning using diluted ammonia water is performed. The cleaning treatment can remove impurities that are attached onto the surfaces of the metal oxide 230a, the metal oxide 230b, and the like or diffused into the metal oxide 230a, the metal oxide 230b, and the like. Furthermore, the crystallinity of the metal oxide 230b can be increased.

After the etching or the cleaning, heat treatment may be performed. The temperature of the heat treatment is preferably higher than or equal to 100° C. and lower than or equal to 450° C., further preferably higher than or equal to 350° C. and lower than or equal to 400° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the metal oxide 230a and the metal oxide 230b to reduce oxygen vacancies. In addition, the crystallinity of the metal oxide 230b can be improved by such heat treatment. The heat treatment may be performed under reduced pressure. Alternatively, heat treatment may be performed in an oxygen atmosphere, and then heat treatment may be successively performed in a nitrogen atmosphere without exposure to the air.

Next, an insulating film to be the insulator 253 is formed to fill the opening 258a, the opening 258b, and the opening 258c. The insulating film can be formed by an ALD method, a sputtering method, a CVD method, an MBE method, or a PLD method, for example, and is preferably formed by an ALD method. It is preferable that the thickness of the insulator 253 be small and hardly vary. An ALD method is a film formation method in which a precursor and a reactant (e.g., an oxidizer) are alternately introduced, and the thickness can be adjusted with the number of repetition times of the cycle; thus, accurate control of the thickness is possible. As illustrated in FIG. 13B, the insulator 253 is preferably formed with good coverage on the bottom surfaces and the side surfaces of the opening 258a, the opening 258b, and the opening 258c. With the use of an ALD method, an atomic layer can be deposited one by one on the bottom surfaces and the side surfaces of the opening 258a, the opening 258b, and the opening 258c. Thus, the insulator 253 can be formed with good coverage in the opening 258a, the opening 258b, and the opening 258c.

When the insulating film to be the insulator 253 is formed by an ALD method, ozone (O₃), oxygen (O₂), water (H₂O), or the like can be used as the oxidizer. When an oxidizer without containing hydrogen, such as ozone (O₃) or oxygen (O₂), is used, the amount of hydrogen diffusing into the metal oxide 230b can be reduced.

In this embodiment, hafnium oxide is deposited for the insulating film to be the insulator 253 by a thermal ALD method.

Next, it is preferable to perform microwave treatment in an atmosphere containing oxygen. Here, the microwave treatment refers to, for example, treatment using an apparatus including a power source that generates high-density plasma with the use of a microwave. In this specification and the like, a microwave refers to an electromagnetic wave having a frequency greater than or equal to 300 MHz and less than or equal to 300 GHz.

The microwave treatment is preferably performed with a microwave treatment apparatus including a power source for generating high-density plasma using microwaves, for example. Here, the frequency of the microwave treatment apparatus is preferably set to greater than or equal to 300 MHz and less than or equal to 300 GHz, further preferably greater than or equal to 2.4 GHz and less than or equal to 2.5 GHZ, and can be set to 2.45 GHz, for example. Oxygen radicals at a high density can be generated with high-density plasma. The electric power of the power source that applies microwaves of the microwave treatment apparatus is preferably set to higher than or equal to 1000 W and lower than or equal to 10000 W, further preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the metal oxide 230b efficiently.

The microwave treatment is preferably performed under reduced pressure, and the pressure is preferably set to higher than or equal to 10 Pa and lower than or equal to 1000 Pa, further preferably higher than or equal to 300 Pa and lower than or equal to 700 Pa. The treatment temperature is preferably set to lower than or equal to 750° C., further preferably lower than or equal to 500° C., and can be approximately 250° C., for example. The oxygen plasma treatment may be followed successively by heat treatment without exposure to air. The temperature of the heat treatment is preferably higher than or equal to 100° C. and lower than or equal to 750° C., further preferably higher than or equal to 300° C. and lower than or equal to 500° C., for example.

Furthermore, the microwave treatment can be performed using an oxygen gas and an argon gas, for example. Here, the proportion of the flow rate of the oxygen gas in the whole gas flow rate (hereinafter, also referred to as an oxygen flow rate ratio) in the microwave treatment is higher than 0% and lower than or equal to 100%. The oxygen flow rate ratio is preferably higher than 0% and lower than or equal to 50%. The oxygen flow rate ratio is further preferably higher than or equal to 10% and lower than or equal to 40%. The oxygen flow rate ratio is still further preferably higher than or equal to 10% and lower than or equal to 30%. The carrier concentration in the metal oxide 230b can be reduced by thus performing the microwave treatment in an atmosphere containing oxygen. In addition, preventing introduction of an excess amount of oxygen into the chamber in the microwave treatment can prevent an excessive reduction in the carrier concentration in the metal oxide 230b.

The microwave treatment in an atmosphere containing oxygen can convert an oxygen gas into plasma using a high-frequency wave such as a microwave or RF, and apply the oxygen plasma to a region of the metal oxide 230b which is between the conductor 242a and the conductor 242b, a region of the metal oxide 230b which is between the conductor 242c and the conductor 242d, and a region of the metal oxide 230b which is between the conductor 242d and the conductor 242e. By the effect of the plasma, the microwave, or the like, V_{O}H in the region can be divided and hydrogen can be removed from the region. That is, V_{O}H contained in the channel formation region can be reduced. Accordingly, oxygen vacancies and V_{O}H in the channel formation region can be reduced to lower the carrier concentration. In addition, oxygen radicals generated by the oxygen plasma can be supplied to oxygen vacancies in the channel formation region, thereby further reducing oxygen vacancies in the channel formation region and lowering the carrier concentration.

Meanwhile, the metal oxide 230b includes a region overlapping with any of the conductor 242a to the conductor 242e. The region can function as a source region or a drain region. Here, the conductor 242a to the conductor 242e preferably function as blocking films preventing the effect caused by the high-frequency wave such as a microwave or RF, the oxygen plasma, or the like in the microwave treatment in an atmosphere containing oxygen. Therefore, the conductor 242a to the conductor 242e preferably have a function of blocking an electromagnetic wave greater than or equal to 300 MHz and less than or equal to 300 GHz, for example, greater than or equal to 2.4 GHz and less than or equal to 2.5 GHz.

The conductor 242a to the conductor 242e block the effects of the high-frequency wave such as a microwave or RF, the oxygen plasma, and the like. Thus, the effects do not reach the region of the metal oxide 230b that overlaps with any of the conductor 242a to the conductor 242e. Hence, a reduction in V_{O}H and supply of an excess amount of oxygen due to the microwave treatment do not occur in the source region and the drain region, preventing a decrease in carrier concentration.

Furthermore, the insulator 253 having a barrier property against oxygen is provided in contact with the side surfaces of the conductor 242a to the conductor 242e. This can inhibit formation of oxide films on the side surfaces of the conductor 242a to the conductor 242e by the microwave treatment.

Furthermore, the film quality of the insulator 253 can be improved, leading to higher reliability of the transistor.

In the above manner, oxygen vacancies and V_{O}H can be selectively removed from the channel formation region in the metal oxide, whereby the channel formation region can be an i-type or substantially i-type region. Furthermore, supply of an excess amount of oxygen to the regions functioning as the source region and the drain region can be inhibited, and the conductivity can be maintained. As a result, a change in the electrical characteristics of the transistor can be inhibited, and thus a variation in the electrical characteristics of transistors in the substrate plane can be inhibited.

In the microwave treatment, thermal energy is directly transmitted to the metal oxide 230b in some cases owing to an electromagnetic interaction between the microwave and a molecule in the metal oxide 230b. The metal oxide 230b may be heated by this thermal energy. Such heat treatment is sometimes referred to as microwave annealing. When microwave treatment is performed in an atmosphere containing oxygen, an effect equivalent to that of oxygen annealing is sometimes obtained. In the case where hydrogen is contained in the metal oxide 230b, it is probable that the thermal energy is transmitted to the hydrogen in the metal oxide 230b and the hydrogen activated by the energy is released from the metal oxide 230b.

Note that the microwave treatment may be performed not after the formation of the insulating film to be the insulator 253 but before the formation of the insulating film.

After the microwave treatment after the formation of the insulating film to be the insulator 253, heat treatment may be performed with the reduced pressure being maintained. Such treatment enables hydrogen in the insulating film, the metal oxide 230b, and the metal oxide 230a to be removed efficiently. Part of hydrogen is gettered by the conductor 242 (the conductor 242a to the conductor 242e) in some cases. Alternatively, the step of performing microwave treatment and then performing heat treatment with the reduced pressure being maintained may be repeated a plurality of cycles. The repetition of the heat treatment enables hydrogen in the insulating film, the metal oxide 230b, and the metal oxide 230a to be removed more efficiently. Note that the temperature of the heat treatment is preferably higher than or equal to 300° C. and lower than or equal to 500° C. The microwave treatment, i.e., the microwave annealing, may also serve as the heat treatment. The heat treatment is not necessarily performed in the case where the metal oxide 230b is adequately heated by the microwave annealing, for example.

Furthermore, the microwave treatment improves the film quality of the insulating film to be the insulator 253, thereby inhibiting diffusion of hydrogen, water, impurities, and the like. Accordingly, hydrogen, water, impurities, and the like can be inhibited from diffusing into the metal oxide 230b, the metal oxide 230a, and the like through the insulator 253 in a later step such as formation of a conductive film to be the conductor 260 or later treatment such as heat treatment.

Next, an insulating film to be the insulator 254 is formed over the insulating film to be the insulator 253. The insulating film can be formed by a sputtering method, a CVD method, an MBE method, a PLD method, or an ALD method, for example. The insulating film is preferably formed by an ALD method, like the insulating film to be the insulator 253. By an ALD method, the insulating film to be the insulator 254 can be formed to have a small thickness and good coverage. In this embodiment, for the insulating film, silicon nitride is deposited by a PEALD method.

Next, the conductive film to be the conductor 260 is formed over the insulating film to be the insulator 254. The conductive film may be a single layer or have a stacked-layer structure of two or more layers. The conductive film to be the conductor 260 can be formed by, for example, a sputtering method, a CVD method, an MBE method, a PLD method, or an ALD method. In this embodiment, the conductive film to be the conductor 260 has a stacked-layer structure of titanium nitride deposited by an ALD method and tungsten deposited by a CVD method.

Then, the insulating film to be the insulator 253, the insulating film to be the insulator 254, and the conductive film to be the conductor 260 are polished by CMP treatment until the insulator 280 is exposed. That is, portions of the insulating film to be the insulator 253, the insulating film to be the insulator 254, and the conductive film to be the conductor 260 that are exposed from the opening 258a, the opening 258b, and the opening 258c are removed. Accordingly, the insulator 253, the insulator 254, and the conductor 260 are formed in the opening 258a, the opening 258b, and the opening 258c (FIG. 13B).

Thus, the insulator 253 is provided in contact with the inner walls and the side surfaces of the opening 258a, the opening 258b, and the opening 258c. The conductor 260 is formed to be embedded in the opening 258a, the opening 258b, and the opening 258c with the insulator 253 and the insulator 254 therebetween. Consequently, the transistor 201, the transistor 202, and the transistor 203 are formed. In this manner, the transistor 201, the transistor 202, and the transistor 203 can be formed in parallel through the same process.

Then, heat treatment may be performed under conditions similar to those for the above heat treatment. In this embodiment, treatment is performed at 400° C. for one hour in a nitrogen atmosphere. The heat treatment can reduce the moisture concentration and the hydrogen concentration in the insulator 280. After the heat treatment, the insulator 282 may be successively formed without exposure to the air.

Next, the insulator 282 is formed over the insulator 253, the insulator 254, the conductor 260, and the insulator 280 (FIG. 13C). The insulator 282 can be formed by, for example, a sputtering method, a CVD method, an MBE method, a PLD method, or an ALD method. The insulator 282 is preferably deposited by a sputtering method. Since a molecule containing hydrogen is not needed to be used for a deposition gas in the sputtering method, the hydrogen concentration in the insulator 282 can be reduced.

In this embodiment, for the insulator 282, aluminum oxide is deposited by a pulsed DC sputtering method using an aluminum target in an atmosphere containing an oxygen gas. The use of the pulsed DC sputtering method can achieve more uniform film thickness and improve the sputtering rate and film quality. The RF power applied to the substrate is lower than or equal to 1.86 W/cm², preferably higher than or equal to 0 W/cm² and lower than or equal to 0.62 W/cm². With low RF power, the amount of oxygen implanted into the insulator 280 can be reduced. Alternatively, the insulator 282 may have a stacked-layer structure of two layers. In that case, for example, the lower layer of the insulator 282 is formed with an RF power of 0 W/cm² applied to the substrate, and the upper layer of the insulator 282 is formed with an RF power of 0.62 W/cm² applied to the substrate.

When the insulator 282 is deposited by a sputtering method in an atmosphere containing oxygen, oxygen can be added to the insulator 280 during the deposition. Thus, excess oxygen can be contained in the insulator 280. At this time, the insulator 282 is preferably deposited while the substrate is being heated.

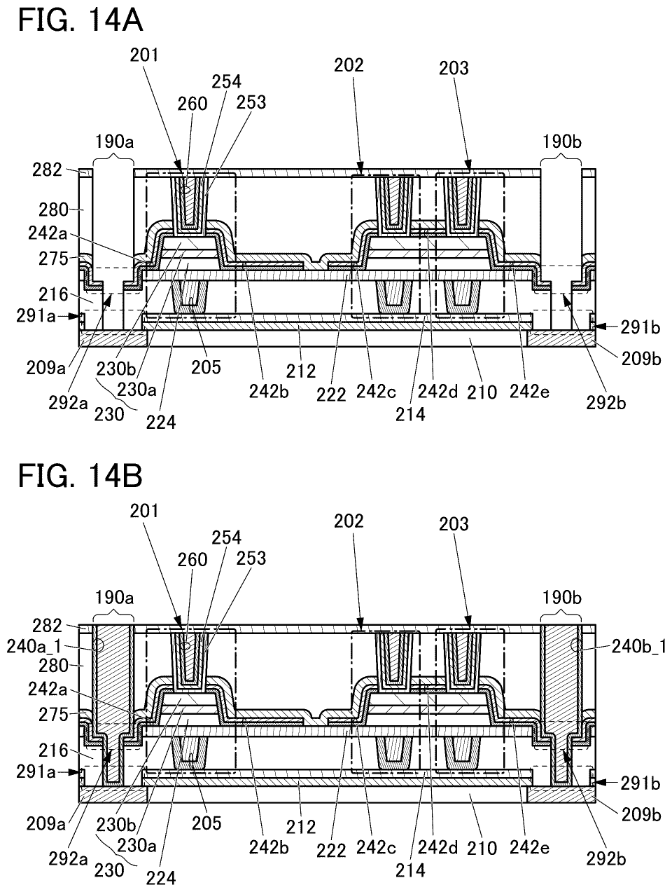

Next, an opening 190a reaching the conductor 209a and an opening 190b reaching the conductor 209b are formed in the insulator 282, the insulator 280, the insulator 275, and the insulator 216 (FIG. 14A).

The opening 190a and the opening 190b can be formed by a lithography method and an etching method. The opening 190a and the opening 190b can be formed by processing the insulator 282, the insulator 280, the insulator 275, and the insulator 216 by a dry etching method.

The opening 190a can be formed under the same conditions until reaching the conductor 209a after the opening 190a is formed in the insulator 282 in the case where the opening 291a is provided in the insulator 212 and the insulator 214, the opening 292a is provided in the insulator 222, and the opening 190a is provided to overlap with the opening 291a and the opening 292a. Furthermore, the opening 190b can be formed under the same conditions until reaching the conductor 209b after the opening 190b is formed in the insulator 282 in the case where the opening 291b is provided in the insulator 212 and the insulator 214, the opening 292b is provided in the insulator 222, and the opening 190b is provided to overlap with the opening 291b and the opening 292b. Accordingly, the range of choices for the materials that can be used for the insulators can be widened. Specifically, the insulator 212, the insulator 214, and the insulator 222 can be formed using materials that are easily processed under conditions different from those of the materials for insulator 216, the insulator 275, and the insulator 280. Note that when the etching conditions of the insulator 282 are different from those of the insulator 280 and the components thereunder, the insulator 282 can be formed using a material that is easily processed under conditions different from those of the materials for the insulator 216, the insulator 275, and the insulator 280. When the insulator 282 is formed using a material that is easily processed under the same conditions as the materials for the insulator 216, the insulator 275, and the insulator 280, the opening 190a and the opening 190b can be formed under the same conditions.

Next, a conductive film to be the conductor 240a_1 and the conductor 240b_1 is formed. The conductive film preferably has a stacked-layer structure of a conductive film having a function of inhibiting passage of impurities such as water and hydrogen and a conductive film having lower electrical resistivity than the conductive film. As the conductive film having a function of inhibiting passage of impurities, tantalum nitride or titanium nitride can be used, for example. As the conductive film having low electrical resistivity, tungsten, molybdenum, or copper can be used, for example. These conductive films can be formed by, for example, a sputtering method, a CVD method, an MBE method, a PLD method, or an ALD method.

Next, the conductive film to be the conductor 240a_1 and the conductor 240b_1 is partly removed by CMP treatment to expose the top surface of the insulator 282. As a result, the conductive film remains only in the opening 190a and the opening 190b, so that the conductor 240a_1 and the conductor 240b_1 having flat top surfaces can be formed (FIG. 14B). Here, in the case where the top surface and the side surface of the conductor 242a are exposed by the formation of the opening 190a, the conductor 240a_1 is formed to include a region in contact with the top surface of the conductor 242a and a region in contact with the side surface of the conductor 242a. In the case where the top surface and the side surface of the conductor 242e are exposed by the formation of the opening 190b, the conductor 240b_1 is formed to include a region in contact with the top surface of the conductor 242e and a region in contact with the side surface of the conductor 242e. Note that the CMP treatment is performed until the insulator 282 is exposed, for example. The top surface of the insulator 282 is partly removed by the CMP treatment in some cases.

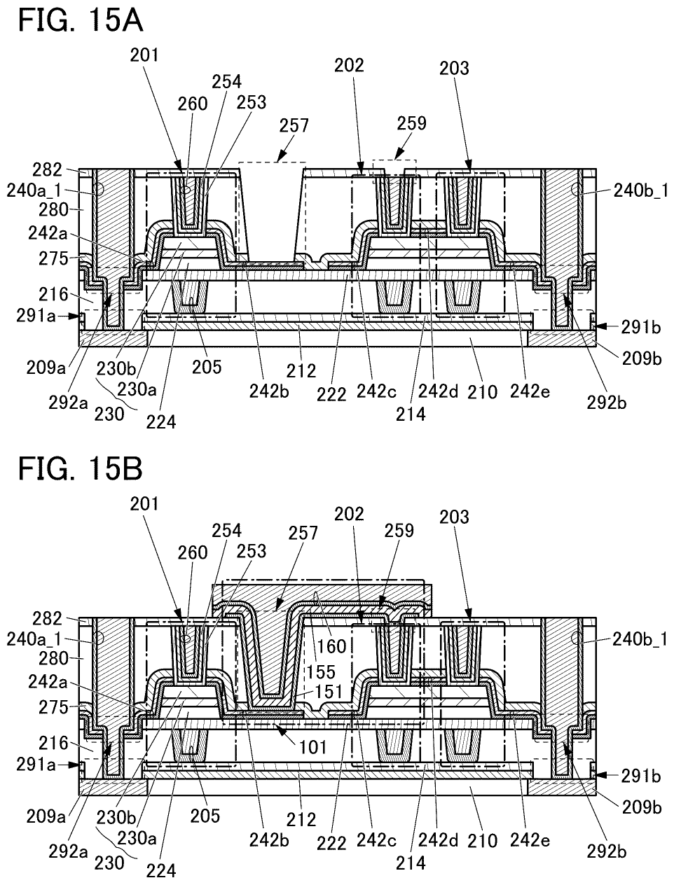

Then, the opening 257 reaching the conductor 242b is formed in the insulator 282, the insulator 280, and the insulator 275. In addition, the opening 259 reaching the conductor 260 of the transistor 202 is formed in the insulator 282 (FIG. 15A).

The opening 257 and the opening 259 can be formed by a lithography method and an etching method. Here, the opening 257 and the opening 259 may be formed in parallel in the same step or in different steps. In the case where the opening 257 and the opening 259 are formed in different steps, one of the opening 257 and the opening 259 can be formed and then the other of the opening 257 and the opening 259 can be formed.

The width of the opening 257 is preferably minute. For example, the width of the opening 257 is preferably less than or equal to 60 nm, less than or equal to 50 nm, less than or equal to 40 nm, less than or equal to 30 nm, less than or equal to 20 nm, or less than or equal to 10 nm and greater than or equal to 1 nm or greater than or equal to 5 nm. In order to form such a minute opening, an electron beam or short-wavelength light such as EUV light is preferably used for the lithography method.

Since the opening 257 has a high aspect ratio, the insulator 282, the insulator 280, and the insulator 275 are preferably processed by anisotropic etching. Processing by a dry etching method is particularly preferable because it is suitable for microfabrication. The processing may be performed under different conditions.

Next, the capacitor 101 is formed to fill the opening 257 and the opening 259. Specifically, the conductor 151, the insulator 155, and the conductor 160 are formed (FIG. 15B).

First, a conductive film to be the conductor 151 is formed to fill the opening 257 and the opening 259. The conductive film to be the conductor 151 is preferably formed in contact with the side surfaces and the bottom surfaces of the opening 257 and the opening 259. In that case, the conductive film to be the conductor 151 is preferably formed by a deposition method that offers excellent coverage, such as an ALD method or a CVD method. In this embodiment, for the conductive film to be the conductor 151, titanium nitride or tantalum nitride is preferably deposited by an ALD method.

Next, the conductive film to be the conductor 151 is processed by a lithography method and an etching method, so that the conductor 151 is formed (FIG. 15B). The conductor 151 is formed in the opening 257 and the opening 259. The conductor 151 is formed to include a region positioned over the insulator 282.

Next, an insulating film to be the insulator 155 is formed over the conductor 151, the conductor 240a_1, the conductor 240b_1, and the insulator 282. The insulating film to be the insulator 155 is preferably formed in contact with the conductor 151 provided in the opening 257 and the opening 259. Thus, the insulating film to be the insulator 155 is preferably formed by a deposition method that offers excellent coverage, such as an ALD method or a CVD method.

The insulator 155 is preferably formed using a high-k material, and further preferably has a stacked-layer structure including a high-k material and a material having higher dielectric strength than the high-k material. In this embodiment, as the insulator 155, zirconium oxide, aluminum oxide, and zirconium oxide are deposited in this order by an ALD method. Alternatively, as the insulator 155, zirconium oxide, aluminum oxide, zirconium oxide, and aluminum oxide may be deposited in this order by an ALD method.

Next, a conductive film to be the conductor 160 is formed over the insulating film to be the insulator 155. The conductive film to be the conductor 160 is preferably formed in contact with the insulating film to be the insulator 155 provided in the opening 257 and the opening 259. Thus, the conductive film to be the conductor 160 is preferably formed by a deposition method that offers excellent coverage, such as an ALD method or a CVD method. In this embodiment, titanium nitride is deposited by an ALD method, and then tungsten is deposited by a CVD method.

In the case where the conductive film to be the conductor 160 is formed by a CVD method, the average surface roughness of the top surface of the conductive film is sometimes increased. In this case, the conductive film is preferably planarized by a CMP method.

Next, the insulating film to be the insulator 155 and the conductive film to be the conductor 160 are processed by a lithography method and an etching method, so that the insulator 155 and the conductor 160 are formed (FIG. 15B). Here, the insulator 155 and the conductor 160 are preferably formed to cover an end portion of the conductor 151. In that case, the conductor 151 and the conductor 160 can be isolated by the insulator 155, so that a short circuit between the conductor 151 and the conductor 160 can be inhibited.

Although an example in which the insulating film to be the insulator 155 is processed is described above, the present invention is not limited thereto. A structure may be employed in which the insulating film is left without being processed while only the conductive film to be the conductor 151 and the conductive film to be the conductor 160 are processed. This structure eliminates the processing step of the insulating film, and the productivity can be improved.

Although an example in which the capacitor 101 is formed after the conductor 240a_1 and the conductor 240b_1 are formed is described above, one embodiment of the present invention is not limited thereto. For example, after the formation of the insulator 282 illustrated in FIG. 13C, the following procedure may be employed: providing the opening 257 and the opening 259 and forming the capacitor 101 are performed, then, the opening 190a and the opening 190b are provided, and the conductor 240a_1 and the conductor 240b_1 are formed in the opening 190a and the opening 190b, respectively.

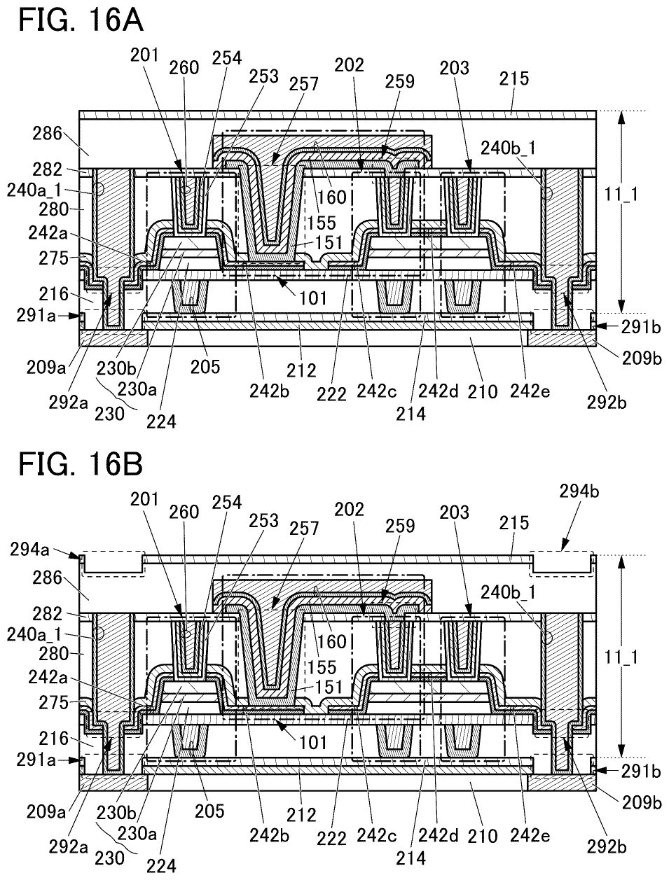

Next, the insulator 286 is formed over the conductor 160, the insulator 282, the conductor 240a_1, and the conductor 240b_1 to cover the capacitor 101 (FIG. 16A). The insulator 286 can be formed by a method similar to that for forming the insulator 216 or the insulator 280. For the insulator 286, a material similar to any of the materials that can be used for the insulator 216 or the insulator 280 can be used. In this embodiment, for the insulator 286, silicon oxide is deposited using a silicon target in an atmosphere containing an oxygen gas by a pulsed DC sputtering method.

Then, the insulator 215 is formed over the insulator 286 (FIG. 16A). The insulator 215 can be formed by a method similar to that for forming the insulator 214. For the insulator 215, a material similar to any of the materials that can be used for the insulator 214 can be used. In this embodiment, for the insulator 215, hafnium oxide is deposited by an ALD method. In the above manner, the memory layer 11_1 can be formed.

Next, the opening 294a reaching the insulator 286 is formed in the insulator 215 to overlap with the conductor 240a_1. The opening 294b reaching the insulator 286 is formed in the insulator 215 to overlap with the conductor 209b (FIG. 16B). The opening 294a and the opening 294b can be formed by a formation method similar to that for the opening 291a and the opening 291b. Note that the insulator 286 is sometimes partly removed by the formation of the openings in the insulator 215. This sometimes leads to formation of a depressed portion in each of a region of the insulator 286 that overlaps with the opening 294a and a region of the insulator 286 that overlaps with the opening 294b.

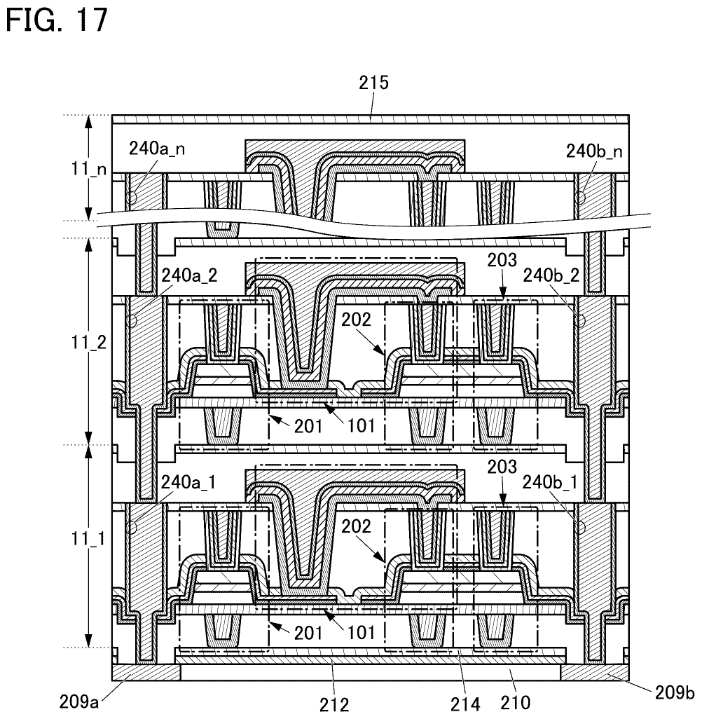

After that, the formation of the transistor 201, the transistor 202, the transistor 203, and the capacitor 101 is repeated n−1 times, whereby the memory layer 11_2 to the memory layer 11_n are formed (FIG. 17).

Next, the insulator 185 is formed over the insulator 215 in the memory layer 11_n. The insulator 185 can be formed by a method similar to that for forming the insulator 216, the insulator 280, or the insulator 286. For the insulator 185, a material similar to any of the materials that can be used for the insulator 216, the insulator 280, or the insulator 286 can be used. Through the above steps, the semiconductor device illustrated in FIG. 1 can be manufactured.

### Example 2 of Method for Manufacturing Semiconductor Device

Next, an example of a method for manufacturing the semiconductor device illustrated in FIG. 6 will be described.

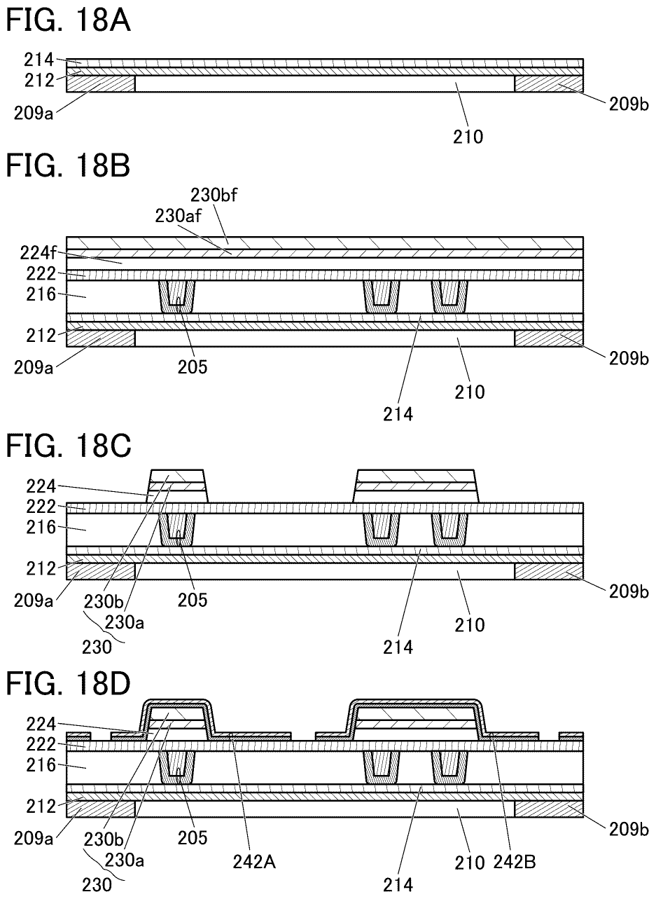

First, a step similar to the step illustrated in FIG. 11A is performed (FIG. 18A). Then, steps similar to the steps illustrated in FIG. 11C to FIG. 11F are performed (FIG. 18B). That is, the formation of the opening 291a and the opening 291b in the insulator 212 and the insulator 214 illustrated in FIG. 11B is not performed.

Next, a step similar to the step illustrated in FIG. 11G is performed (FIG. 18C). Then, a step similar to the step illustrated in FIG. 12B is performed (FIG. 18D). That is, the formation of the opening 292a and the opening 292b in the insulator 222 illustrated in FIG. 12A is not performed.

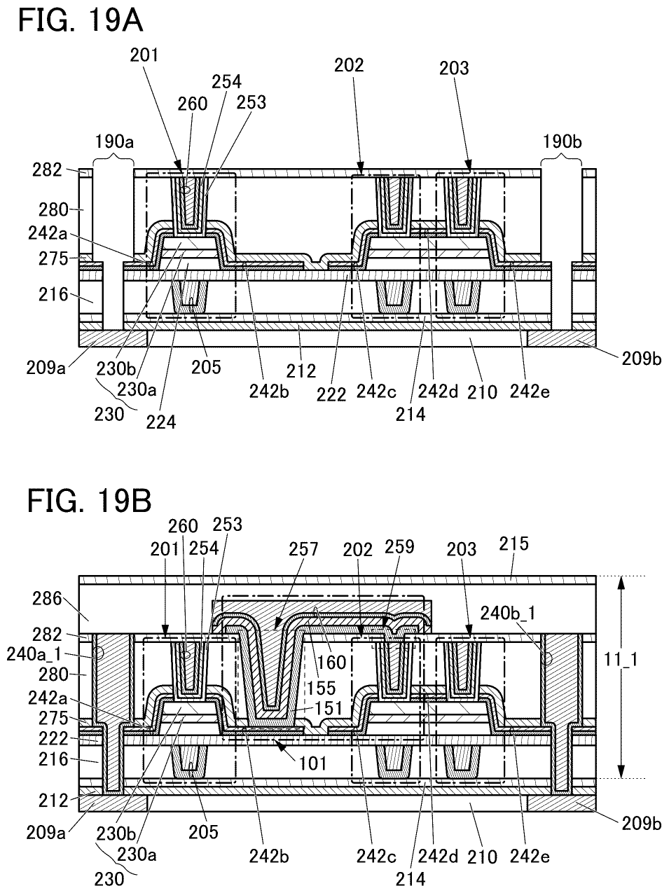

Next, steps similar to the steps illustrated in FIG. 12C, FIG. 13A to FIG. 13C, and FIG. 14A are performed. Specifically, the steps up to the formation of the opening 190a and the opening 190b are performed (FIG. 19A).

In the case where the conditions where the insulator 212, the insulator 214, the insulator 222, and the insulator 282 are easily processed are the same as the conditions where the insulator 216, the insulator 275, and the insulator 280 are easily processed, the opening 190a and the opening 190b can be formed under the same conditions. In that case, since the opening 291, the opening 292, and the opening 294 are not provided, the semiconductor device illustrated in FIG. 6 can be manufactured through a simpler process than the semiconductor device illustrated in FIG. 1, for example. Meanwhile, the semiconductor device illustrated in FIG. 1 can have a wider range of choices for the materials that can be used for the insulators than the semiconductor device illustrated in FIG. 6. Note that in the case where the etching rate of the insulator 212, the insulator 214, the insulator 222, and the insulator 282 is different from the etching rate of the insulator 216, the insulator 275, and the insulator 280, for example, the end portions of the insulator 212, the insulator 214, and the insulator 222 are not aligned or substantially aligned with the end portion of the insulator 216 in a cross-sectional view in some cases. For example, the end portion of the insulator 282 is not aligned or substantially aligned with the end portions of the insulator 275 and the insulator 280 in a cross-sectional view in some cases.

Next, steps similar to the steps illustrated in FIG. 14B, FIG. 15A, FIG. 15B, and FIG. 16A are performed. Consequently, the memory layer 11_1 is formed (FIG. 19B). After that, without formation of the opening 294a and the opening 294b in the insulator 215, the insulator 216 is formed over the insulator 215.

After that, the formation of the transistor 201, the transistor 202, the transistor 203, and the capacitor 101 is repeated n−1 times, whereby the memory layer 11_2 to the memory layer 11_n are formed. After that, the insulator 185 is formed over the insulator 215 in the memory layer 11_n, whereby the semiconductor device illustrated in FIG. 6 can be manufactured.

This embodiment can be combined with the other embodiments as appropriate. In this specification, in the case where a plurality of structure examples are shown in one embodiment, the structure examples can be combined as appropriate.

### Embodiment 2

In this embodiment, a memory device of one embodiment of the present invention will be described with reference to drawings.

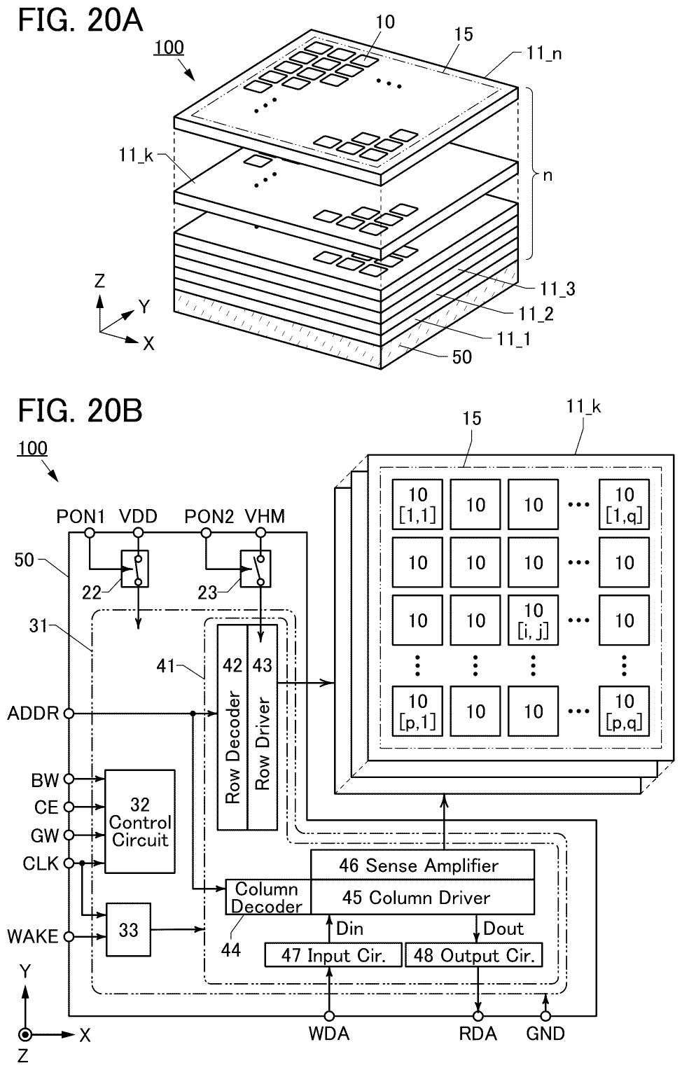

FIG. 20A is a schematic perspective view of a memory device of one embodiment of the present invention. FIG. 20B is a block diagram of the memory device of one embodiment of the present invention.

A memory device 100 illustrated in FIG. 20A and FIG. 20B includes a driver circuit layer 50 and the n memory layers 11. The memory layers 11 each include a memory cell array 15. The memory cell array 15 includes the plurality of memory cells 10.

The n memory layers 11 are provided over the driver circuit layer 50. Provision of the n memory layers 11 over the driver circuit layer 50 can reduce the area occupied by the memory device 100. Furthermore, memory capacity per unit area can be increased.

In this embodiment, the first memory layer 11 is denoted by the memory layer 11_1, the second memory layer 11 is denoted by the memory layer 11_2, and the third memory layer 11 is denoted by a memory layer 11_3. Furthermore, the k-th (k is an integer greater than or equal to 1 and less than or equal to n) memory layer 11 is denoted by a memory layer 11_k, and the n-th memory layer 11 is denoted by the memory layer 11_n. Note that in this embodiment and the like, the simple term “memory layer 11” is sometimes used in the case of describing matters related to all the n memory layers 11 or matters common to the n memory layers 11.

### <Structure Example of Driver Circuit Layer 50>

The driver circuit layer 50 includes a PSW 22 (power switch), a PSW 23, and a peripheral circuit 31. The peripheral circuit 31 includes a peripheral circuit 41, a control circuit 32, and a voltage generation circuit 33.

In the memory device 100, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside.

The signal CLK is a clock signal. The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 100. For example, the control circuit performs a logical operation on the signal CE, the signal GW, and the signal BW to determine an operation mode (e.g., a writing operation or a reading operation) of the memory device 100. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33 and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47 (Input Cir.), an output circuit 48 (Output Cir.), and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting a wiring WWL (write word line) or a wiring RWL (read word line) specified by the row decoder 42. The column driver 45 has a function of writing data to the memory cells 10, a function of reading data from the memory cells 10, a function of retaining the read data, and the like. The column driver 45 has a function of selecting a wiring WBL (write bit line) or a wiring RBL (read bit line) specified by the column decoder 44.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the memory device 100. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 100, a high power supply voltage is VDD and a low power supply voltage is GND (a ground potential). In addition, VHM is a high power supply voltage used to set a word line at a high level and is higher than VDD. The on/off of the PSW 22 is controlled by the signal PON1, and the on/off of the PSW 23 is controlled by the signal PON2. The number of power domains to which VDD is supplied is one in the peripheral circuit 31 in FIG. 20B but can be more than one. In that case, a power switch is provided for each power domain.

### <Structure Example of Memory Layer 11>

A structure example of the n memory layers 11 is described. The n memory layers 11 each include the memory cell array 15. The memory cell array 15 includes the plurality of memory cells 10. FIG. 20A and FIG. 20B illustrate an example in which the memory cell array 15 includes the plurality of memory cells 10 arranged in a matrix of p rows and q columns (each of p and q is an integer greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”.

In FIG. 20B, the memory cell 10 provided in the first row and the first column is referred to as a memory cell 10[1,1], and the memory cell 10 provided in the p-th row and the q-th column is referred to as a memory cell 10[p,q]. The memory cell 10 provided in the i-th row and the j-th column (i is an integer greater than or equal to 1 and less than or equal to p, and j is an integer greater than or equal to 1 and less than or equal to q) is referred to as a memory cell 10[i,j].

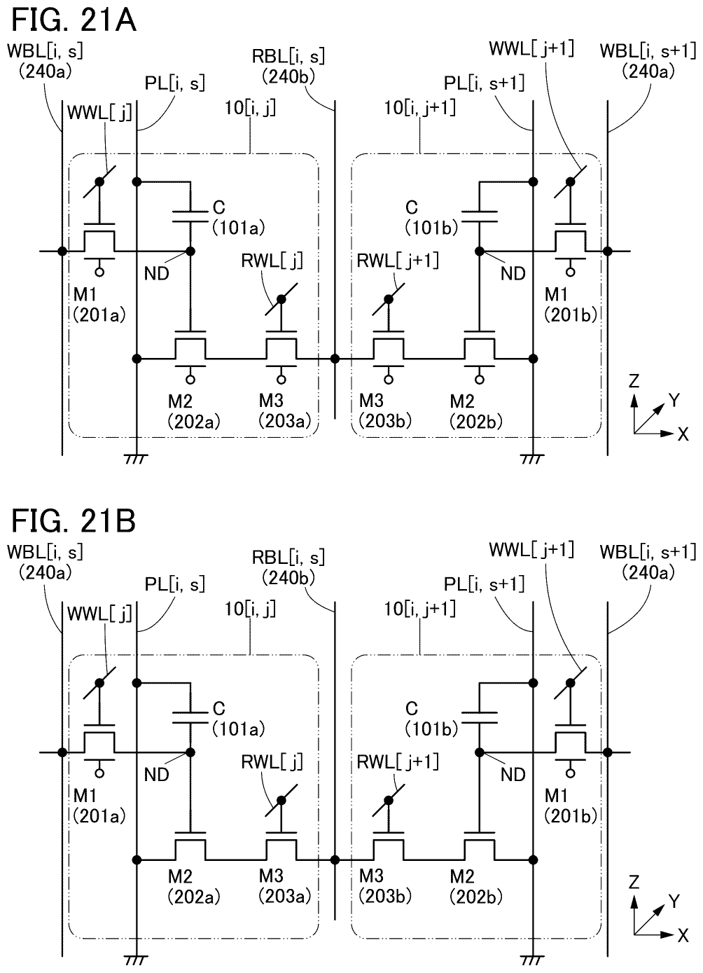

FIG. 21A and FIG. 21B illustrate circuit structure examples of memory cells. Embodiment 1 can be referred to for cross-sectional structure examples of the memory cells 10 corresponding to the circuit structures.

The memory cells 10 each include a transistor M1, a transistor M2, a transistor M3, and a capacitor C. A memory cell composed of three transistors and one capacitor is also referred to as a 3Tr1C memory cell. Thus, the memory cells 10 illustrated in FIG. 21A and FIG. 21B are each a 3Tr1C memory cell.

The transistor M1 corresponds to the transistor 201a or the transistor 201b described in Embodiment 1. The transistor M2 corresponds to the transistor 202a or the transistor 202b described in Embodiment 1. The transistor M3 corresponds to the transistor 203a or the transistor 203b described in Embodiment 1. The capacitor C corresponds to the capacitor 101a or the capacitor 101b described in Embodiment 1. The wiring WBL corresponds to the conductor 240a described in Embodiment 1. The wiring RBL corresponds to the conductor 240b described in Embodiment 1.

In the memory cell 10[i,j], a gate of the transistor M1 is electrically connected to a wiring WWL[j], and one of a source and a drain of the transistor M1 is electrically connected to a wiring WBL[i,s]. Note that FIG. 21A illustrates a structure example in which part of the wiring WWL[j] functions as the gate of the transistor M1. One electrode of the capacitor C is electrically connected to a wiring PL[i,s], and the other electrode is electrically connected to the other of the source and the drain of the transistor M1. Note that FIG. 21A illustrates a structure example in which part of the wiring PL[i,s] functions as the one electrode of the capacitor C, for example. A gate of the transistor M2 is electrically connected to the other electrode of the capacitor C, one of a source and a drain of the transistor M2 is electrically connected to one of a source and a drain of the transistor M3, and the other of the source and the drain of the transistor M2 is electrically connected to the wiring PL[i,s]. A gate of the transistor M3 is electrically connected to a wiring RWL[j], and the other of the source and the drain of the transistor M3 is electrically connected to a wiring RBL[i,s].

In the memory cell 10[i,j], a region where the other electrode of the capacitor C, the other of the source and the drain of the transistor M1, and the gate of the transistor M2 are electrically connected to one another and always have the same potential is referred to as a “node ND”.

In a memory cell 10[i,j+1], the gate of the transistor M1 is electrically connected to a wiring WWL[j+1], and one of the source and the drain of the transistor M1 is electrically connected to a wiring WBL[i,s+1]. Note that FIG. 21A illustrates a structure example in which part of the wiring WWL[j+1] functions as the gate of the transistor M1. One electrode of the capacitor C is electrically connected to a wiring PL[i,s+1], and the other electrode is electrically connected to the other of the source and the drain of the transistor M1. Note that FIG. 21A illustrates a structure example in which part of the wiring PL[i,s+1] functions as the one electrode of the capacitor C, for example. The gate of the transistor M2 is electrically connected to the other electrode of the capacitor C, one of the source and the drain of the transistor M2 is electrically connected to one of the source and the drain of the transistor M3, and the other of the source and the drain of the transistor M2 is electrically connected to the wiring PL[i,s+1]. The gate of the transistor M3 is electrically connected to a wiring RWL[j+1], and the other of the source and the drain of the transistor M3 is electrically connected to the wiring RBL[i,s].

Thus, the wiring RBL[i,s] is electrically connected to the source or the other of the transistor M3 included in the memory cell 10[i,j] and the source or the other of the transistor M3 included in the memory cell 10[i,j+1]. Accordingly, the wiring RBL[i,s] is shared by the memory cell 10[i,j] and the memory cell 10[i,j+1]. Although not illustrated, the wiring WBL[i,s] is shared by a memory cell 10[i,j-1] and the memory cell 10[i,j], and the wiring WBL[i,s+1] is shared by the memory cell 10[i,j+1] and a memory cell 10[i,j+2].

In the memory cell 10[i,j+1], a region where the other electrode of the capacitor C, the other of the source and the drain of the transistor M1, and the gate of the transistor M2 are electrically connected to one another and always have the same potential is referred to as the node ND.

As illustrated in FIG. 21A, a transistor with a back gate may be used as each of the transistor M1, the transistor M2, and the transistor M3. The gate and the back gate are placed such that a channel formation region of a semiconductor is sandwiched between the gate and the back gate. The gate and the back gate are formed using conductors. The back gate can function like the gate. By changing the potential of the back gate, the threshold voltage of the transistor can be changed. The potential of the back gate may be the same as the potential of the gate or may be a ground potential or a given potential.

Note that each of the transistor M1, the transistor M2, and the transistor M3 does not necessarily include a back gate. For example, as illustrated in FIG. 21B, a transistor with a back gate may be used as the transistor M1 and a transistor without a back gate may be used as each of the transistor M2 and the transistor M3.

In addition, the gate and the back gate are formed using conductors and thus also have a function of preventing an electric field generated outside the transistor from affecting the semiconductor in which a channel is formed (particularly, a function of blocking static electricity). That is, a variation in the electrical characteristics of the transistor due to the influence of an external electric field such as static electricity can be inhibited. Moreover, providing the back gate can reduce the amount of change in threshold voltage of the transistor before and after the bias-temperature stress test for examining the reliability of the transistor.

For example, the use of a transistor with a back gate as the transistor M1 can reduce the influence of an external electric field, allowing the off state to be maintained stably. Thus, data written to the node ND can be retained stably. Providing the back gate can stabilize the operation of the memory cells 10 and can improve the reliability of the memory device including the memory cells 10.

Likewise, the use of a transistor with a back gate as the transistor M3 can reduce the influence of an external electric field, allowing the off state to be maintained stably. Thus, leakage current between the wiring RBL and the wiring PL can be reduced, resulting in a reduction in the power consumption of the memory device including the memory cells 10.

As a semiconductor layer in which the channel of each of the transistor M1, the transistor M2, and the transistor M3 is formed, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, an oxide semiconductor, or a nitride semiconductor may be used.

Note that each of the transistor M1, the transistor M2, and the transistor M3 is preferably a transistor using an oxide semiconductor, which is a kind of metal oxide, in a semiconductor layer in which a channel is formed (also referred to as an “OS transistor”). An oxide semiconductor has a band gap of 2 eV or more and thus has an extremely low off-state current. Thus, the power consumption of the memory cells 10 can be reduced. Accordingly, the power consumption of the memory device 100 including the memory cells 10 can be reduced.

A memory cell including an OS transistor can be referred to as an “OS memory”. The memory device 100 including the memory cell can also be referred to as an “OS memory”.

The OS transistor operates stably even in a high-temperature environment and has a small variation in electrical characteristics. For example, the off-state current hardly increases even in the high-temperature environment. Specifically, the off-state current hardly increases even at an environmental temperature higher than or equal to room temperature and lower than or equal to 200° C. Furthermore, the on-state current is unlikely to decrease even in the high-temperature environment. Thus, the OS memory can operate stably and have high reliability even in the high-temperature environment.

### <Operation Example of Memory Cell 10>

Data writing and reading operation examples of the memory cell 10 will be described. In this embodiment, normally-off n-channel transistors are used as the transistor M1, the transistor M2, and the transistor M3.

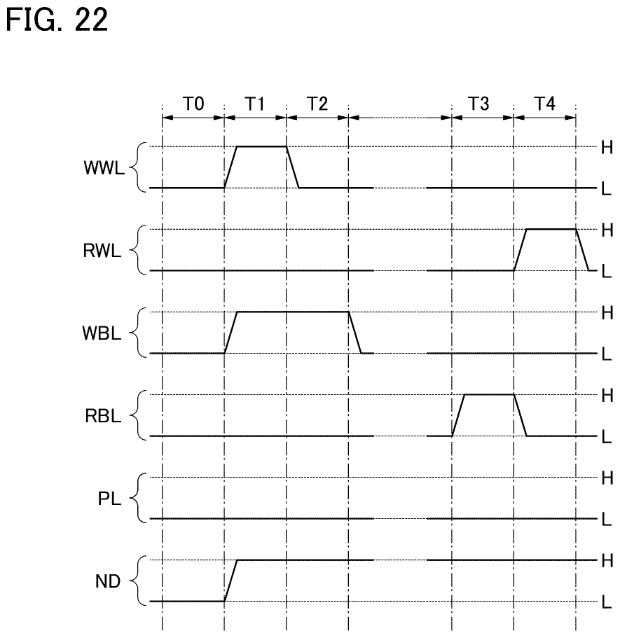

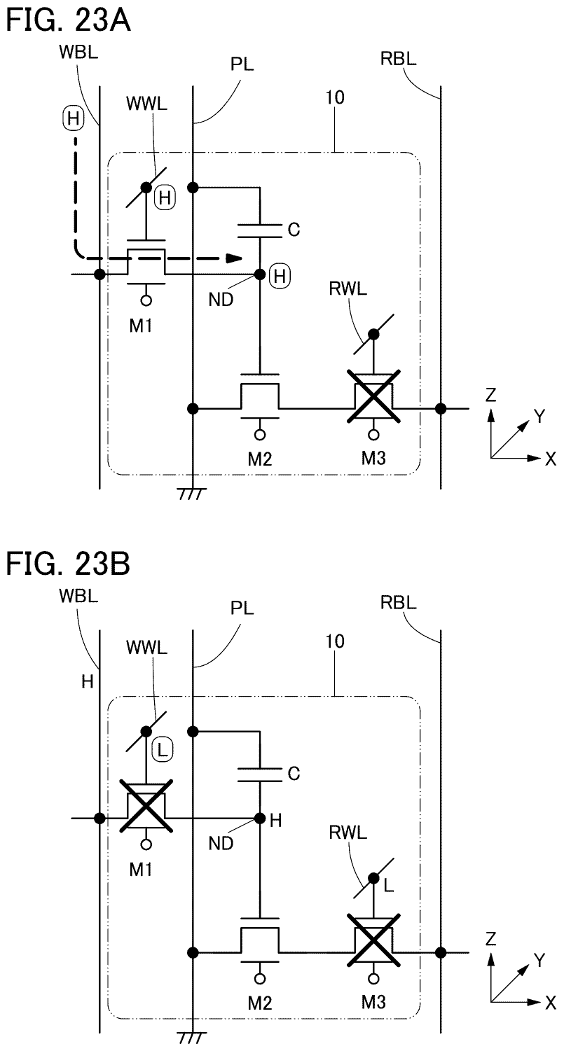

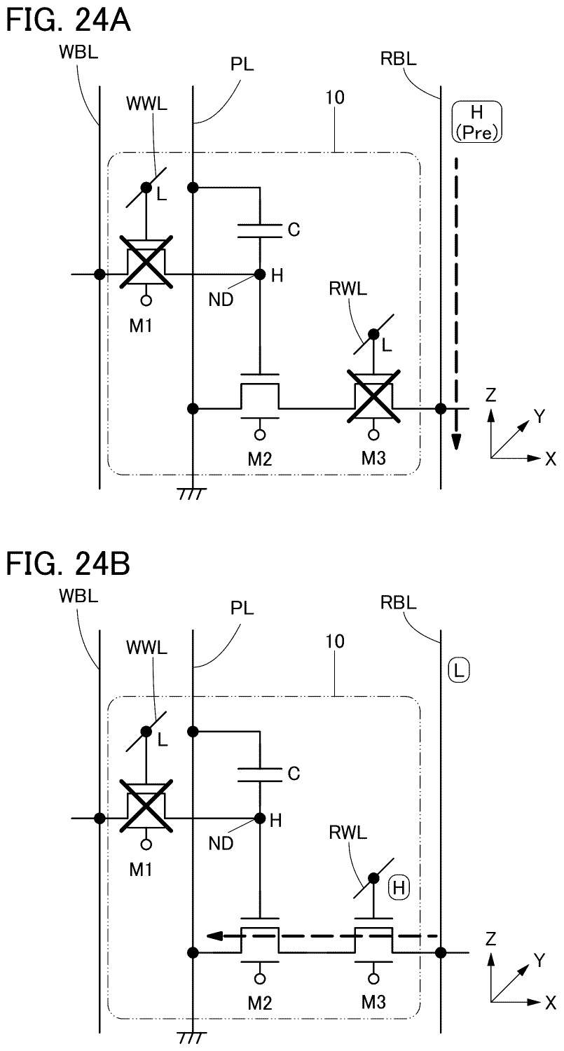

FIG. 22 is a timing chart for describing an operation example of the memory cell 10. FIG. 23A, FIG. 23B, FIG. 24A, and FIG. 24B are circuit diagrams for describing the operation example of the memory cell 10.

In the following drawings and the like, for showing the potentials of a wiring and an electrode, “H” representing a potential H or “L” representing a potential L is sometimes written near the wiring and the electrode. In addition, enclosed “H” or “L” is sometimes written near a wiring or an electrode whose potential changes. Moreover, in the case where a transistor is in an off state, a symbol “x” is sometimes written on the transistor.

When the potential H is supplied to a gate of an n-channel transistor, the transistor is turned on. When the potential L is supplied to a gate of an n-channel transistor, the transistor is turned off. Thus, the potential H is a potential higher than the potential L. The potential H may be a potential equal to the high power supply potential VDD. The potential L may be a potential equal to the ground potential GND. In this embodiment, the potential L is a potential equal to the ground potential GND.

First, in Period TO, the potentials of the wiring WWL, the wiring RWL, the wiring WBL, the wiring RBL, the wiring PL, and the node ND are the potential L (FIG. 22). In addition, the ground potential GND is supplied to the back gates of the transistor M1, the transistor M2, and the transistor M3.

### [Data Writing Operation]

In Period T1, the potential H is supplied to the wiring WWL and the wiring WBL (FIG. 22 and FIG. 23A). Accordingly, the transistor M1 is turned on and the potential H is written to the node ND as data indicating “1”.

When the potential of the node ND becomes the potential H, the transistor M2 is turned on. Since the potential of the wiring RWL is the potential L, the transistor M3 is in the off state. The transistor M3 in the off state can prevent a short circuit between the wiring RBL and the wiring PL.

### [Retention Operation]

In Period T2, the potential L is supplied to the wiring WWL. Accordingly, the transistor M1 is turned off and the node ND is brought into a floating state. Thus, data (potential H) written to the node ND is retained (FIG. 22 and FIG. 23B). Note that after Period T2, the potential of the wiring WBL becomes the potential L.

As described above, the OS transistor is a transistor having an extremely low off-state current. The use of the OS transistor as the transistor M1 enables data written to the node ND to be retained for a long period. Therefore, it becomes unnecessary to refresh the node ND and the power consumption of the memory cell 10 can be reduced. Thus, the power consumption of the memory device 100 can be reduced.

When the OS transistor is used as one or both of the transistor M2 and the transistor M3, leakage current flowing between the wiring RBL and the wiring PL in the writing operation and the retention operation can be extremely low.

Moreover, the OS transistor has a higher source-drain withstand voltage than the Si transistor. When the OS transistor is used as the transistor M1, a higher potential can be supplied to the node ND. This increases the range of a potential retained at the node ND. An increase in the range of the potential retained at the node ND makes it easy to retain multilevel data or to retain analog data.

### [Reading Operation]

In Period T3, the potential His precharged (Pre) to the wiring RBL. That is, the potential of the wiring RBL is set to the potential H and then the wiring RBL is brought into a floating state (FIG. 22 and FIG. 24A).

Next, in Period T4, the potential H is supplied to the wiring RWL, so that the transistor M3 is turned on (FIG. 22 and FIG. 24B). At this time, in the case where the potential of the node ND is the potential H, the transistor M2 is in an on state; thus, electrical continuity is established between the wiring RBL and the wiring PL through the transistor M2 and the transistor M3. When electrical continuity is established between the wiring RBL and the wiring PL, the potential of the wiring RBL, which is in a floating state, changes from the potential H to the potential L.

Note that the transistor M2 is in an off state in the case where the potential L is written to the node ND as data indicating “0”. Thus, electrical continuity is not established between the wiring RBL and the wiring PL even when the transistor M3 is turned on, and the potential of the wiring RBL remains the potential H.

By detecting a change in the potential of the wiring RBL at the time of supplying the potential H to the wiring RWL in this manner, data written to the memory cell 10 can be read.

The memory cell 10 using the OS transistor employs a method in which charge is written to the node ND through the OS transistor; hence, a high voltage, which is required for a conventional flash memory, is unnecessary and a high-speed writing operation is possible. Furthermore, unlike in a flash memory, the number of times of data writing and reading in the memory cell 10 using the OS transistor is substantially unlimited because charge injection and extraction into/from a floating gate or a charge-trap layer are not performed. Unlike in a flash memory, unstableness due to an increase of electron trap centers is not observed in the memory cell 10 using the OS transistor even when a rewriting operation is repeated. The memory cell 10 using the OS transistor is less likely to degrade than a conventional flash memory and can have high reliability.

Unlike a magnetic memory, a resistive random access memory, or the like, the memory cell 10 using the OS transistor has no change in the structure at the atomic level. Thus, the memory cell 10 using the OS transistor has higher rewrite endurance than a magnetic memory and a resistive random access memory.

### <Structure Example of Sense Amplifier 46>

Next, a structure example of the sense amplifier 46 will be described. Specifically, a structure example of a write read circuit that includes the sense amplifier 46 and performs writing or reading of a data signal will be described.

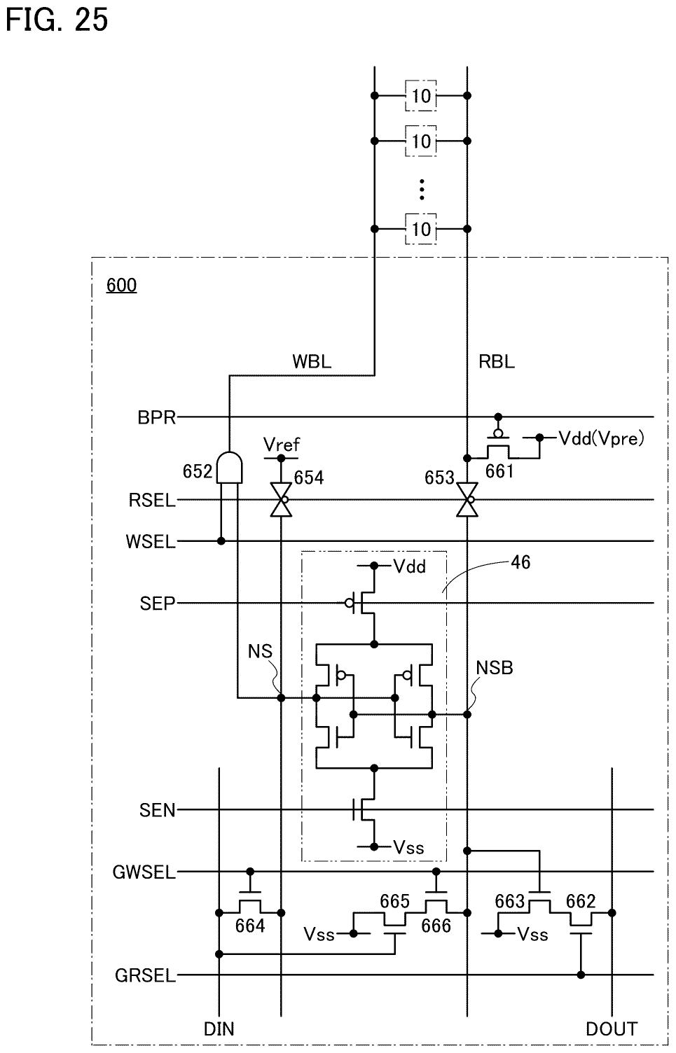

FIG. 25 is a circuit diagram illustrating a structure example of a circuit 600 that includes the sense amplifier 46 and performs writing or reading of a data signal. The circuit 600 is provided for every wiring WBL and every wiring RBL.

The circuit 600 includes a transistor 661 to a transistor 666, the sense amplifier 46, an AND circuit 652, an analog switch 653, and an analog switch 654.

The circuit 600 operates in accordance with a signal SEN, a signal SEP, a signal BPR, a signal RSEL, a signal WSEL, a signal GRSEL, and a signal GWSEL.

Data DIN input to the circuit 600 is written to the memory cell 10 through the wiring WBL electrically connected to a node NS through the AND circuit 652. Data DOUT written to the memory cell 10 is transmitted to the wiring RBL electrically connected to a node NSB through the analog switch 653 and output from the circuit 600 as the data DOUT.

Note that the data DIN and the data DOUT are internal signals and respectively correspond to the signal WDA and the signal RDA illustrated in FIG. 20B.

The transistor 661 is included in a precharge circuit. The wiring RBL is precharged to a precharge potential Vpre by the transistor 661. Note that in this embodiment, the case where a potential Vdd (high level) is used as the precharge potential Vpre will be described (denoted by Vdd (Vpre) in FIG. 25). The signal BPR is a precharge signal, and the conduction state of the transistor 661 is controlled by the signal BPR.

In a reading operation, the sense amplifier 46 determines whether data input to the wiring RBL is at a high level or a low level. In a writing operation, the sense amplifier 46 functions as a latch circuit that temporarily retains the data DIN input to the circuit 600.

The sense amplifier 46 illustrated in FIG. 25 is a latch sense amplifier. The sense amplifier 46 includes two inverter circuits, and an input node of one of the inverter circuits is connected to an output node of the other of the inverter circuits. When the input node of the one of the inverter circuits is the node NS and the output node is the node NSB, complementary data is retained at the node NS and the node NSB.

The signal SEN and the signal SEP are each a sense amplifier enable signal for activating the sense amplifier 46, and a reference potential Vref is a read judge potential. The sense amplifier 46 determines whether the potential of the node NSB at the time of the activation is at a high level or a low level on the basis of the reference potential Vref.

The AND circuit 652 controls electrical continuity between the node NS and the wiring WBL. The analog switch 653 controls electrical continuity between the node NSB and the wiring RBL. The analog switch 654 controls electrical continuity between the node NS and a wiring supplying the reference potential Vref.

In data reading, the potential of the wiring RBL is transmitted to the node NSB by the analog switch 653. When the potential of the wiring RBL is lower than the reference potential Vref, the sense amplifier 46 determines that the wiring RBL is at a low level. The sense amplifier 46 determines that the wiring RBL is at a high level when the potential of the wiring RBL does not become lower than the reference potential Vref.

The signal WSEL is a write selection signal and controls the AND circuit 652. The signal RSEL is a read selection signal and controls the analog switch 653 and the analog switch 654.

The transistor 662 and the transistor 663 are included in an output MUX (multiplexer) circuit. The signal GRSEL is a global read selection signal and controls the output MUX circuit. The output MUX circuit has a function of selecting the wiring RBL from which data is to be read.

The output MUX circuit has a function of outputting the data DOUT read from the sense amplifier 46.

The transistor 664 to the transistor 666 are included in a write driver circuit. The signal GWSEL is a global write selection signal and controls the write driver circuit. The write driver circuit has a function of writing the data DIN to the sense amplifier 46.

The write driver circuit has a function of selecting a column to which the data DIN is to be written. The write driver circuit writes data in byte units, half-word units, or word units in response to the signal GWSEL.

In a gain-cell memory cell, at least two transistors are required for one memory cell, which makes it difficult to increase the number of memory cells that can be placed per unit area. However, when an OS transistor is used as a transistor included in the memory cell 10, the plurality of memory cell arrays 15 can be stacked. That is, the amount of data that can be stored per unit area can be increased. A gain-cell memory cell can operate as a memory by amplifying accumulated charge by the closest transistor even when the capacitance of accumulated charge is small. When an OS transistor with an extremely low off-state current is used as a transistor included in the memory cell 10, the capacitance of the capacitor can be made small. Furthermore, one or both of the gate capacitance of a transistor and the parasitic capacitance of a wiring can be used as the capacitor, so that the capacitor can be omitted. That is, the area of the memory cell 10 can be made small.

This embodiment can be combined with the other embodiments as appropriate.

### Embodiment 3

In this embodiment, an example of a chip on which the memory device of one embodiment of the present invention is mounted will be described with reference to drawings.

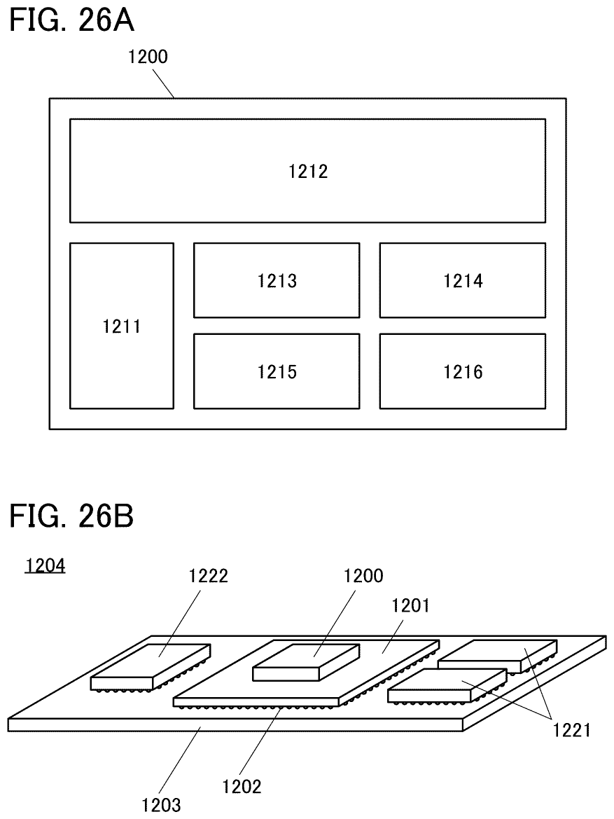

A plurality of circuits (systems) are mounted on a chip 1200 illustrated in FIG. 26A and FIG. 26B. A technique for integrating a plurality of circuits (systems) into one chip is referred to as system on chip (SoC) in some cases.

As illustrated in FIG. 26A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 26B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Memory devices such as DRAMs 1221 and a flash memory 1222 may be provided over the motherboard 1203. For example, the NOSRAM described in the above embodiment can be used as the DRAM 1221. This can make the DRAM 1221 have low power consumption, operate at high speed, and have a large capacity.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The NOSRAM described above can be used as the memory. Moreover, the GPU 1212 is suitable for parallel computation of a large amount of data and thus can be used for image processing or a product-sum operation. When an image processing circuit or a product-sum operation circuit using an OS transistor is provided in the GPU 1212, image processing or a product-sum operation can be performed with low power consumption.

In addition, since the CPU 1211 and the GPU 1212 are provided on the same chip, a wiring between the CPU 1211 and the GPU 1212 can be shortened, and data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at a high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security. The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with the other embodiments as appropriate.

### Embodiment 4

In this embodiment, examples of an electronic component incorporating the memory device of one embodiment of the present invention will be described.

### [Electronic Component]

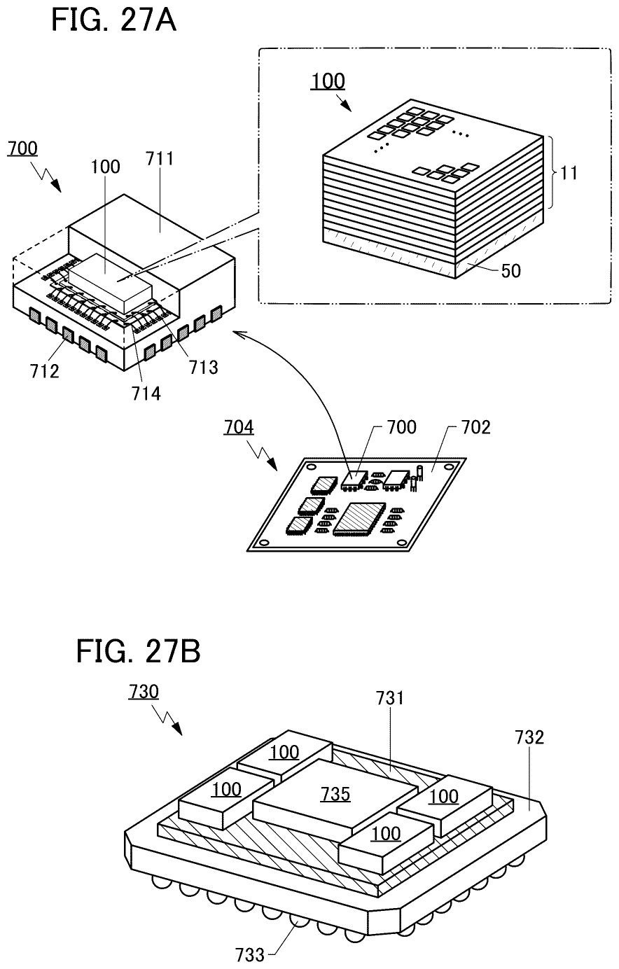

FIG. 27A is a perspective view of an electronic component 700 and a substrate (circuit board 704) on which the electronic component 700 is mounted. The electronic component 700 illustrated in FIG. 27A includes the memory device 100 that is the memory device of one embodiment of the present invention in a mold 711. FIG. 27A omits part of the electronic component to illustrate the inside of the electronic component 700. The electronic component 700 includes a land 712 outside the mold 711. The land 712 is electrically connected to an electrode pad 713, and the electrode pad 713 is electrically connected to the memory device 100 through a wire 714. The electronic component 700 is mounted on a printed circuit board 702, for example. A plurality of such electronic components are combined and electrically connected to each other on the printed circuit board 702, so that the circuit board 704 is completed.

As described in the above embodiment, the memory device 100 includes the driver circuit layer 50 and the memory layers 11 (each including the memory cell array 15).

FIG. 27B is a perspective view of an electronic component 730. The electronic component 730 is an example of a SiP (System in package) or an MCM (Multi Chip Module). In the electronic component 730, an interposer 731 is provided over a package substrate 732 (printed circuit board), and a semiconductor device 735 and a plurality of the memory devices 100 are provided over the interposer 731.

The electronic component 730 using the memory devices 100 as high bandwidth memory (HBM) is illustrated as an example. An integrated circuit (a semiconductor device) such as a CPU, a GPU, or an FPGA can be used as the semiconductor device 735.

As the package substrate 732, for example, a ceramic substrate, a plastic substrate, or a glass epoxy substrate can be used. As the interposer 731, for example, a silicon interposer or a resin interposer can be used.

The interposer 731 includes a plurality of wirings and has a function of electrically connecting a plurality of integrated circuits with different terminal pitches. The plurality of wirings are provided in a single layer or multiple layers. The interposer 731 has a function of electrically connecting an integrated circuit provided over the interposer 731 to an electrode provided over the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In a silicon interposer, a TSV (Through Silicon Via) can also be used as the through electrode.

A silicon interposer is preferably used as the interposer 731. The silicon interposer can be manufactured at lower cost than an integrated circuit because it is not necessary to provide an active element. Moreover, since wirings of a silicon interposer can be formed through a semiconductor process, formation of minute wirings, which is difficult for a resin interposer, is easily achieved.

In order to achieve a wide memory bandwidth, many wirings need to be connected to an HBM. Therefore, formation of minute and high-density wirings is required for an interposer on which an HBM is mounted. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity, so that a poor connection between the silicon interposer and an integrated circuit provided over the silicon interposer is less likely to occur. It is particularly preferable to use a silicon interposer for a 2.5D package (2.5-dimensional mounting) in which a plurality of integrated circuits are arranged side by side over the interposer.

A heat sink (radiator plate) may be provided to overlap with the electronic component 730. In the case of providing a heat sink, the heights of integrated circuits provided over the interposer 731 are preferably the same. In the electronic component 730 described in this embodiment, the heights of the memory devices 100 and the semiconductor device 735 are preferably the same, for example.

An electrode 733 may be provided on the bottom portion of the package substrate 732 to mount the electronic component 730 on another substrate. FIG. 27B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of a mounting method include SPGA (Staggered Pin Grid Array), LGA (Land Grid Array), QFP (Quad Flat Package), QFJ (Quad Flat J-leaded package), and QFN (Quad Flat Non-leaded package).

This embodiment can be combined with the other embodiments as appropriate.

### Embodiment 5

In this embodiment, application examples of the memory device of one embodiment of the present invention will be described.

The memory device of one embodiment of the present invention can be used as memory devices of a variety of electronic devices (e.g., information terminals, computers, smartphones, e-book readers, digital still cameras, video cameras, video recording/reproducing devices, navigation systems, and game machines). The memory device can also be used for image sensors, IoT (Internet of Things), healthcare-related devices, and the like. Note that here, the computers refer not only to tablet computers, laptop computers, and desktop computers, but also to large computers such as server systems.

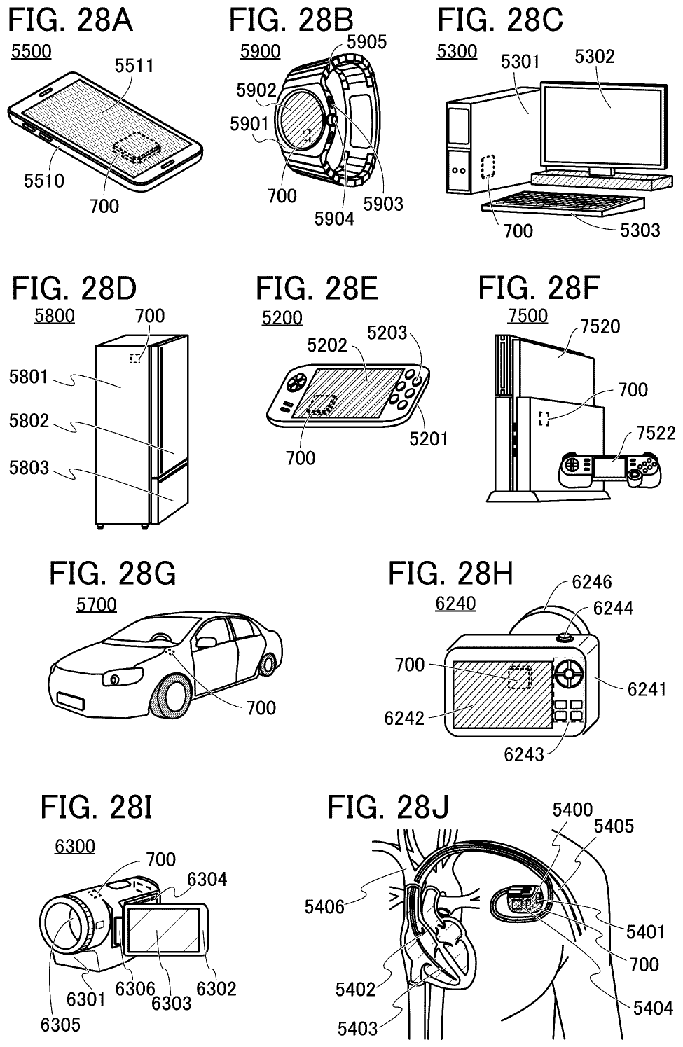

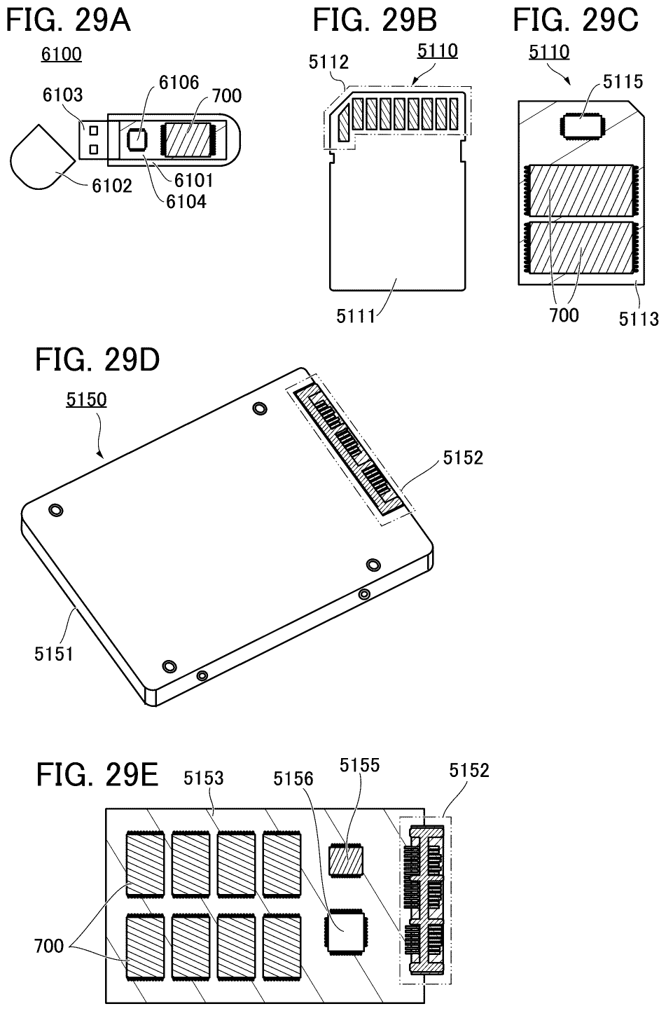

Examples of an electronic device including the memory device of one embodiment of the present invention will be described. Note that FIG. 28A to FIG. 28J and FIG. 29A to FIG. 29E each illustrate a state where the electronic component 700 or the electronic component 730 that includes the memory device described in the above embodiments is included in an electronic device.

### [Mobile Phone]

An information terminal 5500 illustrated in FIG. 28A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

By using the memory device of one embodiment of the present invention, the information terminal 5500 can retain a temporary file generated at the time of executing an application (e.g., a web browser's cache).

### [Wearable Terminal]

FIG. 28B illustrates an information terminal 5900 as an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by using the memory device of one embodiment of the present invention.

### [Information Terminal]

FIG. 28C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application by using the memory device of one embodiment of the present invention.

FIG. 28A to FIG. 28C illustrate the smartphone, the wearable terminal, and the desktop information terminal as electronic devices, and examples of other information terminals include a PDA (Personal Digital Assistant), a laptop information terminal, and a workstation.

### [Household Appliance]

FIG. 28D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The memory device of one embodiment of the present invention can be used in the electric refrigerator-freezer 5800. The electric refrigerator-freezer 5800 can transmit and receive information on food stored in the electric refrigerator-freezer 5800 and food expiration dates, for example, to and from an information terminal via the Internet. In the electric refrigerator-freezer 5800, the memory device of one embodiment of the present invention can retain a temporary file generated at the time of transmitting the information.

FIG. 28D illustrates the electric refrigerator-freezer as a household appliance, and examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

### [Game Machine]

FIG. 28E illustrates a portable game machine 5200 as an example of a game machine. The portable game machine 5200 includes a housing 5201, a display portion 5202, a button 5203, and the like.

FIG. 28F illustrates a stationary game machine 7500 as an example of a game machine. The stationary game machine 7500 can be especially referred to as a home-use stationary game machine. The stationary game machine 7500 includes a main body 7520 and a controller 7522. Note that the controller 7522 can be connected to the main body 7520 with or without a wire. Although not illustrated in FIG. 28F, the controller 7522 can include a display portion that displays a game image, and an input interface besides the button, such as a touch panel, a stick, a rotating knob, and a sliding knob. The shape of the controller 7522 is not limited to that illustrated in FIG. 28F, and the shape of the controller 7522 may be changed in various ways in accordance with the genres of games. For example, for a shooting game such as an FPS (First Person Shooter) game, a gun-shaped controller having a trigger button can be used. For another example, for a music game, a controller having a shape of a musical instrument, audio equipment, or the like can be used. Furthermore, the stationary game machine may include one or more of a camera, a depth sensor, and a microphone so that the game player can play a game using a gesture or a voice instead of a controller.

Videos displayed on the game machine can be output with a display device such as a television device, a personal computer display, a game display, or a head-mounted display.

By using the memory device of one embodiment of the present invention in the portable game machine 5200 or the stationary game machine 7500, power consumption can be reduced. Moreover, heat generation from a circuit can be reduced owing to low power consumption; thus, the influence of heat generation on the circuit itself, a peripheral circuit, and a module can be reduced.

Moreover, by using the memory device of one embodiment of the present invention, the portable game machine 5200 or the stationary game machine 7500 can retain a temporary file or the like necessary for an arithmetic operation that occurs during game play.

FIG. 28E and FIG. 28F illustrate the portable game machine and the home-use stationary game machine as examples of game machines, and examples of other game machines include an arcade game machine installed in an entertainment facility (e.g., a game center and an amusement park) and a throwing machine for batting practice, installed in sports facilities.

### [Moving Vehicle]

The memory device of one embodiment of the present invention can be used in an automobile, which is a moving vehicle, and the periphery of a driver's seat in the automobile.

FIG. 28G illustrates an automobile 5700 as an example of a moving vehicle.

An instrument panel that provides various kinds of information by displaying a speedometer, a tachometer, a mileage, a fuel meter, a gearshift state, air-conditioning settings, and the like is provided around the driver's seat in the automobile 5700. In addition, a memory device showing the above information may be provided around the driver's seat.

In particular, the display device can compensate for the view obstructed by a pillar, blind areas for the driver's seat, and the like by displaying a video from an imaging device (not illustrated) provided for the automobile 5700, which can improve safety. That is, displaying an image taken by the imaging device provided on the exterior of the automobile 5700 can compensate for blind areas and improve safety.

The memory device of one embodiment of the present invention can temporarily retain information; thus, the memory device can be used to retain temporary information necessary in a system conducting automatic driving, navigation, risk prediction, or the like for the automobile 5700, for example. Moreover, the memory device of one embodiment of the present invention may be configured to retain a video of a driving recorder provided in the automobile 5700.

Although the automobile is described above as an example of a moving vehicle, the moving vehicle is not limited to the automobile. Examples of the moving vehicle include a train, a monorail train, a ship, and a flying object (a helicopter, an unmanned aircraft (drone), an airplane, or a rocket).

### [Camera]

The memory device of one embodiment of the present invention can be used in a camera.

FIG. 28H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that the digital camera 6240 is configured here such that the lens 6246 is detachable from the housing 6241 for replacement; alternatively, the lens 6246 may be integrated with the housing 6241. Moreover, the digital camera 6240 may be configured to be additionally equipped with a stroboscope, a viewfinder, or the like.

By using the memory device of one embodiment of the present invention, the digital camera 6240 can have low power consumption. Moreover, heat generation from a circuit can be reduced owing to low power consumption; thus, the influence of heat generation on the circuit itself, a peripheral circuit, and a module can be reduced.

### [Video Camera]

The memory device of one embodiment of the present invention can be used in a video camera.

FIG. 28I illustrates a video camera 6300 as an example of an imaging device. The video camera 6300 includes a first housing 6301, a second housing 6302, a display portion 6303, an operation switch 6304, a lens 6305, a joint 6306, and the like. The operation switch 6304 and the lens 6305 are provided in the first housing 6301, and the display portion 6303 is provided in the second housing 6302. The first housing 6301 and the second housing 6302 are connected to each other with the joint 6306, and the angle between the first housing 6301 and the second housing 6302 can be changed with the joint 6306. Videos displayed on the display portion 6303 may be switched in accordance with the angle at the joint 6306 between the first housing 6301 and the second housing 6302.

When a video taken by the video camera 6300 is recorded, the video needs to be encoded in accordance with a data recording format. With the use of the memory device of one embodiment of the present invention, the video camera 6300 can retain a temporary file generated at the time of encoding.

### [ICD]

The memory device of one embodiment of the present invention can be used in an implantable cardioverter-defibrillator (ICD).

FIG. 28J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with the end of one of the wires placed in the right ventricle and the end of the other wire placed in the right atrium.

The ICD main unit 5400 functions as a pacemaker and paces the heart when the heart rate is not within a predetermined range. When the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In the ICD main unit 5400, data on the heart rate obtained by the sensor, the number of times the treatment with pacing is performed, and the time taken for the treatment, for example, can be stored in the electronic component 700.

The antenna 5404 can receive electric power, and the battery 5401 is charged with the electric power. When the ICD main unit 5400 includes a plurality of batteries, the safety can be improved. Specifically, even when some of the batteries in the ICD main unit 5400 are dead, the other batteries can work properly; hence, the batteries also function as an auxiliary power source.

In addition to the antenna 5404 that can receive electric power, an antenna that can transmit a physiological signal may be included to construct, for example, a system that monitors cardiac activity by checking physiological signals such as a pulse, a respiratory rate, a heart rate, and body temperature with an external monitoring device.

### [Expansion Device for PC]

The memory device of one embodiment of the present invention can be used in a computer such as a PC (Personal Computer) and an expansion device for an information terminal.

FIG. 29A illustrates, as an example of the expansion device, a portable expansion device 6100 that is externally attached to a PC and includes a chip capable of storing information. The expansion device 6100 can store information using the chip when connected to a PC with a USB (Universal Serial Bus), for example. Note that FIG. 29A illustrates the portable expansion device 6100; however, the expansion device of one embodiment of the present invention is not limited thereto and may be a relatively large expansion device including a cooling fan, for example.

The expansion device 6100 includes a housing 6101, a cap 6102, a USB connector 6103, and a substrate 6104. The substrate 6104 is held in the housing 6101. The substrate 6104 is provided with a circuit for driving the memory device of one embodiment of the present invention, for example. The substrate 6104 is provided with the electronic component 700 and a controller chip 6106, for example. The USB connector 6103 functions as an interface for connection to an external device.

### [Sd Card]

The memory device of one embodiment of the present invention can be used in an SD card that can be attached to an electronic device such as an information terminal or a digital camera.

FIG. 29B is a schematic external view of an SD card, and FIG. 29C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, the substrate 5113 is provided with the electronic component 700 and a controller chip 5115. Note that the circuit structures of the electronic component 700 and the controller chip 5115 are not limited to those described above, and the circuit structures may be changed as appropriate depending on circumstances. For example, a write circuit, a row driver, a read circuit, or the like provided in an electronic component may be incorporated into the controller chip 5115 instead of the electronic component 700.

When the electronic component 700 is also provided on the back surface side of the substrate 5113, the capacity of the SD card 5110 can be increased. In addition, a wireless chip with a wireless communication function may be provided on the substrate 5113. This enables wireless communication between an external device and the SD card 5110, making it possible to write and read data to/from the electronic component 700.

### [SSD]

The memory device of one embodiment of the present invention can be used in an SSD (Solid State Drive) that can be attached to an electronic device such as an information terminal.

FIG. 29D is a schematic external view of an SSD, and FIG. 29E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device. For example, the substrate 5153 is provided with the electronic component 700, a memory chip 5155, and a controller chip 5156. When the electronic component 700 is also provided on the back surface side of the substrate 5153, the capacity of the SSD 5150 can be increased. A work memory is incorporated into the memory chip 5155. For example, a DRAM chip is used as the memory chip 5155. A processor, an ECC (Error-Correcting Code) circuit, and the like are incorporated into the controller chip 5156. Note that the circuit structures of the electronic component 700, the memory chip 5155, and the controller chip 5115 are not limited to those described above, and the circuit structures may be changed as appropriate depending on circumstances. For example, a memory functioning as a work memory may also be provided in the controller chip 5156.

### [Computer]

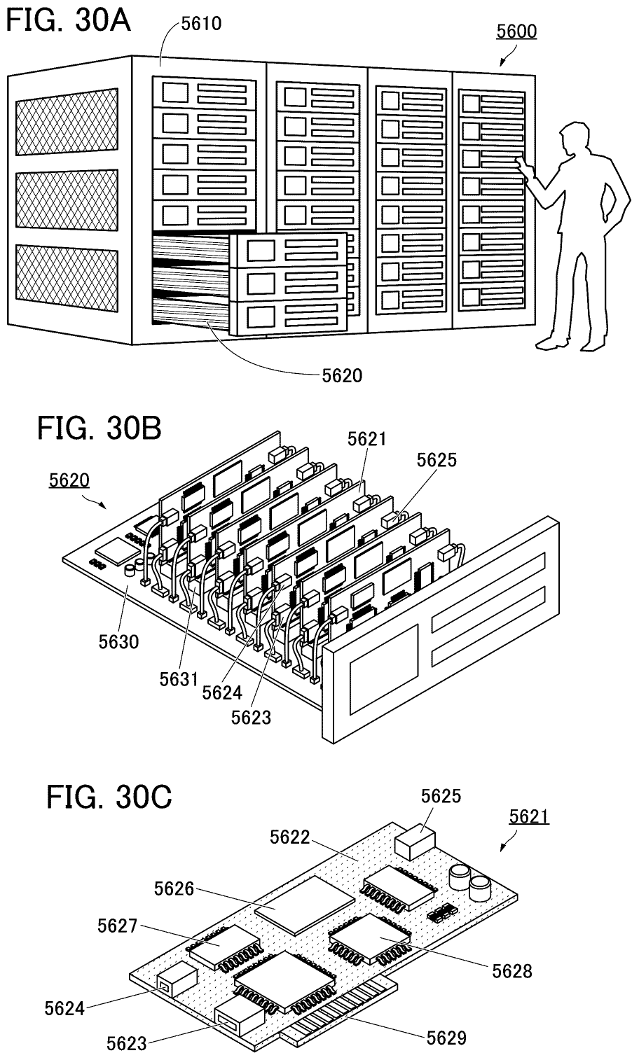

A computer 5600 illustrated in FIG. 30A is an example of a large computer. In the computer 5600, a plurality of rack mount computers 5620 are stored in a rack 5610.

The computer 5620 can have a structure in a perspective view illustrated in FIG. 30B, for example. In FIG. 30B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 30C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. FIG. 30C also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve, for example, as an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

The memory device of one embodiment of the present invention is used in a variety of electronic devices and the like described above, whereby a reduction in size and a reduction in power consumption of the electronic devices can be achieved. In addition, since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention can achieve an electronic device that operates stably even in a high-temperature environment. Thus, the reliability of the electronic device can be improved.

This embodiment can be combined with the other embodiments as appropriate.

### Embodiment 6

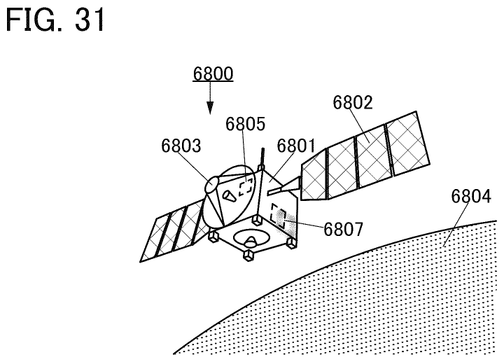

In this embodiment, specific examples of the case where the semiconductor device of one embodiment of the present invention is used in a device for space will be described with reference to FIG. 31.

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space.

FIG. 31 illustrates an artificial satellite 6800 as an example of a device for space. The artificial satellite 6800 includes a body 6801, a solar panel 6802, an antenna 6803, a secondary battery 6805, and a control device 6807. Note that in FIG. 31, a planet 6804 in outer space is illustrated as an example. Note that outer space refers to, for example, space at an altitude greater than or equal to 100 km, and outer space described in this specification may include one or more of thermosphere, mesosphere, and stratosphere.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, meson beams, and the like.

When the solar panel 6802 is irradiated with sunlight, electric power required for the operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for the operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, the present invention is not limited thereto. The semiconductor device of one embodiment of the present invention can be suitably used for a device for space such as a spacecraft, a space capsule, or a space probe, for example.

### REFERENCE NUMERALS

10: memory cell, 11: memory layer, 15: memory cell array, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: driver circuit layer, 100: memory device, 101a: capacitor, 101b: capacitor, 101: capacitor, 151: conductor, 155: insulator, 160: conductor, 185: insulator, 190a: opening, 190b: opening, 201a: transistor, 201b: transistor, 201: transistor, 202a: transistor, 202b: transistor, 202: transistor, 203a: transistor, 203b: transistor, 203: transistor, 205: conductor, 207a: opening, 207b: opening, 207c: opening, 209a: conductor, 209b: conductor, 209: conductor, 210: insulator, 212: insulator, 214: insulator, 215: insulator, 216: insulator, 222: insulator, 224f: insulating film, 224: insulator, 230a: metal oxide, 230af: metal oxide film, 230b: metal oxide, 230bf: metal oxide film, 230: metal oxide, 240a: conductor, 240b: conductor, 240: conductor, 242a: conductor, 242A: conductive layer, 242b: conductor, 242B: conductive layer, 242c: conductor, 242d: conductor, 242e: conductor, 242: conductor, 253: insulator, 254: insulator, 257: opening, 258a: opening, 258b: opening, 258c: opening, 258: opening, 259: opening, 260: conductor, 275: insulator, 280: insulator, 282: insulator, 286: insulator, 291a: opening, 291b: opening, 291: opening, 292a: opening, 292b: opening, 292: opening, 294a: opening, 294b: opening, 294: opening, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 600: circuit, 652: AND circuit, 653: analog switch, 654: analog switch, 661: transistor, 662: transistor, 663: transistor, 664: transistor, 666: transistor, 700: electronic component, 702: printed circuit board, 704: circuit board, 711: mold, 712: land, 713: electrode pad, 714: wire, 730: electronic component, 731: interposer, 732: package substrate, 733: electrode, 735: semiconductor device, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5110: SD card, 5111: housing, 5112: connector, 5113: substrate, 5115: controller chip, 5150: SSD, 5151: housing, 5152: connector, 5153: substrate, 5155: memory chip, 5156: controller chip, 5200: portable game machine, 5201: housing, 5202: display portion, 5203: button, 5300: desktop information terminal, 5301: main body, 5302: display portion, 5303: keyboard, 5400: ICD main unit, 5401: battery, 5402: wire, 5403: wire, 5404: antenna, 5405: subclavian vein, 5406: superior vena cava, 5500: information terminal, 5510: housing, 5511: display portion, 5600: computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5700: automobile, 5800: electric refrigerator-freezer, 5801: housing, 5802: refrigerator door, 5803: freezer door, 5900: information terminal, 5901: housing, 5902: display portion, 5903: operation switch, 5904: operation switch, 5905: band, 6100: expansion device, 6101: housing, 6102: cap, 6103: USB connector, 6104: substrate, 6106: controller chip, 6240: digital camera, 6241: housing, 6242: display portion, 6243: operation switch, 6244: shutter button, 6246: lens, 6300: video camera, 6301: first housing, 6302: second housing, 6303: display portion, 6304: operation switch, 6305: lens, 6306: joint, 6800: artificial satellite, 6801: body, 6802: solar panel, 6803: antenna, 6804: planet, 6805: secondary battery, 6807: control device, 7500: stationary game machine, 7520: main body, 7522: controller

1. A semiconductor device comprising:
a first insulator;
a first transistor comprising:
a first metal oxide;
a second insulator over the first metal oxide;
a first conductor over the second insulator; and
a second conductor being over the first metal oxide and being electrically connected to the first metal oxide;
a second transistor comprising:
a second metal oxide;
a third insulator over the second metal oxide;
a third conductor over the third insulator; and
a fourth conductor;
a third transistor comprising:
the second metal oxide;
a fourth insulator over the second metal oxide;
the fourth conductor electrically connected to the second metal oxide; and
a fifth conductor over the fourth insulator; and
a capacitor comprising:
a sixth conductor electrically connected to the third conductor;
a fifth insulator over the sixth conductor; and
a seventh conductor over the fifth insulator,
wherein the fourth conductor is between the third insulator and the fourth insulator,
wherein the first insulator is over the second conductor,
wherein the sixth conductor comprises a region in contact with a side surface of the first insulator and a top surface of the second conductor, and
wherein the seventh conductor comprises a region below a top surface of the first insulator.

2. The semiconductor device according to claim 1, further comprising an eighth conductor,
wherein the first transistor further comprises a ninth conductor,
wherein the ninth conductor covers a part of a top surface and a part of a side surface of the first metal oxide,
wherein the second insulator is between the second conductor and the ninth conductor, and
wherein the eighth conductor comprises a first region in contact with a side surface of the ninth conductor.

3. The semiconductor device according to claim 2,
wherein the first insulator is over the ninth conductor,
wherein the eighth conductor further comprises a second region in contact with the side surface of the first insulator, and
wherein a width of the second region of the eighth conductor is larger than a width of the first region of the eighth conductor in a cross-sectional view.

4. The semiconductor device according to claim 3, further comprising a sixth insulator and a seventh insulator,
wherein the seventh insulator covers at least a part of a top surface and a side surface of the sixth insulator,
wherein each of the first metal oxide, the second metal oxide and the ninth conductor are over the seventh insulator, and
wherein the eighth conductor further comprises a region in contact with a side surface of the seventh insulator.

5. The semiconductor device according to claim 4,
wherein the first transistor further comprises a tenth conductor and an eighth insulator,
wherein the second transistor further comprises an eleventh conductor and a ninth insulator,
wherein the third transistor further comprises a twelfth conductor and the ninth insulator,
wherein each of the tenth conductor, the eleventh conductor and the twelfth conductor is over the sixth insulator and is in contact with the side surface of the seventh insulator,
wherein the tenth conductor and the first conductor overlap each other,
wherein the eleventh conductor and the third conductor overlap each other,
wherein the twelfth conductor and the fifth conductor overlap each other,
wherein the eighth insulator is between the tenth conductor and the first metal oxide, and
wherein the ninth insulator is between the second metal oxide and each of the eleventh conductor and the twelfth conductor.

6. The semiconductor device according to claim 1, further comprising a tenth insulator,
wherein the first insulator is over the fourth conductor,
wherein the tenth insulator is over the first insulator and comprises a region between the first insulator and the sixth conductor,
wherein the tenth insulator comprises an opening reaching the fourth conductor, and
wherein the sixth conductor further comprises a region in the opening.

7. The semiconductor device according to claim 6, wherein the sixth conductor further comprises a region in contact with a top surface and a side surface of the tenth insulator.

8. The semiconductor device according to claim 1, wherein each of the first metal oxide and the second metal oxide comprises indium, zinc, and one or more selected from gallium, aluminum and tin.

9. A method for manufacturing a semiconductor device, comprising the steps of:
forming a first metal oxide and a second metal oxide;
forming a first conductive layer over the first metal oxide and a second conductive layer over the second metal oxide;
forming a first insulator over the first conductive layer and the second conductive layer;
forming a first conductor and a second conductor by forming a first opening reaching the first metal oxide in the first insulator and the first conductive layer, and forming a third conductor, a fourth conductor, and a fifth conductor by forming a second opening and a third opening each reaching the second metal oxide in the first insulator and the second conductive layer;
forming a second insulator and a sixth conductor over the second insulator in the first opening, a third insulator and a seventh conductor over the third insulator in the second opening, and a fourth insulator and an eighth conductor over the fourth insulator in the third opening;
forming a fifth insulator over the first insulator, the second insulator, the third insulator, the fourth insulator, the sixth conductor, the seventh conductor and the eighth conductor;
forming, in the first insulator and the fifth insulator, a fourth opening reaching the second conductor and forming, in the fifth insulator, a fifth opening reaching the seventh conductor;
forming a ninth conductor in the fourth opening and the fifth opening; and
forming, over the ninth conductor, a sixth insulator and a tenth conductor over the sixth insulator.

10. The method for manufacturing a semiconductor device, according to claim 9,
wherein the first conductive layer is formed to cover a top surface and a side surface of the first metal oxide and the second conductive layer is formed to cover a top surface and a side surface of the second metal oxide,
wherein, after the fifth insulator is formed, a sixth opening is formed in the fifth insulator and the first insulator to expose a side surface of the first conductor, and
wherein an eleventh conductor is formed in the sixth opening to be in contact with the side surface of the first conductor.

11. The method for manufacturing a semiconductor device, according to claim 10, wherein, in a cross-sectional view, the side surface of the first conductor exposed by the formation of the sixth opening is positioned in the sixth opening more inwardly than a side surface of the first insulator.

12. The method for manufacturing a semiconductor device, according to claim 10,
wherein a seventh insulator is formed,
wherein a seventh opening is formed in the seventh insulator,
wherein an eighth insulator is formed to cover the seventh opening,
wherein the first metal oxide and the second metal oxide are formed over the eighth insulator, and
wherein the sixth opening is formed in the eighth insulator to comprise a region overlapping with the first opening.

13. The method for manufacturing a semiconductor device, according to claim 12,
wherein, after the eighth insulator is formed, an eighth opening, a ninth opening, and a tenth opening each reaching the seventh insulator are formed in the eighth insulator,
wherein a twelfth conductor is formed in the eighth opening, a thirteenth conductor is formed in the ninth opening, and a fourteenth conductor is formed in the tenth opening,
wherein a ninth insulator and the first metal oxide over the ninth insulator are formed over the twelfth conductor, and a tenth insulator and the second metal oxide over the tenth insulator are formed over the thirteenth conductor and the fourteenth conductor,
wherein the first conductive layer is formed to cover a side surface of the ninth insulator, and the second conductive layer is formed to cover a side surface of the tenth insulator, and
wherein the first opening is formed to comprise a region overlapping with the twelfth conductor, the second opening is formed to comprise a region overlapping with the thirteenth conductor, and the third opening is formed to comprise a region overlapping with the fourteenth conductor.
